(19) United States
(12) Patent Application Publication
(10) Pub. No.: US 2008/0246025 A1
(43) Pub. Date: Oct. 9, 2008

(54) Semiconductor device and method for manufacturing the same

(76) Inventors: Ryoji Nomura, Yamato (JP); Takaaki Nagata, Atsugi (JP); Naoto Kusumoto, Isehara (JP)

Correspondence Address: ERIC ROBINSON, PMB 955, 21010 SOUTHBANK ST., POTOMAC FALLS, VA, 20165, US

(21) Appl. No.: 11/907,959

(22) Filed: Oct. 18, 2007

(30) Foreign Application Priority Data
Oct. 19, 2006 (JP) 2006-285378

(51) Int. Cl. H01L 35/24; H01L 51/40

(52) U.S. Cl. 257/40; 438/99; 257/E51.001

(57) ABSTRACT

It is an object to provide an element structure in which defects are not easily generated and a semiconductor device that has the element. An element has a structure in which a layer containing an organic compound is interposed between a pair of electrode layers of a first electrode layer and a second electrode layer. At least one of the pair of the electrode layers has a Young's modulus of 7.5×10¹⁰ N/m² or less. A layer containing an organic compound is formed using an organic compound appropriate to usage of an element to be formed, and a memory element, a light-emitting element, a piezoelectric element, or an organic transistor element is formed.

### TECHNICAL FIELD

The present invention relates to a semiconductor device and a method for manufacturing the same. In particular, the present invention relates to a semiconductor device having an element that includes a layer containing an organic compound.

### BACKGROUND ART

In recent years, individual recognition technology has attracted attention. For example, there is a technology which is used for production and management, in which an ID (an individual recognition code) is given to an individual object to clarify information such as a history of the object. Above all, the development of semiconductor devices that can send and receive data without contact has been advanced. As such semiconductor devices, in particular, an RFID (radio frequency identification) tag (also referred to as an ID tag, an IC tag, IC chip, an RF (radio frequency) tag, a wireless tag, an electronic tag, or a wireless chip) has begun to be used in companies, markets, and the like.

A large number of such semiconductor devices include a circuit using a semiconductor substrate such as silicon (Si) (hereinafter, also referred to as an IC (integrated circuit) chip) and an antenna. The IC chip includes a memory circuit (hereinafter, also referred to as a memory), a control circuit, and the like.

In a process for manufacturing such semiconductor devices, in order to reduce manufacturing cost, a process for transposing an element, peripheral circuits, and the like formed over a glass substrate to an inexpensive substrate has been performed (for example, Reference 1: Japanese Published Patent Application No. H11-097357).

### DISCLOSURE OF INVENTION

By transposing an element formed over a glass substrate to a plastic substrate, it becomes possible to provide an extreme thin semiconductor device that can be bent. However, there is a problem in that the element is broken due to causes that the element is not peeled well from the substrate, the substrate or the element is bent in the process for transposing the element or the like.

For example, an element provided with a layer containing an organic compound between a pair of electrode layers can be applied to various elements such as a memory element and a light-emitting element. When a material included in the electrode layers of these elements is selected in consideration of electrical characteristics such as work function and electrical resistance depending on demanded element characteristics and the like, a selection range of the material included in the electrode layer tends to be narrowed, and the element is broken in being transposed. In FIGS. 21A and 21B, an example in which a memory element having a layer containing an organic compound between a pair of electrode layers is broken in being transposed is shown.

FIG. 21A shows a structure in which an element 3020 is provided over a first substrate 3000 and a second substrate 3040 is provided thereover.

The first substrate 3000 is a substrate over which the element 3020 is formed and a substrate from which is the element 3020 is peeled. The element 3020 includes a layer 3024 containing an organic compound between a first electrode layer 3022 and a second electrode layer 3026. In the element 3020, the first electrode layer 3022 is in contact with the substrate 3000, and the second electrode layer 3026 is in contact with the second substrate 3040. The second substrate 3040 is a substrate to which the element 3020 formed over the first substrate 3000 is transposed, in other words, a substrate for peeling the element 3020 from the first substrate 3000. The second substrate 3040 is a flexible substrate.

The element 3020 is transposed (peeled) from the first substrate 3000 to the second substrate 3040. Force is applied to the element 3020 in the direction of the first substrate 3000 or the second substrate 3040 when the element 3020 is transposed, and the element 3020 is bent by the applied force. For example, in a case where the second substrate 3040 is a flexible substrate, force is applied to the second substrate 3040 in transposition, so that the second substrate 3040 is bent. At this time, the element 3020 needs to be bent along with bending of the second substrate 3040. However, the electrode layer included in the element 3020 is formed of a conductive material such as metal, which is generally hard and not easily bent. Therefore, the element 3020 cannot respond to the bending of the second substrate 3040, and the element may be broken.

After the element 3020 is transposed form the first substrate 3000 to the second substrate 3040, in a case where a third substrate (flexible substrate) is attached to a surface where the first substrate 3000 is peeled, the second substrate 3040 or the third substrate may be bent. In this case, similarly, the electrode layer included in the element 3020 is formed of a conductive material such as metal, which is hard and not easily bent; therefore, the element may be broken.

FIG. 21B shows an example in which the element is broken in a transposing process. FIG. 21B shows for example, a state in which peeling is generated at an interface between the second electrode layer 3026 and the layer 3024 containing an organic compound or a state in which crack is caused in the second electrode layer 3026. It is to be noted that defects shown in FIG. 21B are only one example, and various breakdown of the element may occur. Further, the breakdown of the element includes a case where electrical characteristics, reliability, and the like are lowered, even if the element is not damaged in appearance. When the element is broken in the transposing process in such a manner, the yield is reduced in manufacturing semiconductor devices having the element. Furthermore, when the element included in the completed semiconductor device has difficulty in responding to behavior such as bending and the like, reliability is adversely affected.

In view of the above problems, it is an object of the present invention to provide an element structure in which defects are not easily generated and a semiconductor device having the element. It is another object to provide a semiconductor device with high reliability and a method for manufacturing the same. It is further another object to provide a technique in which a semiconductor device having an element can be manufactured with the high yield.

It is a feature of the present invention to manufacture an element in which defects are not easily generated and a semiconductor device having the element. In particular, it is a feature to manufacture an element that can be transposed favorably and a semiconductor device having the element. In this specification, “transposition” means that an element formed over a first substrate is moved to a second substrate. In the transposition, the element is peeled from the first substrate. Further, a state in which a transposing process can be performed favorably means a state in which a transposing process is performed without causing defects such as damage in appearance and characteristic degradation in the element. Hereinafter, a state in which a transposing process can be performed favorably also refers to a state in which transposition characteristics are favorable.

An element in accordance with the present invention has an element structure that includes a layer containing an organic compound between a pair of electrode layers formed of a first electrode layer and a second electrode layer. At least one of the pair of the electrode layers has a Young's modulus of 7.5×10¹⁰ N/m² or less. For the layer containing an organic compound, an organic compound appropriate to usage of the element to be manufactured is used.

After the element having the above structure is formed over the first substrate, the element is transposed to the second substrate, and a semiconductor device having the element is manufactured. In the present invention, it is a feature that in the element, an electrode layer on the side that is not in contact with the first substrate and is attached to the second substrate has a Young's modulus of 7.5×10¹⁰ N/m² or less.

It is a feature of the present invention that an element that includes a layer containing an organic compound between a first electrode layer and a second electrode layer is provided, and the second electrode layer has a Young's modulus of 7.5×10¹⁰ N/m² or less.

It is another feature of the present invention that an element that includes a layer containing an organic compound between a first electrode layer and a second electrode layer is provided, and the second electrode layer has a Young's modulus of 7.5×10¹⁰ N/m² or less and a thickness of greater than or equal to 10 nm and less than or equal to 200 nm.

The second electrode layer preferably contains at least one of indium (In), barium (Ba), lead (Pb), calcium (Ca), bismuth (Bi), magnesium (Mg), tin (Sn), and aluminum (Al).

The element that includes the layer containing an organic compound is preferably a memory element, a light-emitting element, a piezoelectric element, an organic transistor element, a capacitor element, a resistor element, or a photoelectric conversion element.

It is a feature of the present invention that a first electrode layer is formed, a layer containing an organic compound is formed over the first electrode layer, and a second electrode layer having a Young's modulus of 7.5×10¹⁰ N/m² or less is formed over the layer containing an organic compound.

It is another feature of the present invention that a first electrode layer is formed, a layer containing an organic compound is formed over the first electrode layer, and a second electrode layer having a Young's modulus of 7.5×10¹⁰ N/m² or less and thickness of greater than or equal to 10 nm and less than or equal to 200 nm is formed over the layer containing an organic compound.

It is another feature of the present invention that a peeling layer is formed over a first substrate, a first electrode layer is formed over the peeling layer, a layer containing an organic compound is formed over the first electrode layer, a second electrode layer having a Young's modulus of 7.5×10¹⁰ N/m² or less is formed over the layer containing an organic compound, thereby forming an element layer, and after attaching a second substrate over the second electrode layer, the element layer is peeled from the first substrate.

It is another feature of the present invention that a peeling layer is formed over a first substrate, a first electrode layer is formed over the peeling layer, a layer containing an organic compound is formed over the first electrode layer, a second electrode layer having a Young's modulus of 7.5×10¹⁰ N/m² or less and a thickness of greater than or equal to 10 nm and less than or equal to 200 nm is formed over the layer containing an organic compound, thereby forming an element layer, and after attaching a second substrate over the second electrode layer, the element layer is peeled from the first substrate.

After the element layer is peeled from the first substrate, a third flexible substrate can be attached to the element layer.

A flexible substrate is preferably used for the second substrate.

The second electrode layer is preferably formed using a material containing at least one of indium (In), barium (Ba), lead (Pb), calcium (Ca), bismuth (Bi), magnesium (Mg), tin (Sn), and aluminum (Al).

In the element layer, a memory element, a light-emitting element, a piezoelectric element, an organic transistor element, a capacitor element, a resistor element, or a photoelectric conversion element is preferably formed. Further, a transistor may be formed in the element layer.

According to the present invention, an element having high resistance to behavior such as bending, in which defects are not easily generated, can be provided. Therefore, a semiconductor device having the element can be manufactured with high yield.

According to the present invention, a semiconductor device provided over a flexible substrate can be provided. By applying the present invention, defects of an element can be prevented also when the semiconductor device is provided over the flexible substrate; therefore, reliability of the semiconductor device can be improved.

### BRIEF DESCRIPTION OF DRAWINGS

FIGS. 1A and 1B are views each showing an example of an element structure of the present invention.

FIG. 2 is a view showing an example of an element structure of the present invention.

FIGS. 3A and 3B are views showing an element structure of the present invention.

FIGS. 4A to 4C are diagrams showing an example of a semiconductor device of the present invention.

FIGS. 5A and 5B are a top view and a cross-sectional view showing an example of a semiconductor device of the present invention.

FIGS. 6A to 6C are cross-sectional views showing an example of a semiconductor device of the present invention.

FIGS. 7A to 7C are diagrams showing an example of a semiconductor device of the present invention.

FIGS. 8A to 8C are top view and cross-sectional views showing an example of a semiconductor device of the present invention.

FIGS. 9A and 9B are views showing an example of a display device of the present invention.

FIGS. 10A to 10D are views each showing an example of a semiconductor device of the present invention.

FIGS. 11A and 11B are views showing an example of a method for manufacturing a semiconductor device of the present invention.

FIGS. 12A and 12B are views showing an example of a method for manufacturing a semiconductor device of the present invention.

FIGS. 13A to 13F are views each showing an example of a semiconductor device of the present invention.

FIGS. 14A and 14B are views showing an example of a semiconductor device of the present invention.

FIGS. 15A and 15B are views showing an example of a method for manufacturing a semiconductor device of the present invention.

FIGS. 16A and 16B are views showing an example of a method for manufacturing a semiconductor device of the present invention.

FIGS. 17A and 17B are views showing an example of a method for manufacturing a semiconductor device of the present invention.

FIG. 18 is a view showing an example of a method for manufacturing a semiconductor device of the present invention.

FIG. 19 is a view showing an example of a semiconductor device of the present invention.

FIG. 20 is a diagram showing an example of an equivalent circuit of a pixel portion in a display device of the present invention.

FIGS. 21A and 21B are views showing an example of a conventional semiconductor device.

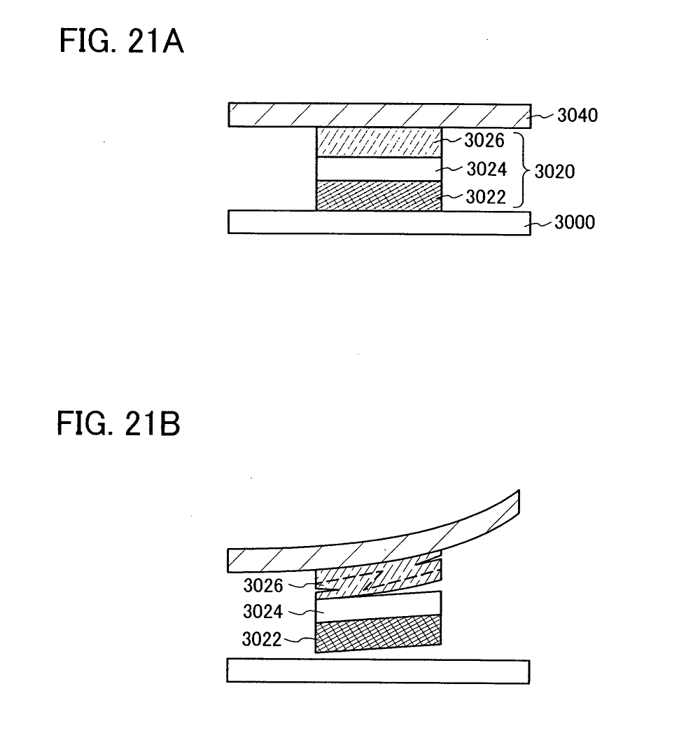

FIG. 22 is a graph showing mechanical properties of metal elements.

FIGS. 23A to 23C are views showing an example of a method for manufacturing a semiconductor device of the present invention.

FIG. 24 is a top schematic view of a semiconductor device of the present invention.

FIGS. 25A and 25B are graphs each showing the evaluation result of a semiconductor device of the present invention.

FIGS. 26A to 26D are graphs each showing the evaluation result of a semiconductor device of the present invention.

### BEST MODE FOR CARRYING OUT THE INVENTION

Hereinafter, embodiment modes of the present invention will be described in detail below with reference to the accompanying drawings. However, the present invention is not limited to the following description, and it is easily understood by those skilled in the art that various changes and modifications are possible, unless such changes and modifications depart from the content and the scope of the invention. Therefore, the present invention is not construed as being limited to the description of the following embodiment modes. It is to be noted that like portions in the drawings may be denoted by the like reference numerals in a structure of the present invention to be given below.

### Embodiment Mode 1

The present invention relates to an element structure of a memory element, a light-emitting element, a piezoelectric element, an organic transistor element, a capacitor element, a resistor element, a photoelectric conversion element, or the like and a semiconductor device having the element. A basic structure of the element that is applied to the present invention includes a layer containing an organic compound (also referred to as an organic compound layer) between a pair of electrode layers. In the element according to the present invention, at least one of the electrode layers has a Young's modulus of 7.5×10¹⁰ N/m² or less. Further preferably, the electrode layer has a Young's modulus of 7.06×10¹⁰ N/m² or less that is a Young's modulus of aluminum. It is to be noted that a Young's modulus indicated in this specification is a Young's modulus at room temperature.

As for the pair of the electrode layers, conductive materials are used. Both of the pair of the electrode layers may have a Young's modulus of 7.5×10¹⁰ N/m² or less, or only one of the electrode layers may have a Young's modulus of 7.5×10¹⁰ N/m² or less. Accordingly, materials may be selected in considering a Young's modulus for one of the electrode layers and electrical characteristics such as work function and electrical resistance for the other electrode layer. For the layer containing an organic compound, an organic compound appropriate to usage of an element to be manufactured is used. Hereinafter, a specific element structure will be described.

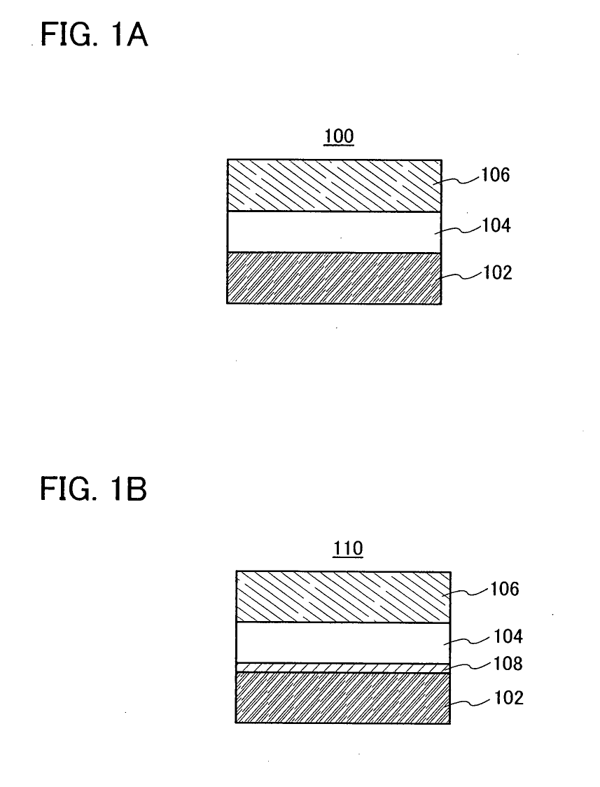

In FIGS. 1A and 1B, examples of a memory element of the present invention are shown. A memory element 100 shown in FIG. 1A has a structure in which a first electrode layer 102, a layer 104 containing an organic compound, and a second electrode layer 106 are sequentially stacked.

The first electrode layer 102 is formed using a conductive material. For example, an element such as gold (Au), silver (Ag), platinum (Pt), nickel (Ni), tungsten (W), chromium (Cr), molybdenum (Mo), iron (Fe), cobalt (Co), copper (Cu), palladium (Pd), carbon (C), aluminum (Al), manganese (Mn), titanium (Ti), or tantalum (Ta), or an alloy material or a compound material containing the element can be used. As a compound containing the element, a nitrogen compound, an oxygen compound, a carbon compound, a halogenated compound, or the like can be used. For example, titanium nitride, tungsten nitride, molybdenum nitride, or the like can be used. In addition, an alkali metal such as lithium (Li) or cesium (Cs), an alkaline earth metal such as magnesium (Mg), calcium (Ca), or strontium (Sr), a rare earth metal such as europium (Er) or ytterbium (Yb), an alloy containing any of these (such as MgAg or AlLi), or the like can be used. Further, a light-transmitting conductive oxide material such as indium tin oxide (ITO), zinc oxide (ZnO), indium zinc oxide (IZO), or zinc oxide to which gallium is added (GZO), or a conductive material such as indium tin oxide containing silicon oxide (ITSO) or indium oxide containing zinc oxide (ZnO) of 2 to 20 wt % can be used. The first electrode layer 102 can be formed using one of these materials or by combining two or more of kinds of these materials.

It is to be noted that a thickness of the first electrode layer 102 is not particularly limited, and it is preferably about 20 nm to 200 nm, further preferably about 50 nm to 100 nm.

The second electrode layer 106 is formed using a conductive material so that a Young's modulus of the second electrode layer 106 in a completed memory element is 7.5×10¹⁰ N/m² or less. For example, the second electrode layer 106 is formed using a metal element having a Young's modulus of 7.5×10¹⁰ N/m² or less or using an alloy material or a compound material having a Young's modulus of 7.5×10¹⁰ N/m² or less. When an alloy material or a compound material is used, it is preferable to contain a metal element having a Young's modulus of 7.5×10¹⁰ N/m² or less. Further, a material having a low Young's modulus is preferably used for the second electrode layer 106. By reducing a Young's modulus, the second electrode layer 106 becomes easy to be transformed.

For example, for the second electrode layer 106, a metal element such as indium (In), barium (Ba), lead (Pb), calcium (Ca), bismuth (Bi), magnesium (Mg), tin (Sn), or aluminum (Al), or an alloy material or a compound material containing the metal element can be used. As an alloy material containing the element, an indium-tin (In—Sn) alloy, an aluminum-magnesium (Al—Mg) alloy, a magnesium-silver (Mg—Ag) alloy, or the like can be used. As a compound containing the element, a nitrogen compound, an oxygen compound, a carbon compound, a halogenated compound, or the like can be used. The second electrode layer 106 can be formed using one of these materials or by combining two or more kinds of these materials.

It is to be noted that a thickness of the second electrode layer 106 is not particularly limited, and it is preferably about 10 nm to 200 nm, and further preferably about 10 nm to 100 nm. By relatively reducing the thickness of the second electrode layer 106 to 10 nm to 100 nm, the second electrode layer becomes easy to be transformed.

The first electrode layer 102 or the second electrode layer 106 is formed using the above material to have a single-layer structure or a stacked structure by an evaporation method, a sputtering method, a printing method, or a droplet discharge method.

The layer 104 containing an organic compound is formed to have a single-layer structure or a stacked structure, using an organic compound of which conductivity is changed or of which a shape is transformed by optical action or electric action. The memory element that includes the layer 104 containing the organic compound can store two values corresponding to an “initial state” and a “state after change” before or after change of the conductivity or transformation of the shape. For such a layer 104 containing an organic compound, an organic compound having a hole-transporting property, an organic compound having an electron-transporting property, or a high molecular organic compound can be used.

As the organic compound material having a hole-transporting property, an aromatic amine compound (namely, a compound having a bond of a benzene ring and nitrogen) such as 4,4′-bis[N-(1-naphthyl)-N-phenyl-amino)-biphenyl (abbreviation: NPB), 4,4′-bis[N-(3-methylphenyl)-N-phenyl-amino)-biphenyl (abbreviation: TPD), 4,4′,4″-tris(N,N-diphenyl-amino)-triphenylamine (abbreviation: TDATA), 4,4′,4″-tris[N-(3-methylphenyl)-N-phenyl-amino]-triphenylamine (abbreviation: MTDATA), or 4,4′-bis(N-(4-(N,N-di-m-tolylamino)phenyl)-N-phenylamino)biphenyl (abbreviation: DNTPD); or a phthalocyanine compound such as phthalocyanine (abbreviation: H₂Pc), copper phthalocyanine (abbreviation: CuPc), or vanadyl phthalocyanine (abbreviation: VOPc) can be used. The substances described above are mainly substances having a hole mobility of 10⁻⁶ cm²/Vs or more.

As the organic compound material having an electron-transporting property, a metal complex having a quinoline skeleton or benzoquinoline skeleton, such as tris(8-quinolinolato)aluminum (abbreviation: Alq₃), tris(4-methyl-8-quinolinolato)aluminum (abbreviation: Almq₃), bis (10-hydroxybenzo[h]-quinolinato)beryllium (abbreviation: BeBq₂), or bis (2-methyl-8-quinolinolato)-4-phenylphenolato-aluminum (abbreviation: BAlq), or the like can be used. In addition, a metal complex material having an oxazole ligand or a thiazole ligand, such as bis[2-(2-hydroxyphenyl)benzoxazolato]zinc (abbreviation: Zn(BOX)₂) or bis[2-(2-hydroxyphenyl)benzothiazolato]zinc (abbreviation: Zn(BTZ)₂), or the like can also be used. Further, as well as the metal complex, 2-(4-biphenylyl)-5-(4-tert-butylphenyl)-1,3,4-oxadiazole (abbreviation: PBD), 1,3-bis[5-p-tert-butylphenyl)-1,3,4-oxadiazol-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproin (abbreviation: BCP) or the like can be used. The substances described above are substances having an electron mobility of 10⁻⁶ cm²/Vs or more.

The layer 104 containing an organic compound is formed to have a single-layer structure or a stacked structure by an evaporation method, a sputtering method, a droplet discharge method, or a spin coating method. In a case where the layer 104 containing an organic compound is formed using a plurality of materials, the materials are deposited at the same time. For example, the layer 104 containing an organic compound can be formed by combining the same kind or different kinds of method such as co-evaporation by resistance-heating evaporation, co-evaporation by electron-beam evaporation, co-evaporation by resistance-heating evaporation and electron-beam evaporation, deposition by resistance-heating evaporation and sputtering, or deposition by electron-beam evaporation and sputtering.

The layer 104 containing an organic compound has a thickness that enables conductivity or a shape thereof to be changed or transformed by optical action or electric action. Specifically, the thickness of the layer 104 containing an organic compound is preferably about 5 nm to 100 nm. Further preferably, the thickness is about 10 nm to 60 nm, 5 nm to 20 nm, or 5 nm to 10 nm.

It is a feature of the present invention that at least one of the pair of the electrode layers (the second electrode layer 106 in this embodiment mode) has a Young's modulus of 7.5×10¹⁰ N/m² or less. The Young's modulus is a sort of an elastic modulus, and the Young's modulus (E) is represented by the following mathematical formula (I).

$$YOUNG ' S MODULUS ( E ) = \frac{STRESS ( T )}{DISTORTION ( ɛ )} \qquad ( 1 )$$

In the above mathematical formula (I), when the equivalent stress (T) is applied, distortion (ε) of a substance becomes enlarged as the Young's modulus becomes low. That is, as a Young's modulus is lower, the substance becomes easy to be transformed.

In this embodiment mode, the second electrode layer 106 has a Young's modulus of 7.5×10¹⁰ N/m² or less, which is lower than a Young's modulus of a metal such as silver (Ag), zinc (Zn), or copper (Cu). Therefore, the second electrode layer 106 is easily transformed along with behavior such as bending. In other words, the second electrode layer 106 is easily influenced by behavior such as bending. Therefore, defects (breakdown of the element) due to behavior such as bending can be prevented, and reliability of the memory element is improved.

It is preferable to reduce the thickness of the second electrode layer 106 because the second electrode layer 106 becomes easier to be influenced by behavior such as bending. Therefore, the thickness of the second electrode layer 106 is preferably reduced as thin as possible within a thickness of the layer capable of serving as an electrode layer. Specifically, the desirable thickness is 10 nm to 200 nm, further preferably, 10 nm to 100 nm.

It is to be noted that a structure of the memory element of the present invention is not particularly limited. For example, as a memory element 110 shown in FIG. 1B, a layer 108 may be provided between a first electrode layer 102 and a layer 104 containing an organic compound. The layer 108 can be formed as a semiconductor layer, an insulating layer, or a metal oxide layer, using a semiconductor material, an insulating material, a metal oxide material, or the like. The layer 108 may be formed of a plurality of layers by combining the above materials. Further, a semiconductor layer, an insulating layer, or a metal oxide layer may be provided between the second electrode layer 106 and the layer 104 containing an organic compound. The thickness of the layer 108 is a thickness for not preventing a completed memory element from storing two values that correspond to an “initial state” and a “state after change” before or after conductivity or a shape of the layer 104 containing an organic compound is changed or transformed.

By providing the layer 108 as shown in FIG. 1B, a distance between the first electrode layer 102 and the second electrode layer 106 can be expanded, and initial defects due to short-circuit between the electrodes can be prevented. In addition, variation in characteristics such as a writing voltage of the memory element can be reduced.

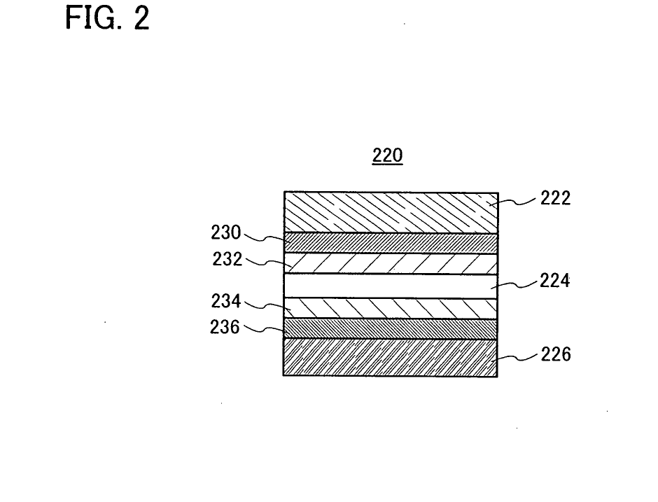

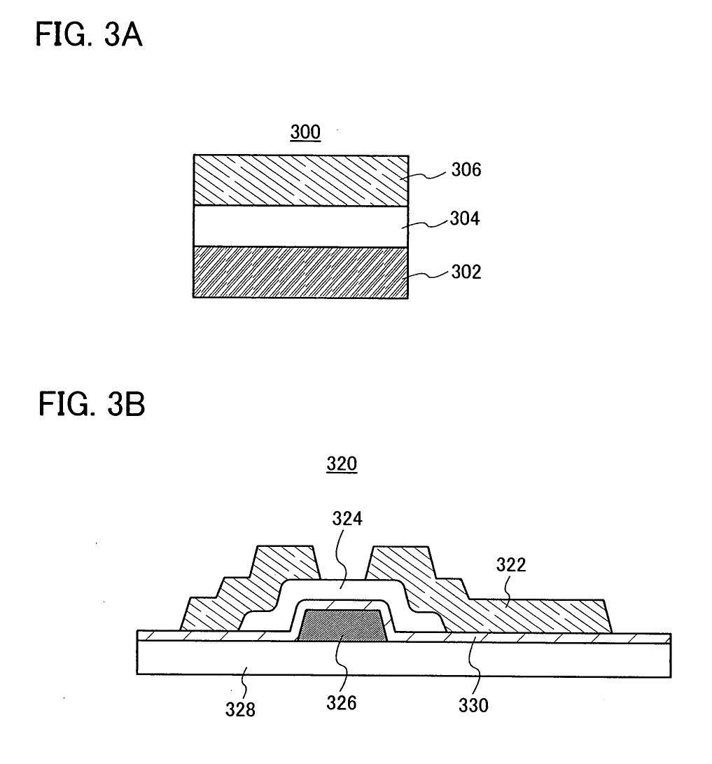

Next, examples of a light-emitting element, a piezoelectric element, and an organic transistor element of the present invention are shown in FIG. 2 and FIGS. 3A and 3B.

A light-emitting element 220 shown in FIG. 2 has a structure in which a first electrode layer 226, an electron-injecting layer 236, an electron-transporting layer 234, a light-emitting layer 224, a hole-transporting layer 232, a hole-injecting layer 230, and a second electrode layer 222 are sequentially stacked. Layers provided between the first electrode layer 226 and the second electrode layer 222 (the electron-injecting layer 236, the electron-transporting layer 234, the light-emitting layer 224, the hole-transporting layer 232, and the hole-injecting layer 230) are formed using organic compounds.

One of the first electrode layer 226 and the second electrode layer 222 is an anode, and the other is a cathode. The anode indicates an electrode layer for injecting holes to the light-emitting layer, and the cathode indicates an electrode layer for injecting electrons to the light-emitting layer. In this embodiment mode, the first electrode 226 is a cathode, and the second electrode 222 is an anode.

The first electrode layer 226 is formed using a conductive material. For example, an element belonging to group 1 or 2 of the periodic table like an alkali metal such as lithium (Li) or cesium (Cs) or an alkaline earth metal such as magnesium (Mg), calcium (Ca), or strontium (Sr); an alloy material containing these elements (Mg—Ag, Al—Li); a rare earth metal such as europium (Er) or ytterbium (Yb); an alloy material containing these elements; or the like can be used. In addition, an element such as gold (Au), platinum (Pt), silver (Ag), copper (Cu), or aluminum (Al); an alloy material or a compound material containing the element; a light-transmitting conductive oxide material such as indium tin oxide (ITO), zinc oxide (ZnO), indium zinc oxide (IZO), or zinc oxide to which gallium is added (GZO); or a conductive oxide material such as indium tin oxide containing silicon oxide (ITSO) or indium oxide containing zinc oxide (ZnO) of 2 to 20 wt % can be used. The first electrode layer 226 can be formed using one of these materials or by combining two or more kinds of these materials.

It is to be noted that a thickness of the first electrode layer 226 is not particularly limited, and it is preferably about 100 nm to 1000 nm, further preferably 200 nm to 500 nm.

The second electrode layer 222 is formed using a conductive material so that the second electrode layer 222 has a Young's modulus of 7.5×10¹⁰ N/m² or less. For example, the second electrode layer 222 is formed using an element, an alloy material, or a compound material of a Young's modulus which is 7.5×10¹⁰ N/m² or less. When an alloy material or a compound material is used, it preferably contains an element of a Young's modulus which is 7.5×10¹⁰ N/m² or less. As the second electrode layer 222, a material of a Young's modulus which is lower is preferably used. For example, for the second electrode layer 222, a metal element such as indium (In), barium (Ba), lead (Pb), calcium (Ca), bismuth (Bi), magnesium (Mg), tin (Sn), or aluminum (Al), or an alloy material or a compound material containing the metal element can be used. As an alloy material containing the metal element, an indium-tin (In—Sn) alloy, an aluminum-magnesium (Al—Mg) alloy, a magnesium-silver (Mg—Ag) alloy, or the like can be used. As a compound containing the metal element, a nitrogen compound, an oxygen compound, a carbon compound, a halogenated compound, or the like can be used. For example, indium tin oxide (ITO), indium zinc oxide (IZO), or indium oxide containing zinc oxide (ZnO) of 2 to 20 wt % can be used. The first electrode layer 222 can be formed using one of these materials or by combining two or more kinds of these materials.

It is to be noted that a thickness of the second electrode layer 222 is not particularly limited, and it is preferably about 10 nm to 200 nm, further preferably, about 10 nm to 100 nm.

The first electrode layer 226 or the second electrode layer 222 is formed to have a single-layer structure or a stacked structure by an evaporation method, a sputtering method, a printing method, or a droplet discharge method.

In order to extract emitted light outside, a light-transmitting conductive oxide material such as indium tin oxide is preferably used for one of or both the first electrode layer 226 and the second electrode 222. Alternatively, silver, aluminum, or the like is deposited to have a thickness of several nm to several tens nm, so that visible light can be transmitted for one of or both the first electrode layer 226 and the second electrode 222, which is also preferable.

The electron-injecting layer 236 is a layer having a function for supporting injection of electrons from the first electrode layer 226 to the electron-transporting layer 234. The electron-injecting layer 236 can be formed using a substance having relatively higher electron affinity than that of a substance used for forming the electron-transporting layer 234, which is selected from substances that can be used for forming the electron-transporting layer 234, such as BPhen, BCP, p-EtTAZ, TAZ, and BzOs. When the electron-injecting layer 236 is formed in such a manner, a difference of electron affinity between the first electrode layer 226 and the electron-transporting layer 234 is relieved, and electrons are easily injected. In addition, the electron-injecting layer 236 may contain an inorganic substance such as alkali metal like lithium (Li), cesium (Cs), or the like; oxide of alkali metal like lithium oxide, potassium oxide, sodium oxide, or the like; oxide of alkaline earth metal like calcium oxide, magnesium oxide, or the like; fluoride of alkali metal like lithium fluoride, cesium fluoride, or the like; fluoride of alkaline earth metal like calcium fluoride or the like; or alkaline earth metal like magnesium (Mg), calcium (Ca), or the like. In addition, the electron-injecting layer 236 may have a structure containing the organic compound such as BPhen, BCP, p-EtTAZ, TAZ, or BzOs or may have a structure containing an inorganic compound such as fluoride of alkali metal such as LiF or fluoride of alkaline earth metal such as CaF₂. By providing the electron-injecting layer 236 as a thin film having a thickness of 1 nm to 2 nm by using an inorganic compound such as fluoride of alkali metal such as LiF or fluoride of alkaline earth metal such as CaF₂, an energy band of the electron-injecting layer 236 is bent, or a tunnel current flows through the electron-injecting layer 236; accordingly, electrons are easily injected from the first electrode layer 226 to the electron-transporting layer 234. It is to be noted that the present invention is not particularly limited, and the electron-injecting layer 236 is not necessarily provided.

The electron-transporting layer 234 is a layer having a function for transporting electrons that are injected from the first electrode layer 226 to the light-emitting layer 224. The electron-transporting layer 234 is provided as described-above, whereby a distance between the first electrode layer 226 and the light-emitting layer 224 can be created. As a result, quenching of light emission caused by metal included in the first electrode layer 226 and the like can be prevented. The electron-transporting layer 234 is preferably formed using an electron-transporting substance, particularly using a substance that has an electron mobility of 1×10⁻⁶ cm²/Vs or more. The electron-transporting substance is a substance whose electron mobility is higher than hole mobility and whose value of a ratio of electron mobility with respect to hole mobility (=electron mobility/hole mobility) is larger than 100. As a specific example of a substance that can be used for forming the electron-transporting layer 234, the following can be given: 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproin (abbreviation: BCP), 4,4-bis(5-methylbenzoxazol-2-yl)stilbene (abbreviation: BzOs), or the like as well as a metal complex such as tris(8-quinolinolato)aluminum (abbreviation: Alq₃), tris(4-methyl-8-quinolinolato)aluminum (abbreviation: Almq₃), bis(10-hydroxybenzo[h]-quinolinato)beryllium (abbreviation: BeBq₂), bis(2-methyl-8-quinolinolato)-4-phenylphenolato-aluminum (abbreviation: BAlq), bis[2-(2-hydroxyphenyl)benzoxazolato]zinc (abbreviation: Zn(BOX)₂), or bis[2-(2-hydroxyphenyl)benzothiazolato]zinc (abbreviation: Zn(BTZ)₂). The electron-transporting layer 234 may have a single-layer structure or a stacked structure in which two or more kinds of these elements are combined. It is to be noted that the present invention is not particularly limited, and the electron-transporting layer 234 is not necessarily provided.

The light-emitting layer 224 is a layer having a light-emitting function, which contains a light-emitting material formed of an organic compound. Alternatively, the light-emitting layer 224 may contain an inorganic compound. The organic compound contained in the light-emitting layer 224 is not particularly limited as long as it is an organic compound with a light-emitting property. Various low molecular organic compounds and high molecular organic compounds can be used. Further, either a fluorescent light-emitting material or a phosphorescent light-emitting material may be used for the organic compound with a light-emitting property. The light-emitting layer 224 may be a layer containing only an organic compound with a light-emitting property or may be a layer that has a structure in which an organic compound with a light-emitting property is dispersed in a host material having a larger energy gap than the organic compound. In a case where the light-emitting layer 224 is a layer in which a plurality of compounds are mixed as a layer containing a light-emitting material formed of the organic compound and the host material, the light-emitting layer 224 can be formed by a co-evaporation method. Here, a co-evaporation method is an evaporation method in which materials are vaporized from a plurality of evaporation sources that are provided in one treatment chamber, and the vaporized materials are mixed in a vapor phase state and then deposited on the object to be processed.

The hole-transporting layer 232 is a layer having a function for transporting holes that are injected from the second electrode layer 222 to the light-emitting layer 224. The hole-transporting layer 232 is provided as described above, whereby a distance between the second electrode layer 222 and the light-emitting layer 224 can be created. As a result, quenching of light emission caused by metal included in the second electrode layer 222 and the like can be prevented. The hole-transporting layer 232 is preferably formed using a hole-transporting substance, particularly using a substance that has a hole mobility of 1×10⁻⁶ cm²/Vs or more. The hole-transporting substance is a substance whose hole mobility is higher than electron mobility and whose value of a ratio of hole mobility with respect to electron mobility (=hole mobility/electron mobility) is preferably larger than 100. As a specific example of a substance that can be used for the hole-transporting layer 232, the following can be given: 4,4′-bis[N-(1-napthyl)-N-phenylamino]biphenyl (abbreviation: NPB), 4,4′-bis[N-(3-methylphenyl)-N-phenylamino]biphenyl (abbreviation: TPD), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis{N-[4-(N,N-di-m-tolylamino)phenyl]-N-phenylamino}biphenyl (abbreviation: DNTPD), 1,3,5-tris[N,N-di(m-tolyl)amino]benzene (abbreviation: m-MTDAB), 4,4′,4″-tris(N-carbazolyl)triphenylamine (abbreviation: TCTA), phthalocyanine (abbreviation: H₂Pc), copper phthalocyanine (abbreviation: CuPc), vanadyl phthalocyanine (abbreviation: VOPc), 4,4′-bis[N-(4-biphenylyl)-N-phenylamino]biphenyl (abbreviation: BBPB), or the like. The hole-transporting layer 232 may have a single-layer structure or a stacked structure in which two or more kinds of these elements are combined. It is to be noted that the present invention is not particularly limited, and the hole-transporting layer 232 is not necessarily provided.

The hole-injecting layer 230 is a layer having a function for supporting injection of holes from the second electrode layer 222 to the hole-transporting layer 232. When the hole-injecting layer 230 is provided, an ionization potential difference between the second electrode layer 222 and the hole-transporting layer 232 is relieved; thus, holes are easily injected. The hole-injecting layer 230 is preferably formed using a substance ionization potential of which is lower than that of a substance forming the hole-transporting layer 232 and higher than that of a substance forming the second electrode layer 222. The hole-injecting layer 230 is also preferably formed using a substance energy band of which is bent by being provided as a thin film having a thickness of 1 nm to 2 nm between the hole-transporting layer 232 and the second electrode layer 222. As a specific example of a substance that can be used for forming the hole-injecting layer 230, a phthalocyanine-based compound such as phthalocyanine (abbreviation: H₂Pc) or copper phthalocyanine (CuPc), a high molecular material such as poly(ethylenedioxythiophene)/poly(styrenesulfonic acid) solution (PEDOT/PSS), and the like can be given. Thus, a substance is selected from hole-transporting substances, so that ionization potential in the hole-injecting layer 230 is relatively lower than that in the hole-transporting layer 232, whereby the hole-injecting layer 230 can be formed. It is to be noted that the present invention is not particularly limited, and the hole-injecting layer 230 is not necessarily provided.

It is to be noted that a hole-generating layer may be provided instead of the hole-injecting layer 230, or an electron-generating layer may be provided instead of the electron-injecting layer 236.

Here, the hole-generating layer is a layer for generating holes. The hole-generating layer can be formed by mixing at least one substance selected from hole-transporting substances and a substance showing an electron accepting property with respect to the hole-transporting substance. As the hole-transporting substance, a similar substance to the substance that can be used for forming the hole-transporting layer 232 can be used. As the substance showing an electron accepting property, metal oxide such as molybdenum oxide, vanadium oxide, ruthenium oxide, or rhenium oxide is preferably used.

The electron-generating layer is a layer for generating electrons. The electron-generating layer can be formed by mixing at least one substance selected from electron-transporting substances and a substance showing an electron donating property with respect to the electron-transporting substance. Here, as the electron-transporting substance, a similar substance to the substance that can be used for forming the electron-transporting layer 234 can be used. As the substance showing an electron donating property, a substance selected from alkali metal or alkaline earth metal, specifically lithium (Li), calcium (Ca), sodium (Na), potassium (K), magnesium (Mg), or the like can be used.

The electron-injecting layer 236, the electron-transporting layer 234, the light-emitting layer 224, the hole-transporting layer 232, and the hole-injecting layer 230 may be each formed by an evaporation method, a droplet discharge method, or a coating method. The first electrode layer 226 or the second electrode layer 222 may be formed by a sputtering method, an evaporation method, or the like.

In this embodiment mode, the light-emitting element 220 may include at least the light-emitting layer 224 between a pair of electrode layers (the first electrode layer 226 and the second electrode layer 222), and layers having other functions (the electron-injecting layer 236, the electron-transporting layer 234, the hole-transporting layer 232, the hole-injecting layer 230, and the like) may be provided as appropriate.

Further, the first electrode layer 226 may be an anode, and the second electrode layer 222 may be a cathode. In this case, a hole-injecting layer, a hole-transporting layer, a light-emitting layer, an electron-transporting layer, and an electron-injecting layer are sequentially stacked from the first electrode layer 226 side.

The second electrode layer 222 included in the light-emitting element 220 has a Young's modulus of 7.5×10¹⁰ N/m² or less, which is lower than a Young's modulus of a metal such as silver (Ag), zinc (Zn), or copper (Cu). Therefore, the second electrode layer 222 is relatively easy to be transformed, and is easily influenced by behavior such as bending of the element. Accordingly, defects due to behavior such as bending can be prevented, and reliability of the light-emitting element is improved.

A piezoelectric element 300 shown in FIG. 3A has a structure in which a first electrode layer 306, a piezoelectric layer 304, and a second electrode layer 302 are sequentially stacked.

The first electrode layer 306 is formed using a conductive material. For example, an element such as gold (Au), silver (Ag), platinum (Pt), nickel (Ni), tungsten (W), chromium (Cr), molybdenum (Mo), iron (Fe), cobalt (Co), copper (Cu), palladium (Pd), carbon (C), aluminum (Al), manganese (Mn), titanium (Ti), or tantalum (Ta), or an alloy material or a compound material containing the element can be used. In addition, a light-transmitting conductive oxide material such as indium tin oxide (ITO), zinc oxide (ZnO), indium zinc oxide (IZO), or zinc oxide to which gallium is added (GZO), or a conductive material such as indium tin oxide containing silicon oxide (ITSO) or indium oxide containing zinc oxide (ZnO) of 2 to 20 wt % can be used. The first electrode layer 306 can be formed using one of these materials or by combining two or more kinds of these materials.

The second electrode layer 302 is formed using a conductive material so that the second electrode layer 302 has a Young's modulus of 7.5×10¹⁰ N/m² or less. For example, the second electrode layer 302 is formed using an element, an alloy material, or a compound material of a Young's modulus which is 7.5×10¹⁰ N/m² or less. When an alloy material or a compound material is used, it preferably contains an element of a Young's modulus which is 7.5×10¹⁰ N/m² or less. Further, as the second electrode layer 302, a material of a Young's modulus which is lower is preferably used.

For example, for the second electrode layer 302, a metal element such as indium (In), barium (Ba), lead (Pb), calcium (Ca), bismuth (Bi), magnesium (Mg), tin (Sn), or aluminum (Al), or an alloy material or a compound material containing the metal element can be used. As an alloy material containing the metal element, an indium-tin (In—Sn) alloy, an aluminum-magnesium (Al—Mg) alloy, a magnesium-silver (Mg—Ag) alloy, or the like can be used. As a compound containing the metal element, a nitrogen compound, an oxygen compound, a carbon compound, a halogenated compound, or the like can be used. The second electrode layer 302 can be formed using one of these materials or by combining two or more kinds of these materials.

It is to be noted that a thickness of the second electrode layer 302 is not particularly limited, and it is preferably about 10 nm to 200 nm, further preferably, 10 nm to 100 nm.

The first electrode layer 306 or the second electrode layer 302 is formed using the above material to have a single-layer structure or a stacked structure by an evaporation method, a sputtering method, a printing method, or a droplet discharge method.

As for the piezoelectric layer 304, an organic piezoelectric material is used. For example, a high molecular organic compound such as polyvinylidene fluoride or a copolymer thereof can be used. The piezoelectric layer 304 may be formed by a sputtering method or an evaporation method.

The second electrode layer 302 included in the piezoelectric element 300 has a Young's modulus of 7.5×10¹⁰ N/m² or less which is lower than a Young's modulus of a metal element such as Ag, Zn, or Cu. Therefore, the second electrode layer 302 is relatively easy to be transformed, and is easily influenced by behavior such as bending of the element. Accordingly, defects due to behavior such as bending can be prevented, and reliability of the piezoelectric element is improved.

An organic transistor element 320 shown in FIG. 3B has a structure in which a gate electrode layer 326, a gate insulating layer 330, an organic semiconductor layer 324, and an electrode layer 322 serving as a source or drain electrode are stacked. First, the gate electrode layer 326 is formed over a substrate 328. The gate insulating layer 330 is formed over the gate electrode layer 326, and the organic semiconductor layer 324 is formed over the gate electrode layer 326 with the gate insulating layer 330 interposed therebetween. The electrode layer 322 serving as a source or drain electrode is formed in contact with the organic semiconductor layer 324.

As for the substrate 328, a glass substrate, a quartz substrate, a semiconductor substrate, a metal substrate, a stainless substrate, or the like is used.

The gate electrode layer 326 is formed using a conductive material. For example, a conductive layer is formed by an evaporation method or a sputtering method, using an element such as platinum (Pt), gold (Au), aluminum (Al), chromium (Cr), nickel (Ni), cobalt (Co), copper (Cu), titanium (Ti), magnesium (Mg), calcium (Ca), or barium (Ba), or an alloy material or a compound material containing the element. Then, the conductive layer is selectively etched, so that the gate electrode layer 326 can be formed. The gate electrode layer 326 may be formed by various printing methods (a method by which a desired pattern is formed, such as screen (mimeograph) printing, offset (planographic) printing, relief printing, or gravure (intaglio) printing), a nanoimprint method, a droplet discharge method, a dispenser method, a selective coating method, or the like. By using such a method, the conductive layer can be selectively formed at the desired portion.

The gate insulating layer 330 is formed using an inorganic insulating material such as silicon oxide, silicon nitride, silicon oxynitride, or silicon nitride oxide, or an organic insulating material such as polyimide. The gate insulating layer 330 may be formed to have a single-layer structure or a stacked structure in which two or more kinds of these elements are combined. It is to be noted that the gate insulating layer 330 may be formed by a CVD method, a sputtering method, a droplet discharge method, a coating method, or the like.

The organic semiconductor layer 324 has a carrier transporting property (hole-transporting property or electron-transporting property) and is formed using an organic compound of which the carrier density (hole density or electron density) is changed by the electric field effect. For example, a low molecular organic compound such as pentacene or naphthacene or a high molecular organic compound such as poly(ethylene dioxythiophene) (PEDOT) or polyphenylenevinylene (PPV) can be used. The organic semiconductor layer 324 may be formed by an evaporation method, a coating method, a droplet discharge method, or the like. When the low molecular organic compound is used, the organic semiconductor layer 324 is preferably formed by an evaporation method.

The electrode layer 322 is formed using a conductive material so that the second electrode layer 322 has a Young's modulus of 7.5×10¹⁰ N/m² or less. For example, the electrode layer 322 is formed using an element, an alloy material, or a compound material of a Young's modulus which is 7.5×10¹⁰ N/m² or less. When an alloy material or a compound material is used, it preferably contains an element of a Young's modulus which is 7.5×10¹⁰ N/m² or less. Further, as the second electrode layer 322, a material of a Young's modulus which is lower is preferably used.

For example, for the electrode layer 322, a metal element such as indium (In), barium (Ba), lead (Pb), calcium (Ca), bismuth (Bi), magnesium (Mg), tin (Sn), or aluminum (Al), or an alloy material or a compound material containing the metal element can be used. As an alloy material containing the metal element, an indium-tin (In—Sn) alloy, an aluminum-magnesium (Al—Mg) alloy, a magnesium-silver (Mg—Ag) alloy, or the like can be used. As a compound containing the metal element, a nitrogen compound, an oxygen compound, a carbon compound, a halogenated compound, or the like can be used. The electrode layer 322 can be formed using one of these materials or by combining two or more kinds of these materials. As the electrode layer 322, a conductive layer is formed by a sputtering method or an evaporation method using the above material, and then the conductive layer is selectively etched, so that the electrode layer 322 can be formed. The electrode layer 322 may be formed by various printing methods (a method by which a desired pattern is formed, such as screen (mimeograph) printing, offset (planographic) printing, relief printing, or gravure (intaglio) printing), a nanoimprint method, a droplet discharge method, a dispenser method, a selective coating method, or the like. By using such a method, the electrode layer can be selectively formed in a desired position. The electrode layer 322 serves as a source or drain electrode.

The electrode layer 322 included in the organic transistor element 320 has a Young's modulus of 7.5×10¹⁰ N/m² or less which is lower than a Young's modulus of a metal element such as Ag, Zn, or Cu. Therefore, the electrode layer 322 is relatively easy to be transformed, and is easily influenced by behavior such as bending of the element. Accordingly, defects due to behavior such as bending can be prevented, and reliability of the element is improved.

As described above, the present invention can be applied to various elements that include a layer containing an organic compound. By applying the present invention, an element in which defects are not easily generated can be provided. When a material for forming the electrode layer is selected in considering electrical characteristics such as work function or electrical resistance depending on characteristics that are necessary for an element to be applied, by applying the present invention and considering a Young's modulus, an element in which defects are not easily generated can be provided. Therefore, since defects of the element can be prevented, reliability of the element can be improved. In addition, the yield in manufacturing the element can be improved.

### Embodiment Mode 2

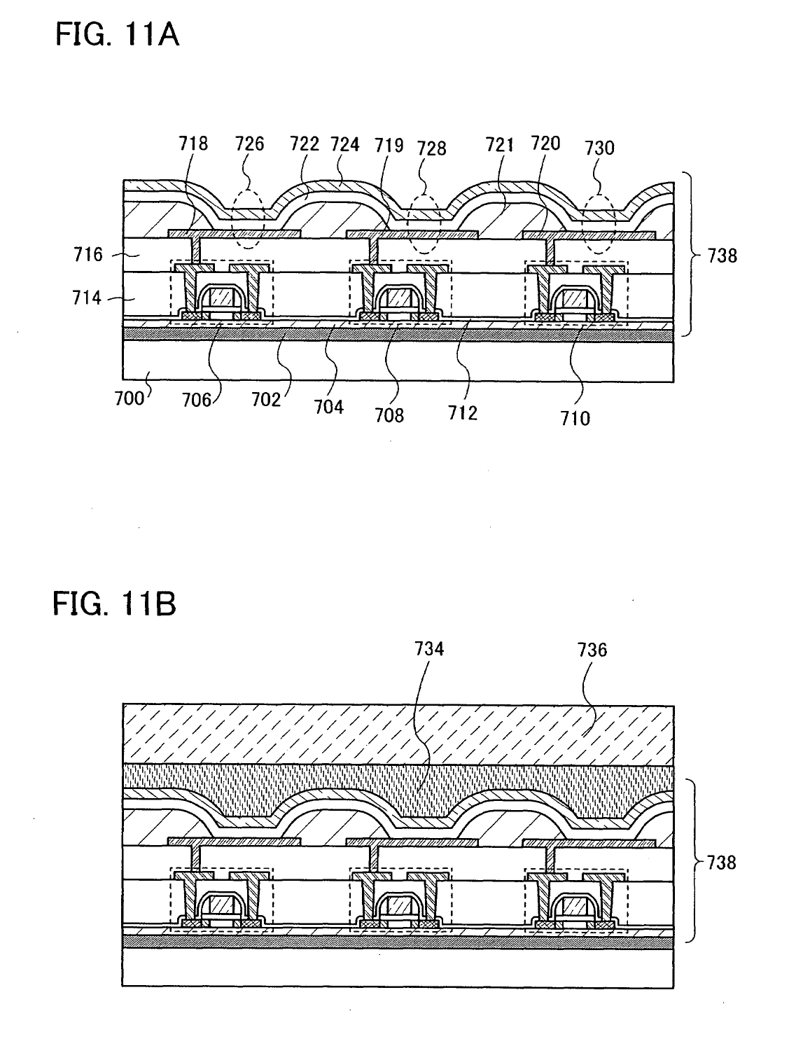

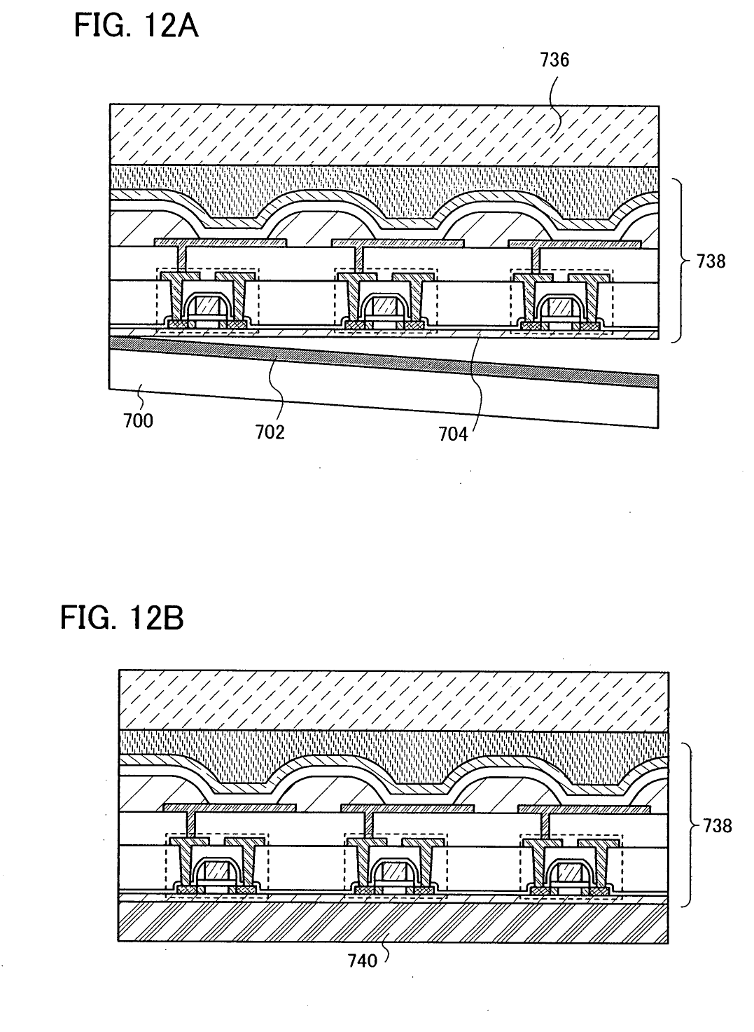

In this embodiment mode, an example of a method for manufacturing a semiconductor device of the present invention will be described with reference to FIGS. 11A to 12B. In a semiconductor device described in this embodiment mode, an element that includes a layer containing an organic compound is provided over a flexible substrate.

As shown in FIG. 11A, a peeling layer 702 is formed over a first substrate 700, and an insulating layer 704 is formed thereover. Then, a semiconductor element is formed over the insulating layer 704. Here, as a semiconductor element, a transistor 706, a transistor 708, and a transistor 710 are formed. A first electrode layer 718, a first electrode layer 719, and a first electrode layer 720 respectively connected to the transistor 706, the transistor 708 and the transistor 710, are formed. A partition layer 721 covering end portions of the first electrode layers 718, 719, and 720 is formed. A layer 722 containing an organic compound is formed over the first electrode layers 718, 719, and 720 and the partition layer 721. Then, a second electrode layer 724 is formed over the layer 722 containing an organic compound, so that an element 726, an element 728, and an element 730, which include the layer containing an organic compound, are formed. An insulating layer 734 serving as a protective layer is formed over the second electrode layer 724. Here, a stacked body, which includes the insulating layer 704 to the second electrode layer 724, is an element formation layer 738.

As for the first substrate 700, a heat-resistance substrate that can withstand a processing temperature of this manufacturing process is used, such as a glass substrate, a quartz substrate, a semiconductor substrate, a metal substrate, or a stainless substrate.

The peeling layer 702 is formed using a metal element such as tungsten (W), molybdenum (Mo), titanium (Ti), tantalum (Ta), niobium (Nb), nickel (Ni), cobalt (Co), zirconium (Zr), zinc (Zn), ruthenium (Ru), rhodium (Rh), palladium (Pd), osmium (Os), or iridium (Ir), or an alloy material or a compound material containing the metal element. Further, the peeling layer 702 can be formed using a material containing silicon (Si). When the peeling layer 702 is formed using silicon, any of an amorphous structure, a microcrystal structure, or a polycrystalline structure may be employed. The peeling layer 702 is formed using these materials to have a single-layer structure or a stacked structure by a sputtering method, a CVD method, a coating method, a printing method, or the like. It is to be noted that the coating method includes a spin coating method and a droplet discharge method.

When the peeling layer 702 is formed to have a single-layer structure, it is preferable to form a tungsten layer, a molybdenum layer, or a layer containing a mixture of tungsten and molybdenum. Alternatively, the peeling layer 702 is formed using a tungsten oxide layer, a tungsten oxynitride layer, a molybdenum oxide layer, a molybdenum oxynitride layer, or a layer containing oxide or oxynitride of a mixture of tungsten and molybdenum. It is to be noted that the mixture of tungsten and molybdenum corresponds to, for example, an alloy of tungsten and molybdenum.

When the peeling layer 702 is formed to have a stacked structure, it is preferable to form a metal layer as a first layer and to form a layer containing metal oxide or metal nitride as a second layer. For example, it is preferable to form a tungsten layer, a molybdenum layer, or a layer containing a mixture of tungsten and molybdenum as a first layer. For example, it is preferable to form a tungsten oxide layer, a tungsten oxynitride layer, a molybdenum oxide layer, a molybdenum oxynitride layer, or a layer containing oxide or oxynitride of a mixture of tungsten and molybdenum as a second layer. It is to be noted that in the peeling layer 702, a first layer and a second layer are sequentially stacked from the first substrate 700 side.

When the peeling layer 702 has a stacked structure of a metal layer and a layer containing metal oxide, a metal layer is formed, and the metal layer is subjected to oxidation treatment, so that a metal oxide layer can be formed. As oxidation treatment, thermal oxidization treatment, oxygen plasma treatment, or treatment with a solution having strong oxidizability such as ozone water may be performed. Alternatively, a metal layer is formed as the peeling layer, and an insulating layer formed from oxide is formed over the metal layer, whereby a layer containing an oxide of the metal (metal oxide layer) can be formed at an interface between the metal layer and the insulating layer. For example, when the peeling layer 702 has a stacked structure of a tungsten layer and a layer containing tungsten oxide, a tungsten layer is formed, and the tungsten layer is subjected to oxidation treatment, so that a layer containing tungsten oxide can be formed. Alternatively, an insulating layer formed from oxide is formed over the tungsten layer, whereby a layer containing tungsten oxide can be formed at an interface between the tungsten layer and the insulating layer. Similarly, an insulating layer containing nitride is formed over the tungsten layer, whereby a layer containing tungsten nitride can be formed at an interface between the tungsten layer and the insulating layer.

Tungsten oxide used in the peeling layer 702 can be expressed by WOX, where x is in the range of 2 to 3, inclusive. The x may be 2 (WO₂), 2.5 (W₂O₅), 2.75 (W₄O₁₁), 3 (WO₃), and the like.

Although the peeling layer 702 is formed to be in contact with the first substrate 700 in this embodiment mode, the present invention is not particularly limited. For example, an insulating layer may be formed to be in contact with the first substrate 700, and the peeling layer 702 may be formed to be in contact with the insulating layer.

The insulating layer 704 is formed using an insulating material such as silicon oxide (SiOₓ), silicon nitride (SiNₓ), silicon oxynitride (SiOₓN_{y}) (x>y), or silicon nitride oxide (SiNₓO_{y}) (x>y>0) by a sputtering method, a CVD method, a coating method, a printing method, or the like to have a single-layer structure or a stacked structure.

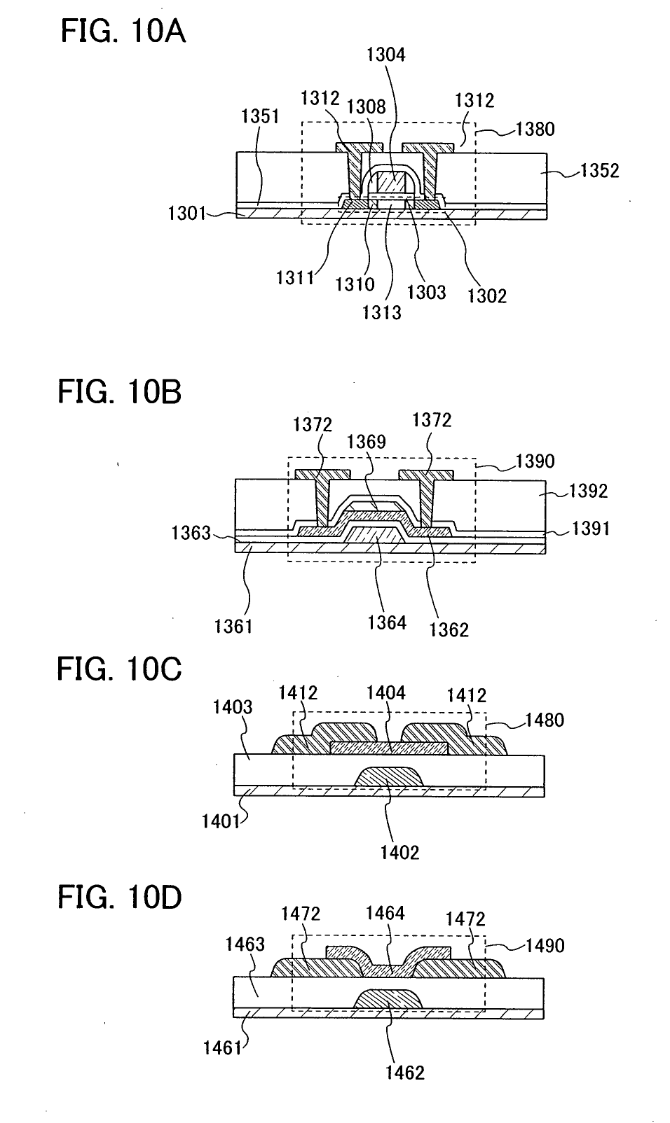

Various transistors can be applied to the transistors 706, 708, and 710. For example, as the transistors 706, 708, and 710, a TFT 1380, a TFT 1390, a TFT 1480, and a TFT 1490 as shown in FIGS. 10A to 10D can be applied. Hereinafter, a specific method for manufacturing a transistor is described with reference to FIGS. 10A to 10D.

The TFT 1380 shown in FIG. 10A shows one example of a top-gate thin film transistor. A thin film transistor is also referred to as a TFT. An insulating layer 1301 is provided over a substrate with a peeling layer interposed therebetween, and the TFT 1380 is provided over the insulating layer 1301.

In the TFT 1380, a semiconductor layer 1302 is formed over the insulating layer 1301, and a gate electrode layer 1304 is formed over the semiconductor layer 1302 with a gate insulating layer 1303 interposed therebetween. An insulating layer 1308 that is also called a sidewall is formed on the side face of the gate electrode layer 1304. An insulating layer 1351 and an insulating layer 1352 serving as interlayer insulating layers are formed over the semiconductor layer 1302 and the gate electrode layer 1304. An electrode layer 1312 that is connected to the semiconductor layer 1302 through the insulating layers 1351 and 1352 is formed. The electrode layer 1312 serves as a source or a drain electrode.

The semiconductor layer 1302 is formed using a semiconductor material. For example, silicon, a material containing silicon as its main component such as silicon germanium, germanium, or the like is used. As the semiconductor layer 1302, a semiconductor layer is formed using a semiconductor material by a CVD method or a sputtering method, and the semiconductor layer is selectively etched, so that an island-shaped semiconductor layer 1302 is formed.

The semiconductor layer 1302 may be formed using either an amorphous semiconductor or a crystalline semiconductor. In this embodiment mode, the semiconductor layer 1302 is formed using a semiconductor having a crystalline structure. As for the layer formed using a semiconductor having a crystalline structure, a crystalline semiconductor formed by crystallization of an amorphous or microcrystalline semiconductor by laser irradiation, a crystalline semiconductor formed by crystallization of an amorphous or microcrystalline semiconductor by heat treatment, or a crystalline semiconductor formed by crystallization of an amorphous or microcrystalline semiconductor by combination of heat treatment and laser irradiation is preferably applied. In heat treatment, a crystallization method using a metal element such as nickel, which has a function for promoting crystallization of a semiconductor, can be employed.

In a case where a crystallized semiconductor layer by heat treatment is formed, an oxide layer of a peeling layer can be formed at an interface between the peeling layer and an insulating layer formed below the semiconductor layer by heat treatment in crystallization. For example, in FIG. 11A, when a metal layer is formed as the peeling layer 702, a surface of the metal layer that is the peeling layer 702 can be oxidized to be formed a metal oxide layer at an interface between the peeling layer 702 and the insulating layer 704, by heat treatment in crystallizing the semiconductor layer included in the transistors 706, 708, and 710 that are formed over the peeling layer 702. In such a manner, by forming an oxide layer (metal oxide layer) of the peeling layer at an interface between the peeling layer 702 and the insulating layer 704, peeling between the peeling layer and the insulating layer can be easily performed in the subsequent peeling step.

In the case of performing crystallization by laser beam irradiation, crystallization can be performed by continuously moving a melted zone of the crystalline semiconductor, which is melted by irradiation with a continuous wave laser beam or a high-repetition-rate ultrashort pulsed laser beam having a repetition rate of 10 MHz or higher and a pulse width of 1 nanosecond or shorter, preferably in the range of 1 to 100 picoseconds inclusive, along the laser beam irradiation direction. By such a crystallization method, a crystalline semiconductor having crystal grains which have a large grain size and have a grain boundary grown in one direction can be obtained. By aligning the drift direction of carriers with the direction in which such a crystal grain boundary is grown, field-effect mobility of the transistor can be increased. For example, 400 cm²/V·sec or higher can be attained.

In a case of employing a crystallization process at a temperature equal to or lower than the allowable temperature limit of a glass substrate (approximately 600° C.) as the above crystallization step, a large-area glass substrate can be used. Therefore, large quantities of semiconductor devices can be manufactured from one substrate, and thus cost reduction can be achieved.

Alternatively, a semiconductor layer 1302 can be formed by performing a crystallization step by heating at a temperature equal to or higher than the allowable temperature limit of a glass substrate. Typically, a quartz substrate is used as the insulating substrate, and an amorphous or microcrystalline semiconductor is heated at 700° C. or higher, thereby forming the semiconductor layer 1302. As a result, a semiconductor with high crystallinity can be formed. Therefore, it is possible to provide a thin film transistor which has excellent characteristics such as a high response speed and high mobility and which can operate at high speed.

In the semiconductor layer 1302, at least a channel formation region and impurity regions serving as a source or drain region are formed. In addition, low concentration impurity regions serving as an LDD (lightly doped drain) region may be formed between the channel formation region and the impurity regions serving as a source or drain region. The impurity region can be formed by adding an element imparting a conductivity type to the semiconductor layer. As an element imparting a conductivity type, an element imparting p-type conductivity or an element imparting n-type conductivity may be added. As the element imparting n-type conductivity, phosphorus (P), arsenic (As), or the like can be used. As the element imparting p-type conductivity, boron (B), aluminum (Al), gallium (Ga), or the like can be used. Here, a channel formation region 1313, high concentration impurity regions 1311 serving as a source or drain region, and low concentration impurity regions 1310 (also referred to as LDD region) are formed in the semiconductor layer 1302. The low concentration impurity region 1310 is formed between the channel formation region 1313 and the high concentration impurity region 1311. An element imparting a conductivity type is added to the high concentration impurity region 1311 so as to have higher concentration than the low concentration impurity region 1310. The channel formation region 1313 is formed to be overlapped with the gate electrode layer 1304 with the gate insulating layer 1303 interposed therebetween, and the low concentration impurity region 1310 is formed to be overlapped with the insulating layer 1308 with the gate insulating layer 1303 interposed therebetween. It is to be noted that the present invention is not particularly limited, and the low concentration impurity region may be formed to be overlapped with the gate electrode layer, or the low concentration impurity region is not necessarily formed.

The gate insulating layer 1303 is formed using an inorganic insulating material such as silicon oxide, silicon nitride, silicon oxynitride, or silicon nitride oxide. The gate insulating layer 1303 is formed using such a material to have a single-layer structure or a stacked structure by a CVD method or a sputtering method. Alternatively, the gate insulating layer 1303 may be formed using a solution having an insulating property by a droplet discharge method, a coating method, a sol-gel method, or the like. As typical examples of the solution having an insulating property, a solution in which inorganic oxide fine particles are dispersed, polyimide, polyamide, polyester, acrylic, PSG (phosphosilicate glass), BPSG (borophosphosilicate glass), silicate-based SOG (Spin on Glass), alkoxy silicate-based SOG, polysilazane-based SOG, or SiO₂ having a Si—CH₂ bond typified by polymethyl siloxane can be appropriately used.

The gate electrode layer 1304 is formed using a conductive material of an element such as tungsten (W), molybdenum (Mo), titanium (Ti), tantalum (Ta), or aluminum (Al); an alloy material or a compound material containing the element; or the like. The gate electrode layer 1304 can be also formed using a polycrystalline semiconductor to which an element imparting a conductivity type is added. A conductive layer having a single-layer structure or a stacked structure is formed using these materials by a CVD method, a sputtering method, an evaporation method, or the like, and the conductive layer is selectively etched, so that the gate electrode layer 1304 can be formed. The gate electrode layer 1304 may be formed by various printing methods (a method by which a desired pattern is formed, such as screen (mimeograph) printing, offset (planographic) printing, relief printing, or gravure (intaglio) printing), a nanoimprint method, a droplet discharge method, a dispenser method, a selective coating method, or the like. By using such a method, a conductive layer that is to be the gate electrode layer 1304 can be selectively formed at the desired portion, and an etching step is unnecessary.

For example, when the gate electrode layer 1304 is formed to have a stacked structure, a layer formed from metal nitride may be formed as a first layer, and a layer formed from a metal element may be formed as a second layer. The gate electrode layer 1304 has a structure in which a first layer and a second layer are sequentially stacked from the gate insulating layer 1303 side. When the gate electrode layer 1304 has such a stacked structure, end portions of the first layer may be projected beyond end portions of the second layer. Further, when the first layer is formed from the metal nitride, the first layer can serve as a barrier metal. That is, such the first layer can prevent the metal element for forming the second layer from dispersing in the gate insulating layer 1303 or the underlying semiconductor layer 1302.

The insulating layer 1308 is formed using an insulating material containing silicon such as silicon oxide. For example, after the gate electrode layer 1304 is formed, an insulating layer is formed using silicon oxide by a CVD method, and the insulating layer is etched by RIE (reactive ion etching) method, so that the insulating layer 1308 can be formed. The insulating layer 1308 is formed on the side face of the gate electrode layer 1304. The insulating layer 1308 is also referred to as a sidewall. It is to be noted that the insulating layer 1308 is not necessarily provided. In this embodiment mode, when the insulating layer 1308 is formed by an etching process, the gate insulating layer 1303 below the insulating layer 1308 is also etched. As a matter of course, only the insulating layer 1308 may be etched.

The insulating layer 1351 and the insulating layer 1352 are formed using an inorganic insulating material such as silicon oxide, silicon nitride, silicon oxynitride, or silicon nitride oxide, or an organic insulating material such as acryl or polyamide to have a single-layer structure or a stacked structure by a sputtering method, a CVD method, a coating method, or the like. For example, the insulating layers 1351 and 1352 can be formed by a coating method such as spin coating or a roll coater. In such a case, after an insulating material in a liquid state is applied, an insulating layer containing silicon oxide can be formed by thermal treatment. Specifically, after a material containing a siloxane bond is applied, thermal treatment at 200 to 400° C. is performed, so that an insulating layer containing silicon oxide can be formed. By forming an insulating layer formed by a coating method or an insulating layer planarized by reflow as the insulating layers 1351 and 1352, disconnection of a wiring to be formed thereover can be prevented. Further, such a method can be effectively used in a case of forming a multilayer wiring. In FIG. 10A, an example in which an interlayer insulating layer has a two-layer structure of the insulating layers 1351 and 1352; however, the present invention is not particularly limited, and the interlayer insulating layer may have a single-layer structure or a stacked structure of three or more layers.

The electrode layer 1312 can be formed using a conductive material of an element such as aluminum (Al), tungsten (W), titanium (Ti), tantalum (Ta), molybdenum (Mo), nickel (Ni), platinum (Pt), copper (Cu), gold (Au), silver (Ag), manganese (Mn), neodymium (Nd), carbon (C), or silicon (Si); an alloy material or a compound material containing the element; or the like can be formed. For example, as an alloy material containing aluminum, an alloy material containing aluminum and nickel or an alloy material containing aluminum, nickel, and one of or both carbon and silicon can be used. As for the electrode layer 1312, a stacked structure of a barrier layer, aluminum-silicon (Al—Si) layer, and a barrier layer or a stacked structure of a barrier layer, an aluminum-silicon (Al—Si) layer, a titanium nitride layer, and a barrier film are preferably employed. Here, the barrier layer corresponds to a layer formed using titanium, a nitride of titanium, molybdenum, or a nitride of molybdenum. Since aluminum and aluminum silicon have low resistance and are inexpensive, they are optimum materials for forming the electrode layer 1312. By providing barrier layers as an upper layer and a lower layer, hillock generation of aluminum or aluminum-silicon can be prevented. In addition, by forming the barrier layer formed from titanium that is a highly-reducible element, even if a thin natural oxide layer is formed over a crystalline semiconductor layer, the natural oxide layer is reduced so that preferable contact with the crystalline semiconductor layer can be obtained. As the formation of the electrode layer 1312, a conductive layer having a single-layer structure or a stacked structure is formed using these materials by a sputtering method, a CVD method, or the like, and the conductive layer is selectively etched, so that the electrode layer 1312 can be formed. Furthermore, the electrode layer 1312 may be formed by various printing methods (a method by which a desired pattern is formed, such as screen (mimeograph) printing, offset (planographic) printing, relief printing, or gravure (intaglio) printing), a nanoimprint method, a droplet discharge method, a dispenser method, a selective coating method, or the like. By using such a method, a conductive layer that is to be the electrode layer 1312 can be selectively formed at the desired portion.

It is to be noted that the insulating layers 1351 and 1352 in FIG. 10A correspond to insulating layers 712 and 714 in FIG. 11A, respectively. Further, the insulating layer 1301 corresponds to the insulating layer 704.

A TFT 1390 shown in FIG. 10B shows an example of a bottom-gate thin film transistor. An insulating layer 1361 is provided over a substrate with a peeling layer interposed therebetween, and the TFT 1390 is provided over the insulating layer 1361.

In the TFT 1390, a gate electrode layer 1364 is formed over the insulating layer 1361, and a semiconductor layer 1362 is formed over the gate electrode layer 1364 with a gate insulating layer 1363 interposed therebetween. A channel protective layer 1369 is formed over the semiconductor layer 1362. An insulating layer 1391 and an insulating layer 1392 serving as an interlayer insulating layer are formed over the semiconductor layer 1362 and the channel protective layer 1369. An electrode layer 1372 connected to the semiconductor layer 1362 through the insulating layers 1391 and 1392 is formed. The electrode layer 1372 serves as a source or drain electrode.

The gate electrode layer 1364, the gate insulating layer 1363, the semiconductor layer 1362, and the electrode layer 1372 are based on description of FIG. 10A and formed using a similar material and method to those of FIG. 10A. The insulating layers 1361, 1391, and 1392 respectively correspond to the insulating layers 1301, 1351, and 1352 and may be formed using a similar material and method.

The channel protective layer 1369 is formed using an inorganic insulating material such as silicon oxide, silicon nitride, silicon oxynitride, or silicon nitride oxide, or an organic insulating material such as acryl or polyimide. An insulating layer is formed by a CVD method or a sputtering method using these materials, and the insulating layer is selectively etched, so the channel protective layer 1369 is formed. Further, an insulating layer serving as the channel protective layer can be selectively formed using a solution having an insulating property by a droplet discharge method, a coating method, a sol-gel method, or the like.

A TFT 1480 shown in FIG. 10C shows an example of a staggered organic semiconductor transistor. An insulating layer 1401 is provided over a substrate with a peeling layer interposed therebetween, and the TFT 1480 is provided over the insulating layer 1401.

In the TFT 1480, a gate electrode layer 1402 is formed over the insulating layer 1401, and an organic semiconductor layer 1404 is formed over the gate electrode layer 1402 with a gate insulating layer 1403 interposed therebetween. An electrode layer 1412 connected to the organic semiconductor layer 1404 is formed over the organic semiconductor layer 1404 and the gate insulating layer 1403. The electrode layer 1412 serves as a source or drain electrode.

The gate electrode layer 1402 can be formed using a similar material and method to those of the gate electrode layer 1304. Alternatively, the gate electrode layer 1402 can be formed by a droplet discharge material and by drying and baking. Further alternatively, a paste including conductive fine particles is printed over the insulating layer 1401 by a printing method, dried, and baked, so that the gate electrode layer 1402 can be formed. As a typical example of the conductive fine particles, a fine particle mainly containing any one of gold, copper, an alloy of gold and silver, an alloy of gold and copper, an alloy of silver and copper, and an alloy of gold, silver, and copper may be used. Alternatively, fine particles mainly containing conductive oxide such as indium tin oxide (ITO) may be used.

The gate insulating layer 1403 can be formed using a similar material and method to those of the gate insulating layer 1303.

The organic semiconductor layer 1404, which has a carrier-transporting property (hole-transporting property or electron-transporting property), is formed using an organic compound of which the carrier density (hole density or electron density) is changed by the electric field effect. For example, a low molecular organic compound such as pentacene or naphthacene or a high molecular organic compound such as poly(ethylene dioxythiophene) (PEDOT) or polyphenylenevinylene (PPV) can be used. The organic semiconductor layer 1404 may be formed using these materials by an evaporation method, a coating method, a droplet discharge method, or the like. When the low molecular organic compound is used, the organic semiconductor layer 1404 is preferably formed by an evaporation method.

The electrode layer 1412 can be formed using a similar material and method to those of the electrode layer 1312.

A TFT 1490 shown in FIG. 10D shows an example of a coplanar organic semiconductor transistor. Am insulating layer 1461 is provided over a substrate with a peeling layer interposed therebetween, and the TFT 1490 is provided over the insulating layer 1461.

In the TFT 1490, a gate electrode layer 1462 is formed over the insulating layer 1461, and a gate insulating layer 1463 is formed over the gate electrode layer 1462. An electrode layer 1472 is formed over the gate insulating layer 1463, and an organic semiconductor layer 1464 is formed over the electrode layer 1472 and the gate insulating layer 1463. The organic semiconductor layer 1464 is formed so as to partially cover the electrode layer 1472 and be connected to the electrode layer 1472. The organic semiconductor layer 1464 faces the gate electrode layer 1462 with the gate insulating layer 1463 interposed therebetween. The electrode layer 1472 serves as a source or drain electrode.

The gate electrode layer 1462, the gate insulating layer 1463, the electrode layer 1472, and the organic semiconductor layer 1464 are based on the description of FIG. 10C and formed using a similar material and method to those of FIG. 10C.

The TFTs 1380, 1390, 1480, and 1490 formed as the above can be applied to the transistors 706, 708, and 710 shown in FIG. 11A.

The first electrode layers 718, 719, and 720 shown in FIG. 11A are formed using a conductive material of an element such as gold (Au), silver (Ag), platinum (Pt), nickel (Ni), tungsten (W), chromium (Cr), molybdenum (Mo), iron (Fe), cobalt (Co), copper (Cu), palladium (Pd), carbon (C), aluminum (Al), manganese (Mn), titanium (Ti), or tantalum (Ta); an alloy material or a compound material containing the element; or the like can be used. In addition, an alkali metal such as lithium (Li) or cesium (Cs), an alkaline earth metal such as magnesium (Mg), calcium (Ca), or strontium (Sr), a rare earth metal such as europium (Er) or ytterbium (Yb), an alloy containing any of these (such as MgAg or AlLi), or the like can be used. Further, a light-transmitting conductive oxide material such as indium tin oxide (ITO), zinc oxide (ZnO), indium zinc oxide (IZO), or zinc oxide to which gallium is added (GZO), or a conductive material such as indium tin oxide including silicon oxide (ITSO) or indium oxide containing zinc oxide (ZnO) of 2 to 20 wt % can be used. As the formation of the first electrode layers 718, 719, and 720, conductive layers having a single-layer structure or a stacked structure are formed using these materials by a sputtering method, a CVD method, an evaporation method, or the like, and the conductive layers are selectively etched, so that the first electrode layers 718, 719, and 720 can be formed. The first electrode layers 718, 719, and 720 may be formed by various printing methods (a method by which a desired pattern is formed, such as screen (mimeograph) printing, offset (planographic) printing, relief printing, or gravure (intaglio) printing), a nanoimprint method, a droplet discharge method, a dispenser method, a selective coating method, or the like. By using such a method, conductive layers that are to be the first electrode layers 718, 719, and 720 can be selectively formed at the desired portion, and an etching step is unnecessary.

The first electrode layers 718, 719, and 720 and the transistors 706, 708, and 710 are respectively connected through an insulating layer 716. The insulating layer 716 serves as an interlayer insulating layer and is formed using an inorganic insulating material such as silicon oxide, silicon nitride, silicon oxynitride, or silicon nitride oxide, or an organic insulating material such as acryl or polyimide. The insulating layer 716 may be formed to have a single-layer structure or a stacked structure using these materials by a sputtering method, a CVD method, a coating method, or the like. As for the insulating layer 716, a planarized insulating layer is preferably formed so as to prevent the first electrode layers 718, 719, and 720 formed thereover from disconnection.

A partition layer 721 is formed using an inorganic insulating material such as silicon oxide, silicon nitride, silicon oxynitride, or silicon nitride oxide, or an organic insulating material such as acryl or polyimide. An insulating layer is formed over the entire surface using these insulating materials by a CVD method, a sputtering method, a coating method, or the like, and the insulating layer is selectively etched, so that the partition layer 721 can be formed. Alternatively, an insulating layer serving as a partition layer can be selectively formed by a droplet discharge method, a printing method, or the like. Further alternatively, after an insulating layer is formed over the entire surface using a photosensitive material, the insulating layer is exposed and developed, so that the layer can be processed into a desired shape. The partition layer 721 preferably has a shape of which end portions have a continuously-changing radius of curvature. By forming the partition layer 721 with such a shape, coverage by the layer to be formed above can be improved.

The layer 722 containing an organic compound is formed using an organic compound of which conductivity is changed or of which a shape is transformed by optical action or electric action. Specifically, the layer 722 containing an organic compound can be formed using an organic compound having a hole-transporting property, an organic compound having an electron-transporting property, or a high-molecular organic compound. The layer 722 containing an organic compound is formed using these elements to have a single-layer structure or a stacked structure by a sputtering method, an evaporation method, a printing method, or a droplet discharge method.

The second electrode layer 724 is formed using a conductive material so as to have a Young's modulus of 7.5×10¹⁰ N/m² or less. For example, the second electrode layer 724 is formed using an element, an alloy material, or a compound material which have a Young's modulus of 7.5×10¹⁰ N/m² or less. When an alloy material and a compound material is used, it preferably contains an element that has Young's modulus of 7.5×10¹⁰ N/m² or less. Further, the second electrode layer 724 preferably has a lower Young's modulus of 7.5×10¹⁰ N/m² or less. Specifically, a metal element such as indium (In), barium (Ba), lead (Pb), calcium (Ca), bismuth (Bi), magnesium (Mg), tin (Sn), or aluminum (Al), or an alloy material or a compound material containing the metal element may be used. The second electrode layer 724 is formed using these materials to have a single-layer structure or stacked structure by a sputtering method, an evaporation method, a printing method, a droplet discharge method, or the like. Although a thickness of the second electrode layer 724 is not particularly limited, and it is preferably about 10 nm to 200 nm, more preferably about 10 nm to 100 nm.

As described, the elements 726, 728, and 730 can be obtained. In this embodiment mode, the elements 726, 728, and 730 serve as memory elements. In such a case, the elements 726, 728, and 730 may be formed using a similar material and method to those of the memory element 100 or the memory element 110 shown in Embodiment Mode 1; therefore, the detailed description is omitted in this embodiment mode. Although an example in which the first electrode layer is formed in contact with the layer containing an organic compound is described in this embodiment mode, an insulating layer, a semiconductor layer, or the like may be provided between the first electrode layer and the layer containing an organic compound. Similarly, an insulating layer, a semiconductor layer, or the like may be provided between the second electrode layer and the layer containing an organic compound.

The present invention is not particularly limited, and the elements 726, 728, and 730, which serve as light-emitting elements, can be also formed by selecting a material for forming the layer 722 containing an organic compound as appropriate.

When the elements 726, 728, and 730 serve as light-emitting elements, a layer having a light-emitting function is formed as the layer 722 containing an organic compound. For example, as the layer 722 containing an organic compound, a light-emitting layer containing a light-emitting material that is formed from an organic compound is formed. The light-emitting layer may contain an inorganic compound. The organic compound contained in the light-emitting layer is not particularly limited as long as it has a light-emitting property, and various low-molecular organic compounds and high-molecular organic compounds can be used. As for the organic compound having a light-emitting property, either a fluorescent material or a phosphorescent material may be used. The light-emitting layer may be a layer formed from only an organic compound having a light-emitting property, or have a structure in which an organic compound having a light-emitting property is dispersed in a host material having a larger energy gap than the organic compound. The layer 722 containing an organic compound may include at least a light-emitting layer, and a hole-transporting layer, a hole-injecting layer, an electron-transporting layer, an electron-injecting layer, and the like may be provided as appropriate. When the elements 726, 728, and 730 serve as light-emitting elements, the light-emitting elements may be formed using a similar material and a similar method to those of the light-emitting layer, a hole-transporting layer, a hole-injecting layer, an electron-transporting layer, and an electron-injecting layer of the light-emitting layer 220 shown in Embodiment Mode 1; therefore, the detailed description is omitted in this embodiment mode.

By forming the layer 722 containing an organic compound using an organic piezoelectric material in the present invention, the elements 726, 728, and 730 can serve as piezoelectric elements. For example, as the layer 722 containing an organic compound, a layer containing an organic piezoelectric material of a high-polymer organic compound such as polyvinylidene fluoride or copolymer thereof can be formed. When the elements 726, 728, and 730 serve as piezoelectric elements, the elements 726, 728, and 730 may be formed using a similar material and method to those of the piezoelectric element 300 shown in Embodiment Mode 1; therefore, the detailed description is omitted in this embodiment mode.

A stacked body including a transistor to the second electrode layer 724 that are formed up to here is an element formation layer 738.

Next, as shown in FIG. 11B, an insulating layer 734 is formed over the second electrode layer 724, and a second substrate 736 is attached to a surface of the insulating layer 734.

The insulating layer 734 is formed of the following: an organic resin such as an acrylic resin, a polyimide resin, a melamine resin, a polyester resin, a polycarbonate resin, a phenol resin, an epoxy resin, polyacetal, polyether, polyurethane, polyamide (nylon), a furan resin, or a diallylphthalate resin; an inorganic siloxane polymer including a Si—O—Si bond among compounds including silicon, oxygen, and hydrogen formed by using a siloxane polymer-based material typified by silica glass as a starting material; or an organic siloxane polymer in which hydrogen bonded to silicon is substituted by an organic group such as methyl or phenyl, typified by an alkylsiloxane polymer, an alkylsilsesquioxane polymer, a silsesquioxane hydride polymer, or an alkylsilsesquioxane hydride polymer. The insulating layer 734 can be formed by applying these materials by a coating method and drying and heating. When the insulating layer 734 is formed by a coating method, an insulating layer with less unevenness can be formed, which is preferable. Alternatively, after an insulating layer such as silicon oxide, silicon nitride, silicon oxynitride, or silicon nitride oxide is formed by a CVD method, a sputtering method, or the like, a surface thereof is polished by a CMP method, so that the insulating layer 734 can be formed. The insulating layer 734 serves as a protective layer in the subsequent peeling step.

Although the second substrate 736 is attached to a surface of the insulating layer 734 in this embodiment mode, the present invention is not particularly limited, and the insulating layer 734 is not necessarily provided. That is, the second substrate 736 may be directly attached to the second electrode layer 724.

As the second substrate 736, a flexible substrate is preferably used. In this specification, the flexible substrate indicates a substrate that can be bent. A thin and lightweight substrate is preferably used. Specifically, a substrate made from PET (polyethylene terephthalate), PEN (polyethylene naphthalate), PES (polyethersulfone), polypropylene, polypropylene sulfide, polycarbonate, polyetherimide, polyphenylene sulfide, polyphenylene oxide, polysulfone, polyphthalamide, or the like can be used. Moreover, paper made from a fibrous material; a multilayer film of a base material film (polyester, polyamide, an inorganic evaporated film, paper, or the like) and an adhesive organic resin film (an acrylic-based organic resin, an epoxy-based organic resin, or the like); or the like can also be used. In a case of using the above substrate as the second substrate 736, an adhesive layer is provided between the insulating layer 734 and the second substrate 736, and the insulating layer 734 and the second substrate 736 are preferably attached to each other.

Alternatively, a film having an adhesive layer (made from polypropylene, polyester, vinyl, polyvinyl fluoride, vinyl chloride, or the like) which is attached to an object to be processed by thermocompression may be used as the second substrate 736. Such a film can be attached to an object to be processed by melting the adhesive layer provided in the outermost surface of the film or a layer (which is not the adhesive layer) provided in the outermost layer of the film by heat treatment and then by applying pressure thereto. In this case, the adhesive layer is not necessarily provided between the insulating layer 734 and the second substrate 736.

Here, the object to be processed indicates a stacked body including the insulating layer 734 to the first substrate 700, and a surface to be processed is not in contact with the second electrode layer 724 on the side of the insulating layer 734.

In this embodiment mode, a composite containing an epoxy resin is applied by a coating method and dried and baked, so that the insulating layer 734 is formed. Next, the insulating layer 734 and the second substrate 736 are attached by thermocompressing a film that is the second substrate 736 to the surface of the insulating layer 734, using a film having an adhesive layer as the second substrate 736.

Next, as shown in FIG. 12A, the peeling layer 702 and the insulating layer 704 are peeled off from each other. In such a manner, the element formation layer 738 that includes the transistors, the elements, and the like are peeled from the first substrate 700, and transposed to the second substrate 736.

A method for peeling the element formation layer 738 from the first substrate 700 can be appropriately selected from the following methods: (1) a method in which a stacked structure of a metal layer and a layer containing metal oxide (or metal nitride) is provided as a peeling layer between the substrate and the element formation layer, the layer containing metal oxide is weakened by crystallization, and the element formation layer is physically peeled from the substrate; (2) a method in which a stacked structure of a metal layer and a layer containing metal oxide (or metal nitride) is provided as a peeling layer between the substrate and the element formation layer, the layer containing metal oxide is weakened by crystallization, part of the peeling layer is etched away using a solution or a halogen fluoride gas such as NF₃, BrF₃, or ClF₃, and the element formation layer is physically peeled from the substrate; (3) a method in which a peeling layer is formed using amorphous silicon containing hydrogen between the substrate and the element formation layer, and the peeling layer is irradiated with a laser beam to discharge a hydrogen gas, so that the substrate is peeled; (4) a method in which a peeling layer is formed using amorphous silicon between the substrate and the element formation layer, and the peeling layer is etched away using a solution or a halogen fluoride gas to be peeled; (5) a method in which a substrate provided with an element formation layer (the first substrate 700 in this embodiment mode) is mechanically shaved, or the substrate provided with an element formation layer is etched away using a solution or a halogen fluoride gas such as NF₃, BrF₃, or ClF₃ to be peeled; and the like. In the above peeling methods (1) and (2), a peeling layer and an insulating layer may be formed between the substrate and the element formation layer, a layer containing metal oxide (or metal nitride) may be provided between the peeling layer and the insulating layer, and then the layer containing metal oxide may be weakened by crystallization. In this embodiment mode, the peeling layer 702 and the insulating layer 704 are formed between the first substrate 700 and the element formation layer 738, a metal oxide layer is provided at an interface between the peeling layer 702 and the insulating layer 704, and the metal oxide layer is weakened by crystallization, whereby the element formation layer 738 is physically peeled from the first substrate 700.

Next, as shown in FIG. 12B, a third substrate 740 is attached to a surface of the insulating layer 704. The third substrate 740 is preferably a flexible substrate. Specifically, a similar substrate to the second substrate 736 is attached to the insulating layer 704 by a similar method. In this embodiment mode, a film is used as the third substrate 740, and the film is bonded with thermocompression to the exposed surface of the insulating layer 704, so that the insulating layer 704 and the third substrate 740 are attached to each other. Through the process, the element that includes the layer containing an organic compound can be transposed to the flexible substrate with the use of a peeling step.

Through the process for transposing element, the element needs to be bent in the step for peeling the element from the substrate (supporting substrate such as a glass substrate), the step for attaching the substrate (flexible substrate) to the element, or the like. The electrode layer included in the element is difficult to be transformed by being influenced by bending of the element when a Young's modulus thereof is high. The flexible substrate and the element are bonded with high adhesion relatively, by a method such as thermocompression. Accordingly, when the electrode layer has a high Young's modulus, on the side which is not in contact with the supporting substrate and is bonded to the flexible substrate, the electrode layer cannot be influenced by behavior such as bending of the substrate or the element, and the element is broken.

It is a feature of the present invention that the second electrode layer has a Young's modulus of 7.5×10¹⁰ N/m² or less, which is not in contact with the supporting substrate and is bonded to the flexible substrate. The electrode layer bonded to the flexible substrate with high adhesion is formed so as to have a Young's modulus of 7.5×10¹⁰ N/m² or less, which is relatively low by applying the present invention, so that the element is easily influenced by behavior of the substrate. As a result, element defects and element breakdown through the transposing process can be prevented from generation. Accordingly, a semiconductor device with high reliability can be manufactured with high yield.

### Embodiment Mode 3

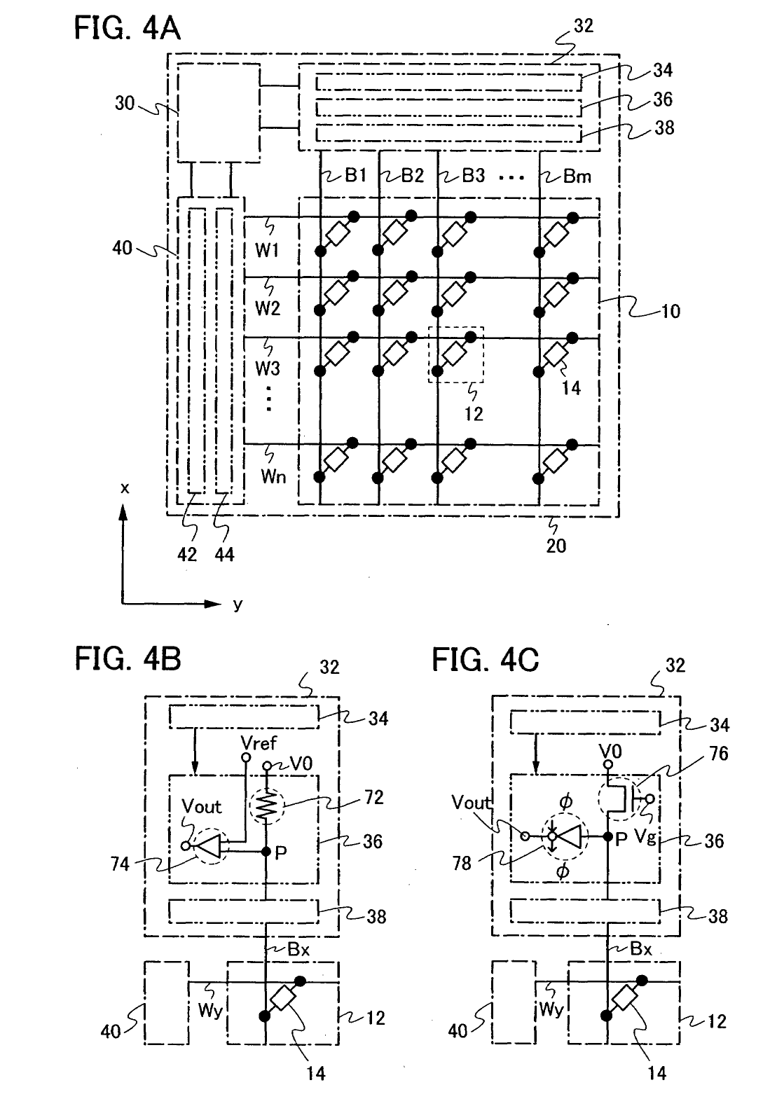

In this embodiment mode, an example of a semiconductor device that has a memory element by the present invention will be described with FIGS. 4A to 6C. Here, an example of a passive-matrix semiconductor device will be described.

FIG. 4A shows an example of a semiconductor device of the present invention, which includes a memory cell array 10, a bit line driver circuit 32, a word line driver circuit 40, and an interface 30 provided over a substrate 20.

The memory cell array 10 is constructed by a plurality of bit lines Bx (1≦x≦m) extending in the x direction and a plurality of word lines Wy (1≦y≦n) extending in the y direction which is perpendicular to the x direction. At intersecting portions of the bit lines Bx and the word lines Wy, memory cells 12 each including a memory element 14 are provided. The memory cells 12 are provided in matrix in the memory cell array 10.

The bit line driver circuit 32 includes a column decoder 34, a reading/writing circuit 36 and a selector 38. In addition, the bit line driver circuit 32 is connected to the bit lines Bx and the interface 30.

The word line driver circuit 40 includes a row decoder 42 and a level shifter 44. In addition, the word line driver circuit 40 is connected to the word lines Wy and the interface 30.

The interface 30 is a circuit which supplies signals inputted from the outside to the bit line driver circuit 32 or the word line driver circuit 40 or which supplies signals outputted from the bit line driver circuit 32 to the outside.

The structure shown in FIG. 4A is just an example, and another circuit such as a sense amplifier, an output circuit or a buffer circuit may be included. Further, a writing circuit may be provided for the interface 30.

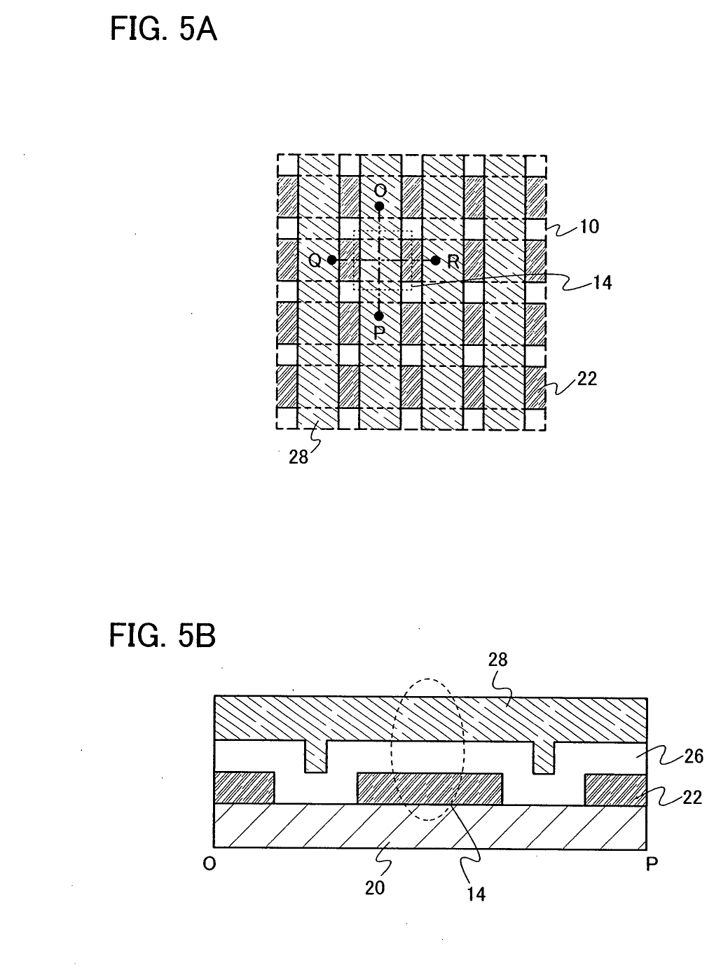

Next, an example of a top view of the memory cell array 10 is shown in FIG. 5A. An example of a cross-sectional view taken along a line O-P of FIG. 5A is shown in FIG. 5B. In FIG. 5A, other than a first electrode layer and a second electrode layer, a structure is partially omitted.

As shown in FIGS. 5A and 5B, the memory cell array 10 is constructed by a first electrode layer 22 forming the bit line Bx and a second electrode layer 28 forming the word line Wy. An intersection portion of the first electrode layer 22 and the second electrode layer 28 in the memory cell array 10 corresponds to the memory cell 12 in FIG. 4A, in which the memory element 14 is formed. As the memory element 14, the memory element as shown in Embodiment Mode 1 or 2 is formed. Specifically, the memory element 14 includes at least a layer containing an organic compound between a pair of electrodes of the first electrode layer and the second electrode layer. At least one of the pair of electrode layers (the second electrode in this embodiment mode) has a Young's modulus of 7.5×10¹⁰ N/m² or less. In this embodiment mode, the memory element 14 has a structure in which a layer 26 containing an organic compound is provided between the first electrode layer 22 and the second electrode layer 28 to be contacted therewith (see FIG. 5B). It is to be noted that the present invention is not particularly limited, and an insulating layer, a semiconductor layer, a metal oxide layer, and the like may be provided between the first electrode layer and the layer containing an organic compound or between the second electrode layer and the layer containing an organic compound.

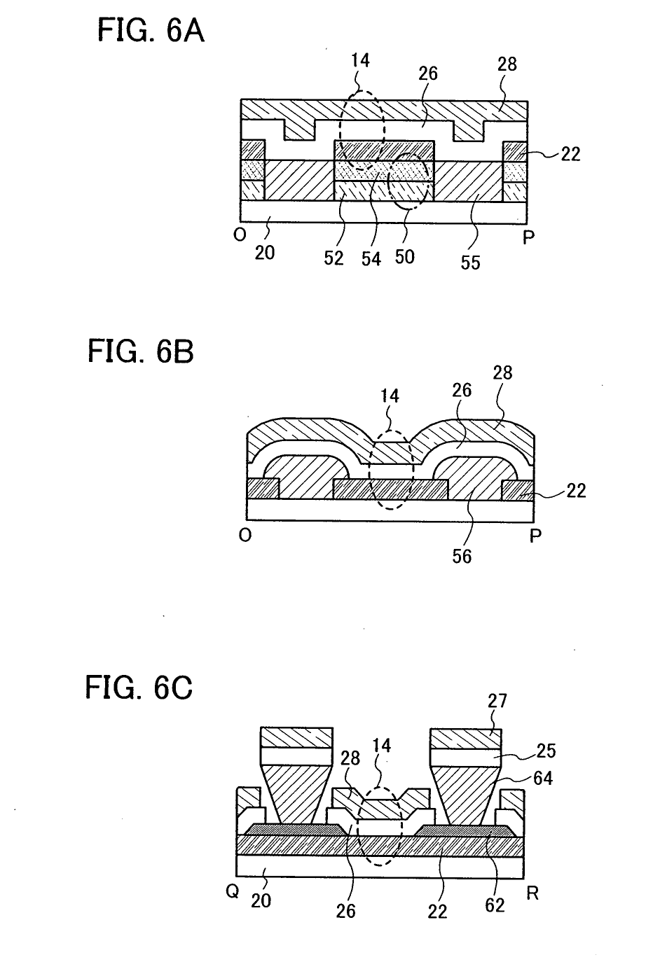

Another example of a structure of the memory cell array 10 is shown in FIGS. 6A to 6C. For example, as shown in FIG. 6A, an element having a rectifying property may be provided on the side opposite to the layer 26 containing an organic compound with the first electrode layer 22 interposed therebetween. As the element having a rectifying property, a schottky diode, a diode having a PN junction, a diode having a PIN junction, an avalanche diode, a transistor in which a gate electrode layer is connected to a drain electrode layer, or the like is given. Alternatively, a diode having another structure may be used. Here, a diode 50 including a third electrode layer 52 and a semiconductor layer 54 is provided to be in contact with the first electrode layer 22. Specifically, the semiconductor layer 54 is provided in contact with the first electrode layer 22, and the third electrode layer 52 is provided in contact with the semiconductor layer 54. That is, the semiconductor layer 54 is interposed between the first electrode layer 22 and the third electrode layer 52. Further alternatively, the element having a rectifying property may be provided on the side opposite to the layer 26 containing an organic compound with the second electrode layer 28 interposed therebetween. For example, a diode may be formed in contact with the second electrode layer 28 by stacking the semiconductor layer and the third electrode layer, sequentially. In such a manner by providing the element having a rectifying property, current flows only in one direction, thereby decreasing errors and improving reading precision. In addition, an insulating layer 55 that insulates diodes is provided between adjacent memory elements.

For example, a thin film transistor (TFT) may be provided over an insulating substrate and the memory element 14 may be provided thereover. Alternatively, a field effect transistor (FET) may be formed over a semiconductor substrate of Si or the like or an SOI (Silicon On Insulator) substrate instead of using the insulating substrate, and the memory element 14 may be provided thereover.

The memory element and a TFT or a FET may be attached. In this case, the memory element and the TFT or the FET are formed in different steps, and then they can be attached using a conductive film, an anisotropic conductive adhesive, and the like. The TFT or the FET may have any structure as long as it is a known structure.

A TFT may be provided over a flexible substrate, and the memory element 14 may be formed thereover. For example, as described in Embodiment Mode 2, after an element formation layer that includes the TFT and the memory element is formed over a supporting substrate with heat resistance that can withstand a processing temperature in the manufacturing process, the element formation layer is peeled from the supporting substrate and transposed to another substrate (a flexible substrate is preferable). Alternatively, after the element formation layer is formed over the supporting substrate, the element formation layer is fixed to another substrate, and the element formation layer may be peeled from the supporting substrate.

If an influence of an electric field in a lateral direction between the adjacent memory elements is concerned, an insulating layer serving as a partition (hereinafter also referred to as a partition layer) may be provided between the layers containing an organic compound provided in each memory element in order to separate the layers containing an organic compound. The layer containing an organic compound may be selectively provided for each memory cell.

For example as shown in FIG. 6B, a partition layer 56 may be provided between the adjacent first electrode layers 22 when providing the layer 26 containing an organic compound to cover the first electrode layers 22. By employing such a structure, disconnection of the layer 26 containing an organic compound caused by a step of the first electrode layer 22 or an influence of an electric field in a lateral direction between the memory cells can be prevented. In a cross section of the partition layer 56, a side surface of the partition layer 56 preferably has a tilt angle of 10° or more and less than 60°, and preferably 25° or more and 45° or less with respect to a surface of the first electrode layer 22. Moreover, it is preferable that the partition layer 56 be curved. Then, the layer 26 containing an organic compound and the second electrode layer 28 are formed so as to cover the first electrode layer 22 and the partition layer 56.

Further, as shown in FIG. 6C, an interlayer insulating layer 62 covering a part of the first electrode layer 22 which is provided over the substrate 20 and extends in the x direction, and a partition layer 64 covering a part of the interlayer insulating layer 62 may be provided. The interlayer insulating layer 62 has an opening where the memory element 14 is provided. Moreover, the partition layer 64 is provided in a region where the opening is not formed, of the interlayer insulating layer 62 so as to extend in the y direction. In a cross section of the partition layer 64, a sidewall of the partition layer 64 has a tilt angle of 95° or more and 135° or less with respect to a surface of the interlayer insulating layer 62.

Although a material of the partition layer 64 is not particularly limited, the partition layer 64 can be formed by photolithography with the use of, for example, a positive photosensitive resin, of which an unexposed portion remains. In this case, the amount of light exposure and developing time are adjusted so that a part lower than the pattern to be a partition layer is etched more; accordingly, the partition layer having a preferable tilt angle can be formed. The partition layer 64 may be formed by forming an insulating layer with the use of an inorganic insulating material, an organic insulating material, or the like and etching the insulating layer selectively.

Moreover, the thickness of the partition layer 64 is set higher than the thickness of the layer 26 containing an organic compound and the second electrode layer 28. As a result, only by the step of providing the layer 26 containing an organic compound and the second electrode layer 28 by evaporation for the entire surface of the substrate 20, memory elements separated in a plurality of regions and being electrically independent can be formed. Specifically, the stripe-shaped layer 26 containing an organic compound and second electrode layer 28 which extend in the y direction and intersect with the first electrode layer 22 which extends in the x direction can be formed. Therefore, the number of steps can be decreased. Although a layer 25 containing an organic compound and a second electrode layer 27 are formed over the partition layer 64, these are separated from the layer 26 containing an organic compound and the second electrode layer 28 which form the memory element 14.

As the substrate 20, a flexible substrate, a glass substrate, a quartz substrate, a semiconductor substrate, a metal substrate, a stainless substrate, or the like can be used. As a flexible substrate, a plastic substrate, paper made from a fibrous material, a film, or the like can be used.

In this embodiment mode, the second electrode layer is formed to have a Young's modulus of 7.5×10¹⁰ N/m² or less, so that the memory element can be influenced by behavior such as bending. As a result, generation of defects of the memory element can be prevented or reduced. Accordingly, a semiconductor device that has a memory element can be manufactured with high yield. In addition, a semiconductor device with high reliability can be provided.

Next, an example of data writing operation in a semiconductor device that has a memory element of the present invention will be described. In the case of writing data in the memory cell 12 which is located in the x-th column and the y-th row among the plurality of memory cells 12 provided in the memory cell array 10 shown in FIG. 4A, for example, a bit line Bx in the x-th column and a word line Wy in the y-th row are first selected by the row decoder 42, the column decoder 34, and the selector 38, and then the memory cell 12 located at an intersecting portion of the bit line Bx and the word line Wy is selected. Then, data is written in the selected memory cell 12 by the writing circuit.

The memory cell 12 includes the memory element 14. The electrical resistance of the memory element 14 changes before or after application of voltage. Accordingly, by utilizing the change in the electrical resistance of the memory element 14, data writing in the memory cell 12 can be selectively conducted.

Specific operation in writing data to a semiconductor device of the present invention will be described with reference to FIGS. 4A to 4C. Data writing is conducted by changing the electrical characteristic such as electrical resistance of the memory cell. It is assumed that an initial state (a state where an electric action is not applied) of the memory cell is data “0” and a state where the electrical characteristic is changed is data “1”.

In the case of writing the data “1” in the memory cell 12, the memory cell 12 is selected first by the row decoder 42, the level shifter 44, the column decoder 34 and the selector 38 which are shown in FIG. 4A. For example, in the case of selecting the memory cell 12 located at an intersecting portion of a bit line B3 and a word line W3, a predetermined voltage V2 is applied to the word line W3 which is connected to the memory cell 12, by the row decoder 42 and the level shifter 44. In addition, the bit line B3 connected to the memory cell 12 is connected to the reading/writing circuit 36 by the column decoder 34 and the selector 38. Then, a writing voltage V1 is output from the reading/writing circuit 36 to the bit line B3. Thus, a voltage Vw (=V1−V2) is applied between the first electrode layer 22 and the second electrode layer 28 which form the memory cell 12. By selecting the voltage Vw appropriately, the layer 26 containing an organic compound provided between the first electrode layer 22 and the second electrode layer 28 which are included in the memory element 14 is changed physically or electrically, so that the data “1” can be written. Specifically, the layer containing an organic compound is changed so that the electrical resistance between the first electrode layer 22 and the second electrode layer 28 in a state of having the data “1” is much smaller than that in a state of having the data “0” at reading operation voltage. For example, V1 is set to 0 V and V2 is appropriately selected from 5 to 15 V. Alternatively, V1 is appropriately selected from 3 to 5 V, and V2 is appropriately selected from −12 to −2 V. The voltage Vw may be set in the range of 5 to 15 V or −5 to −15 V.

Non-selected word lines and non-selected bit lines are controlled so that the data “1” is not written in the memory cells connected to the non-selected word lines and the non-selected bit lines. For example, the non-selected word lines and the non-selected bit lines may be set in a floating state. It is necessary to include a layer having a characteristic capable of securing selectivity such as a diode characteristic between the first electrode layer 22 and the second electrode layer 28 which form the memory cell.

On the other hand, in the case of writing the data “0” in the memory cell 12, electric action is not applied to the memory cell 12. In circuit operation, the memory cell 12 is selected by the row decoder 42, the level shifter 44, the column decoder 34, and the selector 38 similarly to the case of writing the data “1”; however, an output potential from the reading/writing circuit 36 to the bit line B3 is set to be similar to a potential of the selected word line W3 or potentials of the non-selected word lines and voltage of such a degree that the electrical characteristic of the memory cell 12 does not change (for example, −5 to 5 V) may be applied between the first electrode layer 22 and the second electrode layer 28 which form the memory cell 12.

Then, specific operation for reading data from the semiconductor device of the present invention is described. Data reading is conducted by using the difference between the memory cell having the data “0” and the memory cell having the data “1” in the electrical characteristic between the first electrode layer and the second electrode layer which form the memory cell. For example, effective electrical resistance between the first electrode layer and the second electrode layer which form the memory cell having the data “0” (hereinafter the effective electrical resistance is simply referred to as electrical resistance of the memory cell) is assumed to be R0 at the reading voltage, while the electrical resistance of the memory cell having the data “1” is assumed to be R1 at the reading voltage, and a method of reading the data by using the difference in the electrical resistance will be described. It is assumed that the relation, R1<<R0, is made. As a configuration of a reading portion of the reading/writing circuit 36, a circuit using a resistor element 72 and a differential amplifier 74 shown in FIG. 4B can be used. The resistor element 72 has a resistance value Rr, and it is assumed that the relation, R1<Rr<R0, is made. As shown in FIG. 4C, a transistor 76 may be provided instead of the resistor element 72 and a clocked inverter 78 can be provided instead of the differential amplifier. A signal φ or an inverted signal φ, which becomes High when reading is conducted and Low when reading is not conducted, is inputted to the clocked inverter 78. The circuit configuration is not limited to those in FIGS. 4B and 4C.

In the case of reading data from the memory cell 12, the memory cell 12 is first selected by the row decoder 42, the level shifter 44, the column decoder 34 and the selector 38. Specifically, a predetermined voltage Vy is applied to the word line Wy connected to the memory cell 12, by the row decoder 42 and the level shifter 44. In addition, the bit line Bx connected to the memory cell 12 is connected to a terminal P of the reading/writing circuit 36 by the column decoder 34 and the selector 38. As a result, a potential Vp of the terminal P is set to be a value that is determined by resistance division by the resistor element 72 (resistance value Rr) and the memory cell 12 (resistance value R0 or R1). Accordingly, if the memory cell 12 has the data “0”, Vp0=Vy+(V0−Vy)×R0/(R0+Rr). If the memory cell 12 has the data “1”, Vp1=Vy+(V0−Vy)×R1/(R1+Rr). Therefore, Vref is selected so as to have a value between the Vp0 and the Vp1 in FIG. 4B and a point of change of the clocked inverter is selected so as to be between the Vp0 and the Vp1 in FIG. 4C. Accordingly, Low/High (or High/Low) is output as an output potential Vout in accordance with the data “0” or data “1”, thereby conducting data reading.

For example, the differential amplifier 74 is operated at Vdd=3 V, and the Vy is set to be 0 V, the V0 is set to be 3 V, and the Vref is set to be 1.5 V. If R0/Rr=Rr/R1=9, in the case where the memory cell has the data “0”, the Vp0 is 2.7 V and High is output as the Vout, while in the case where the memory cell has the data “1”, the Vp1 is 0.3 V and Low is output as the Vout. Thus, data reading from the memory cell can be conducted.

According to the above method, the state of the electrical resistance of the memory element 14 is read by the voltage value, using the difference in the resistance value and the resistance division. The reading method is not limited to this method. For example, instead of the method using the difference in the electrical resistance, a reading method using a difference in a current value is also applicable. Alternatively, in the case where the electrical characteristic of the memory cell has a diode characteristic in which threshold voltage varies between the data “0” and “1”, the difference in the threshold voltage may be used for reading. Furthermore, a method in which resistance of a memory element is regarded as an amount of current to be read or a method in which a bit line is precharged can also be employed.

By applying the present invention, defects of the memory element can be prevented from generation. Therefore, in manufacturing a semiconductor device that has the memory element, the yield can be improved. Further, a semiconductor device with high reliability can be provided.

It is possible to provide a semiconductor device that has a memory element in which writing of data (additional recording) at a time other than a manufacturing process is possible and forgery caused by rewriting of data can be prevented.

This embodiment mode can be freely combined with Embodiment Mode 1 or 2.

### Embodiment Mode 4

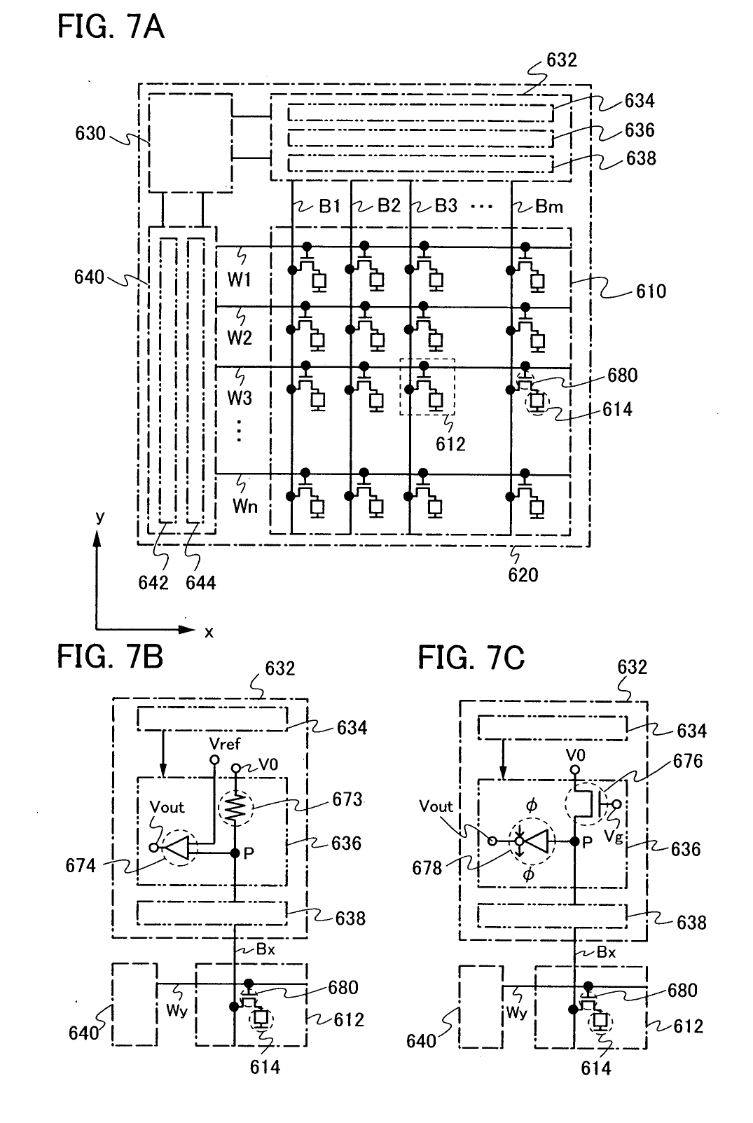

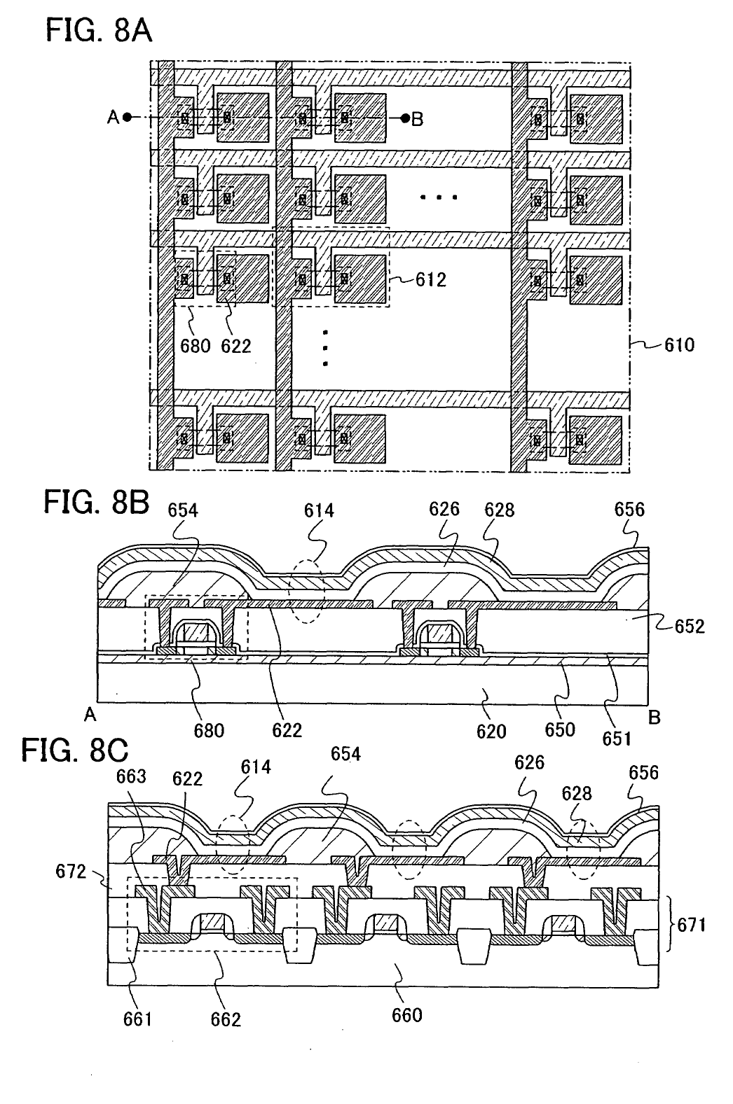

In this embodiment mode, an example of a semiconductor device that has a memory element of the present invention will be described with reference to FIGS. 7A to 8C. Here, an active-matrix semiconductor device will be described.

FIG. 7A shows an example of a semiconductor device of the present invention, in which a memory cell array 610, a bit line driver circuit 632, a word line driver circuit 640, and an interface 630 are included over a substrate 620.

The memory cell array 610 is constructed by a plurality of bit lines Bx (1≦x≦m) extending in the x direction and a plurality of word lines Wy (1≦y≦n) extending in the y direction which is perpendicular to the x direction. At intersecting portions of the bit lines Bx and the word lines Wy, memory cells 612 each including a transistor 680 and a memory element 614 are provided. The memory cells 612 are provided in matrix in the memory cell array 610.

The bit line driver circuit 632 includes a column decoder 634, a reading/writing circuit 636, and a selector 638. In addition, the bit line driver circuit 632 is connected to the bit lines Bx and the interface 630.

The word line driver circuit 640 includes a row decoder 642 and a level shifter 644. In addition, the word line driver circuit 640 is connected to the word lines Wy and the interface 630.

The interface 630 is a circuit which supplies signals inputted from the outside to the bit line driver circuit 632 or the word line driver circuit 640 or which supplies signals outputted from the bit line driver circuit 632 to the outside.

The structure shown in FIG. 7A is just an example, and another circuit such as a sense amplifier, an output circuit, or a buffer circuit may be included. Further, a writing circuit may be provided for the interface 630.

Next, the memory cells 612 will be described in detail with reference to FIGS. 8A to 8C. FIG. 8A shows an example of a top view of the memory cell array 610. FIG. 8B shows an example of a cross-sectional view taken along a line A-B of FIG. 8A. In the top view of FIG. 8A, structures other than transistors and first electrode layers are partially omitted.

Each of the memory cells 612 includes a first electrode layer 622 connected to the bit line Bx (1≦x≦m), a second electrode layer 628 connected to the word line Wy (1≦y≦n), the memory element 614, and the transistor 680. The memory element 614 has a structure shown in Embodiment Mode 1. Specifically, the memory element 614 includes at least a layer containing an organic compound between a pair of electrode layers of the first electrode layer and the second electrode layer. At least one of the pair of the electrode layers (the second electrode layer, in this embodiment mode) has a Young's modulus of 7.5×10¹⁰ N/m² or less. A gate electrode layer of the transistor 680 is connected to the word line Wy, one of source or drain electrode layers is connected to the bit line Bx, and the other one is connected to one of two terminals included in the memory element 614. The other terminal of the memory element is connected to a common electrode (potential Vcom).

For example, as shown in FIG. 8B, the memory element 614 can be formed over the substrate 620 over which the transistor 680 is provided. As the memory element 614, a memory element 614 shown in Embodiment Mode 1 is formed. Specifically, the memory element 614 has a structure in which the first electrode layer 622, a layer 626 containing an organic compound, and the second electrode layer 628 are sequentially stacked. A partition layer 654 that covers end portions of the first electrode layers 622 is provided between the adjacent first electrode layers 622. In this embodiment mode, an insulating layer 656 serving as a protective layer is provided over the memory element 614. The memory element 614 may also have a structure in which an insulating layer or a semiconductor layer is provided between the first electrode layer 622 and the layer 626 containing an organic compound as shown in FIG. 1B of Embodiment Mode 1.

The transistor 680 is provided over the substrate 620 with a base insulating layer 650 interposed therebetween. Further, an electrode layer serving as the source electrode or the drain electrode of the transistor 680 is connected to the first electrode layer 622 of the memory element 614.

As the transistor 680 in this embodiment mode, various transistors can be applied. For example, the TFT 1380, the TFT 1390, the TFT 1480, or the TFT 1490 as shown in FIGS. 10A to 10D can be applied. The specific structure, manufacturing method and the like of the transistors of FIGS. 10A to 10D are based on description of Embodiment Mode 2; therefore, description thereof is omitted here. Insulating layers 651 and 652 in FIG. 8B may be formed using a similar material and method to those of the insulating layers 1351 and 1352 in FIG. 10A. In this embodiment mode, the top-gate TFT 1380 shown in FIG. 10A is applied as the transistor 680.

In the TFT 1380 applied as the transistor 680, the semiconductor layer 1302 is formed, and the gate electrode layer 1304 is formed over the semiconductor layer 1302 with the gate insulating layer 1303 therebetween. Further, the insulating layer 1308 (sidewall) is formed at side faces of the gate electrode layer 1304. The insulating layers 1351 and 1352 serving as an interlayer insulating layer are formed over the semiconductor layer 1302, the gate electrode layer 1304, and the insulating layer 1308. The electrode layer 1312 connected to the semiconductor layer 1302 through the insulating layers 1351 and 1352 is formed. In the semiconductor layer 1302, a channel formation region, an impurity region serving as a source or drain region, and a low concentration impurity region serving as an LDD region are formed.

Although the electrode layer 1312 in FIG. 10A serves as a source or drain electrode, the electrode layer 1312 also serves as an electrode layer included in the memory element in this embodiment mode. In other words, in FIG. 8B, the electrode layer serving as a source or drain electrode of the transistor 680 and the first electrode layer 622 included in the memory element 614 are formed of the same layer. The electrode layer serving as a source or drain electrode of the transistor 680 can be provided to be intersected with a wiring formed of the same layer as the gate electrode layer of the transistor 680, and a multilayer wiring structure can be formed. Furthermore, a plurality of insulating layers similar to the insulating layer 652 are stacked, and a wiring is formed thereover, so that a multilayer wiring structure can be formed. The first electrode layer 622 is preferably formed by combining a low-resistance material such as aluminum (Al), and a barrier metal using a metal material that has a high melting point such as titanium (Ti) or molybdenum (Mo) to have a stacked structure of titanium (Ti) and aluminum (Al), a stacked structure of molybdenum (Mo) and aluminum (Al), or the like.

Alternatively, the transistor 680 may have a multi-gate structure that has a semiconductor layer including at least two or more channel formation regions connected in series and at least two or more gate electrode layers for applying a voltage to each channel formation region. Further alternatively, the transistor 680 may have a dual-gate structure where a semiconductor layer is interposed between upper and lower gate electrodes.

The thin film transistors and the organic semiconductor transistors shown in FIGS. 10A to 10D may have any structure as long as they serve as a switching element.

Furthermore, a transistor may be formed using a single crystalline substrate or an SOI substrate, and a memory element may be provided thereover. The SOI substrate may be formed by using a bonding method and an ion implantation method called SIMOX. A bonding method is a method in which a substrate where an oxide film is formed over a surface and a substrate where an oxide film is not formed over a surface are bonded, and the surface of one of the substrates is shaved. The ion implantation method is a method in which an insulating layer is formed inside a Si substrate by implanting oxygen ions into the Si substrate. For example, as shown in FIG. 8C, a field effect transistor 662 is formed using a single crystalline semiconductor substrate 660, and the memory element 614 is provided thereover. Here, an electrode layer 663 connected to an impurity region of the field effect transistor 662 and the first electrode layer 662 of the memory element 614 are connected, so that the field effect transistor 662 and the memory element 614 are connected. Further, an insulating layer 672 is provided so as to cover the electrode layer 663 serving as a source or drain electrode of the field effect transistor 662, and the memory element 614 is provided over the insulating layer 672. The field effect transistors 662 are separated from each other by a field oxide film 661.

Since the transistor formed using a single crystalline semiconductor has excellent characteristics such as high response speed and good mobility, the transistor can operate at high speed. Further, such transistors have only little variation in its characteristics, and therefore, a highly-reliable semiconductor device can be provided.

When the electrode layer serving as a source or drain electrode of the transistor and the first electrode layer included in the memory element are formed of the same layer shown in FIG. 8B, the memory element is needed to be provided in a region that is not an upper part of the transistor. On the other hand, as shown in FIG. 8C, the insulating layer is formed over the electrode layer serving as a source or drain electrode of the transistor, the first electrode layer included in the memory element is formed over the insulating layer, and the electrode layer of the transistor and the first electrode layer of the memory element are connected through the insulating layer, so that the memory element can be freely located.

Although an example in which the layer 626 containing an organic compound is provided over an entire surface of the substrate is shown in the structures shown in FIGS. 8C and 8C, the layer containing an organic compound may be selectively provided only in each memory cell. In this case, the layer containing an organic compound is selectively provided by discharging an organic compound using a droplet discharge method or the like and baking it, whereby the use efficiency of materials can be improved.

A specific structure, manufacturing method, and the like of the memory element 614 are based on description of Embodiment Modes 1 to 3. More specifically, the memory element 614 may be formed using a similar material and method to the memory elements 100 and 110, the elements 726, 728, and 730 serving as the memory element, and the memory element 14 shown in Embodiment Modes 1 to 3.

The partition layer 654 can be provided using a similar material and method to those of the partition layers 56 and 721 shown in Embodiment Modes 2 and 3.

In the memory element in this embodiment mode, the second electrode layer has a Young's modulus of 7.5×10¹⁰ N/m² or less, so that the memory element can become to be easily influenced by behavior such as bending. As a result, generation of defects of the memory element can be prevented or reduced. Accordingly, a semiconductor device that has a memory element can be manufactured with high yield. In addition, a semiconductor device with high reliability can be provided.

Next, specific operation when conducting data writing in a semiconductor device of the present invention will be described with reference to FIGS. 7A to 7C. It is to be noted that writing is conducted by changing the electrical characteristic of a memory cell, and it is assumed that an initial state (state where an electric action is not applied) of the memory cell is data “0”, and a state where the electrical characteristic is changed is data “1”.

Here, a case where data is written in the memory cell 612 in the third column and the third row will be described. When data “1” is written in the memory cell 612, the memory cell 612 is selected by the row decoder 642, the column decoder 634, and the selector 638. Specifically, predetermined voltage V22 is applied to a word line W3 connected to the memory cell 612 by the row decoder 642. Further, a bit line B3 connected to the memory cell 612 is connected to the reading/writing circuit 636 by the column decoder 634 and the selector 638. Then, writing voltage V21 is outputted to the bit line B3 from the reading/writing circuit 636.

Thus, the transistor 680 forming the selected memory cell 612 is made in an ON state, and the bit line is electrically connected to the memory element 614, and voltage Vw (Vw is almost equal to Vcom−V21) is applied. Further, one of the electrodes of the memory element 614 is connected to a common electrode having a potential Vcom. By appropriately selecting the potential Vw, the layer containing an organic compound provided between the first electrode layer included and the second electrode layer in the memory element 614 is physically or electrically changed, and thus, the data “1” can be written. Specifically, at reading operation voltage, electrical resistance between the first electrode layer and the second electrode layer in the state of the data “1” is preferably reduced significantly as compared to that in a state of the data “0”, or a short circuit may simply be generated between the first electrode layer and the second electrode layer. It is to be noted that the potential V21 may be appropriately selected from 5 to 15V, the potential V22 may be appropriately selected from 5 to 15 V, and the potential Vcom may be set at 0 V. Alternatively, the potential V21 may be appropriately selected from −12 to 0 V, the potential V22 may be appropriately selected from −12 to 0 V, and the potential Vcom may be appropriately selected from 3 to 5 V. The voltage Vw may be set to be 5 to 15 V, or −5 to −15 V.

It is to be noted that non-selected word lines and non-selected bit lines are controlled such that the data “1” is not written in the memory cells connected to the non-selected word and bit lines. Specifically, a potential (e.g., 0 V) by which transistors of memory cells connected to the non-selected word lines are made in an OFF state, may be applied to the non-selected word lines whereas the non-selected bit lines may be set in a floating state or applied with a potential, which is the same level as Vcom.

On the other hand, when the data “0” is written in the memory cell 612, no electric action may be applied to the memory cell 612. In circuit operation, for example, in a similar manner to the case of writing the data “1”, the memory cell 612 is selected by the row decoder 642, the column decoder 634 and the selector 638; however, an output potential, which is the same level as Vcom, is applied to the bit line B3 from the reading/writing circuit 636, or the bit line B3 is set to be in a floating state. Then, low voltage (e.g., about −5 to 5 V) is applied to the memory element 614, or no voltage is applied to the memory element 614; therefore, an electrical characteristic of the memory element is not changed and writing of the data “0” can be realized.

Next, operation in reading data by an electric action will be described. Data is read by utilizing difference in electrical characteristics of the memory elements 614 between a memory cell having data “0” and a memory cell having data “1”. For example, a method for reading data by utilizing difference in electrical resistance will be described under conditions where electrical resistance of a memory element included in a memory cell having the data “0” is assumed to be R0 at reading voltage, and electrical resistance of a memory element included in a memory cell having the data “1” is assumed to be R1 at reading voltage. It is assumed that the relation, R1<<R0, is made. As a structure of a reading portion of the reading/writing circuit, for example, the reading/writing circuit 636 including the resistor element 673, and the differential amplifier 674 shown in FIG. 7B can be given. The resistor element has a resistance value Rr, and it is assumed that the relation, R1<Rr<R0, is made. As shown in FIG. 7C, a transistor 676 may be provided instead of the resistor element 673 and a clocked inverter 678 may be provided instead of the differential amplifier 674. The circuit configuration is not limited to those in FIGS. 7B and 7C.

When data is read from the memory cell 612 in the x-th column and the y-th row, the memory cell 612 is selected by the row decoder 642, the column decoder 634, and the selector 638. Specifically, predetermined voltage V24 is applied to a word line Wy connected to the memory cell 612 by the row decoder 642, and the transistor 680 is turned on. A bit line Bx connected to the memory cell 612 is connected to a terminal P of the reading/writing circuit 636 by the column decoder 634 and the selector 638. As a result, a potential Vp of the terminal P becomes a value which is determined by resistance division of Vcom and V0 by the resistor element 673 (resistance value Rr) and the memory element 614 (resistance value R0 or R1). Therefore, in the case where the memory cell 612 has the data “0”, the relation, Vp0=Vcom+(V0−Vcom)×R0/(R0+Rr), is given. When the memory cell 612 has the data “1”, the relation, Vp1=Vcom+(V0−Vcom)×R1/(R1+Rr), is given. As a result, Vref is selected so as to have a value between the Vp0 and the Vp1 in FIG. 7B, and a point of change of the clocked inverter 678 is selected so as to be between the Vp0 and the Vp1 in FIG. 7C. Accordingly, Low/High (or High/Low) is outputted as an output potential Vout in accordance with the data “0” or data “1”, thereby conducting data reading.

For example, it is assumed that the differential amplifier 674 is operated at Vdd=3V, and the Vcom is set to be 0 V; the V0 is set to be 3 V; and the Vref is set to be 1.5 V. If R0/Rr=Rr/R1=9 and on-resistance of the transistor 680 can be ignored, in a case where a memory cell has the data “0”, Vp0 is 2.7 V and High is outputted as the Vout. Meanwhile, in the case where the memory cell has the data “1”, the Vp1 is 0.3 V and Low is output as the Vout. Thus, data reading from the memory cell can be conducted.

According to the aforementioned method, reading is conducted with a voltage value by utilizing a difference in the resistance value of the memory element 614 and resistance division. Needless to say, the reading method is not limited to this. For example, other than using the difference in an electrical resistance, reading may be conducted by using the difference in a current value. Alternatively, in the case where the electrical characteristic of the memory cell has a diode characteristic in which threshold voltage varies between the data “0” and “1,” the difference in the threshold voltages may be used for reading.

By applying the present invention, defects of the memory element can be prevented from generation. Therefore, in manufacturing a semiconductor device that has the memory element, the yield can be improved. Further, a semiconductor device with high reliability can be provided.

It is possible to provide a semiconductor device having a memory element in which writing of data (additional recording) at a time other than a manufacturing process is possible and forgery caused by rewriting of data can be prevented.

It is to be noted that this embodiment mode can be combined with Embodiment Mode 1 and 2 as appropriate.

### Embodiment Mode 5

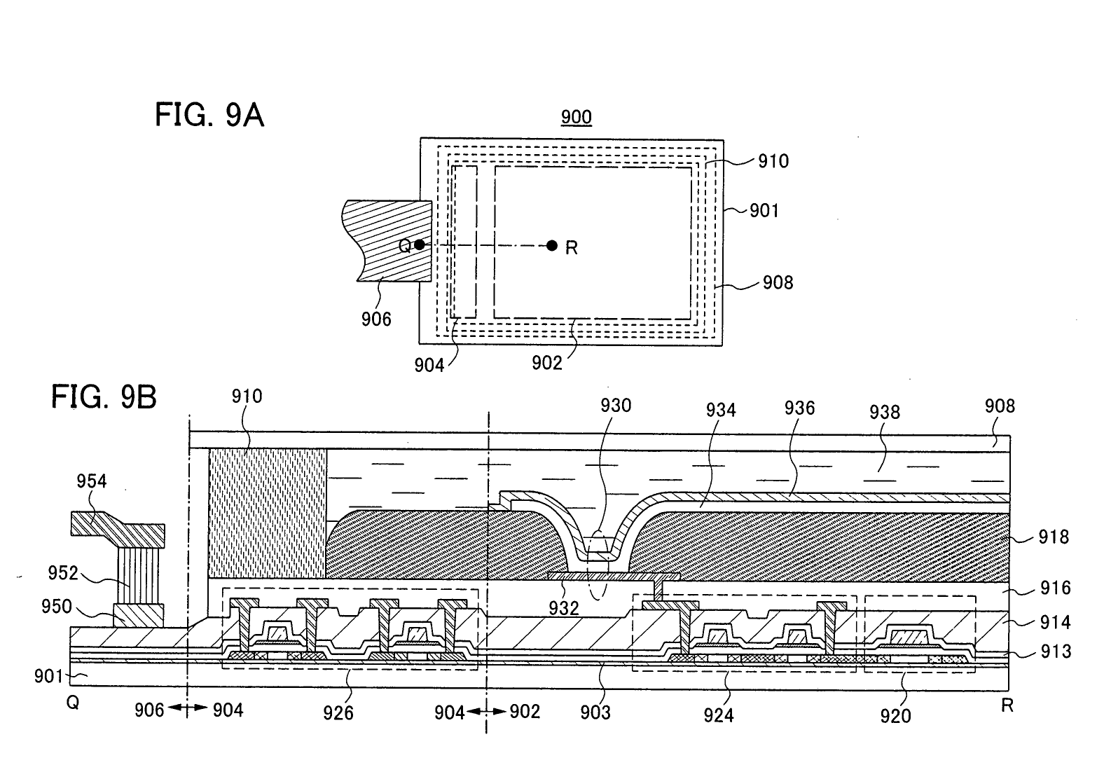

An example of a semiconductor device that has a light-emitting element of the present invention will be described. It is to be noted that an example of a display device that has a display function will be described with reference to FIGS. 9A and 9B in this embodiment mode.

FIG. 9A shows an example of a top view of a display device. FIG. 9B shows an example of a cross-sectional view taken along a line Q-R of FIG. 9A.

A display device 900 shown in FIGS. 9A and 9B has a pixel portion 902 and a driver circuit portion 904 provided over a substrate 901. A substrate 908 is provided over the substrate 901 with a sealant 910 interposed therebetween. A terminal portion 906 is provided over the substrate 901. Signals and power supply potentials for controlling operations of plural elements included in the pixel portion 902 are inputted from the outside through the terminal portion 906.

As shown in FIG. 9B, the pixel portion 902 is provided with a driver transistor 924 and a capacitor element 920 over the substrate 901. The pixel portion 902 may also be provided with a switching transistor. A light-emitting element 930 is provided over the driver transistor 924. Further, the light-emitting element 930 and the driver transistor 924 are connected to each other.

As the light-emitting element 930, the light-emitting element shown in Embodiment Mode 1 and the like is formed. Specifically, the light-emitting element 930 has a structure in which a layer containing an organic compound having a light-emitting function is interposed between a pair of electrodes of a first electrode layer and a second electrode layer. At least one of the pair of electrode layers (the second electrode layer in this embodiment mode) has a Young's modulus of 7.5×10¹⁰ N/m² or less. In this embodiment mode, the light-emitting layer 930 has a structure in which a layer 934 containing an organic compound having a light-emitting function is interposed between a first electrode layer 932 and a second electrode layer 936. Also, the light-emitting layer 930 may have a structure in which a hole-transporting layer, a hole-injecting layer, an electron-transporting layer, an electron-injecting layer, and the like are appropriately provided between the first electrode layer 932 and the second electrode layer 936.

Terminal portions of the first electrode layer 932 of the light-emitting element 930 are covered with a partition layer 918. The partition layer 918 is formed using an inorganic insulating material such as silicon oxide or silicon nitride, an organic insulating material such as acryl or polyimide, or the like. The partition layer 918 can separate adjacent light-emitting elements from each other. The partition layer 918 preferably has an edge portion with a rounded shape of which a radius of curvature continuously changes. By such a shape, coverage by the layer 934 containing an organic compound and the second electrode layer 936 stacked thereover can be improved.

The driver transistor 924 and the capacitor element 920 are provided over the substrate 901 with an insulating layer 903 interposed therebetween. An electrode layer serving as a source or drain electrode of the driver transistor 924 is connected to the first electrode layer 932 of the light-emitting element 930 through an insulating layer 916.

As the driver transistor 924, various transistors can be applied. For example, the above-described transistors shown in FIGS. 10A to 10D can be applied. In this embodiment mode, a top-gate TFT is applied. An example of the top-gate TFT is shown in FIG. 10A. However, the driver transistor 924 shown in this embodiment mode has a different point from the TFT shown in FIG. 10A, in which a gate electrode layer has a stacked structure of two layers and sidewalls are not provided on side faces thereof, and the driver transistor 924 has a multi-gate structure (structure in which two channel formation regions that are connected in series to be formed in a semiconductor layer, and two gate electrodes each apply a voltage to each channel formation region).

In the driver transistor 924, a gate electrode layer is formed over a semiconductor layer with a gate insulating layer interposed therebetween. In the semiconductor layer, two channel formation regions and source or drain regions are formed. A high concentration impurity region is formed between the channel formation regions adjacent to each other. The concentration of the high concentration impurity region is almost the same as that of the source or drain region. Further, LDD regions are formed between the source or drain regions and the channel formation regions and between the high concentration impurity region and the channel formation regions. The concentration of the impurity region in the LDD region is lower than that in the source or drain region.

The two gate electrode layers of the driver transistor 924 are formed corresponding to the two channel formation regions formed in the semiconductor layer. Here, the gate electrode layers each have a stacked layer of two layers. A width (in a direction in which carriers flow in the channel formation region: i.e. direction connecting the source region and drain region) of a lower layer (on a side in contact with the gate insulating layer) of the gate electrode layer is larger than that of an upper layer of the gate electrode layer.

The electrode layer serving as a source or drain electrode of the driver transistor 924 is formed so as to be connected to a source or drain region formed in the semiconductor layer through insulating layers 913 and 914.

In the capacitor element 920, an electrode layer is formed over a semiconductor layer with the gate insulating layer interposed therebetween. The semiconductor layer is the same layer as the semiconductor layer of the driver transistor 924 and includes an intrinsic region where an impurity element is not added, a low concentration impurity region, and a high concentration impurity region. The concentration of the low concentration impurity region is almost the same as that of the LDD region of the driver transistor 924, and the concentration of the high concentration impurity region is almost the same as that of the source or drain region of the driver transistor 924. The source or drain region of the driver transistor 924 also has a function for connecting the driver transistor 924 and the capacitor element 920. The electrode layer of the capacitor element 920 is the same layer as the gate electrode layer of the driver transistor 924.

The insulating layers 913, 914, and 916 are formed using an inorganic insulating material such as silicon oxide, silicon nitride, silicon oxynitride, or silicon nitride oxide, or an organic insulating material such as acryl or polyamide. The insulating layers 913, 914, and 916 serve as an interlayer insulating layer. Here, a wiring formed of the same layer as the gate electrode layer of the driver transistor 924 can be provided to be intersect with the electrode layer serving as a source or drain electrode by the insulating layers 913 and 914. Therefore, multilayer wiring structure can be formed. Similarly, the insulating layer 916 is formed, and the first electrode layer 932 is formed thereover, whereby a multilayer wiring structure can be formed.

In the driver circuit portion 904, a plurality of transistor groups 926 are provided over the substrate 901. The plurality of the transistor groups 926 are included in a driver circuit for controlling operation of the pixel portion 902. The driver circuit portion 904 is provided with, for example, a shift register, a decoder, a buffer, a sampling circuit, a latch circuit, and the like.

The plurality of the transistor groups 926 are formed of a plurality of transistors. In FIG. 9B, two transistors are shown as the plurality of the transistor groups 926.

As a transistor included in the plurality of transistor groups 926, various transistors can be applied. For example, the transistors shown in FIGS. 10A to 10D can be applied. Here, a top-gate TFT is applied similarly to the driver transistor 924.

In the transistor included in the plurality of the transistor groups 926, a gate electrode layer is formed over a semiconductor layer with the gate insulating layer interposed therebetween. In the semiconductor layer, a channel formation region and source or drain regions are formed. LDD regions are formed between the channel formation region and the source and drain regions. The concentration of the LDD region is lower than that of the source or drain region. The gate electrode layer has a stacked structure of two layers. A width of a lower layer of the electrode layer is wider than that of an upper layer. An electrode layer serving as a source or drain electrode of the transistor is formed so as to be connected to the source or drain region in the semiconductor layer through the insulating layers 913 and 914.

The two transistors as the plurality of the transistor groups 926 shown in FIG. 9B may have conductivity (p-type or n-type) different from each other. The transistors having conductivity type different from each other are complementarily combined, so that a CMOS circuit can be formed.

The substrate 901 and the substrate 908 are attached with the sealant 910 so as to seal the pixel portion 902 and the driver circuit portion 904.

As the sealant 910, a photocurable resin or a thermosetting resin is preferably used. For example, a phenol region, an epoxy resin, or the like can be used. A region 938 surrounded by the sealant 910 may be filled with a filler such as an epoxy resin, or may be filled and sealed with nitrogen by sealing the region in a nitrogen atmosphere. When a substance having a hygroscopic property such as a drying agent is used as the filler, deterioration of the light-emitting element 930 due to moisture or the like can be prevented. When light emission from the light-emitting element 930 is extracted from the substrate 908 side, a filler having a light-transmitting property is used.

As the substrate 901 and the substrate 908, a glass substrate, a quartz substrate, a semiconductor substrate, a metal substrate, a stainless steel substrate, or the like can be used. As the substrate 908, a flexible substrate such as a plastic substrate can be used. Further, as shown in Embodiment Mode 2, after an element formation layer which includes the TFT and the light-emitting element is formed over a supporting substrate with heat resistance that can withstand a processing temperature, the element formation layer is peeled from the supporting substrate and transposed to a flexible substrate, so that a flexible substrate can be used as the substrate 901.

In the terminal portion 906, a terminal electrode layer 950 is provided over the substrate 901 with an insulating layer interposed therebetween. An FPC 954 is connected to the terminal electrode layer 950 through an anisotropic conductive layer 952, and is electrically connected to the outside.

Although a structure in which the pixel portion 902 and the driver circuit portion 904 are provided over the same substrate as shown in FIG. 9A is described in this embodiment mode, the present invention is not particularly limited. For example, an IC chip may be mounted as the driver circuit portion by a COG method or a TAB method.

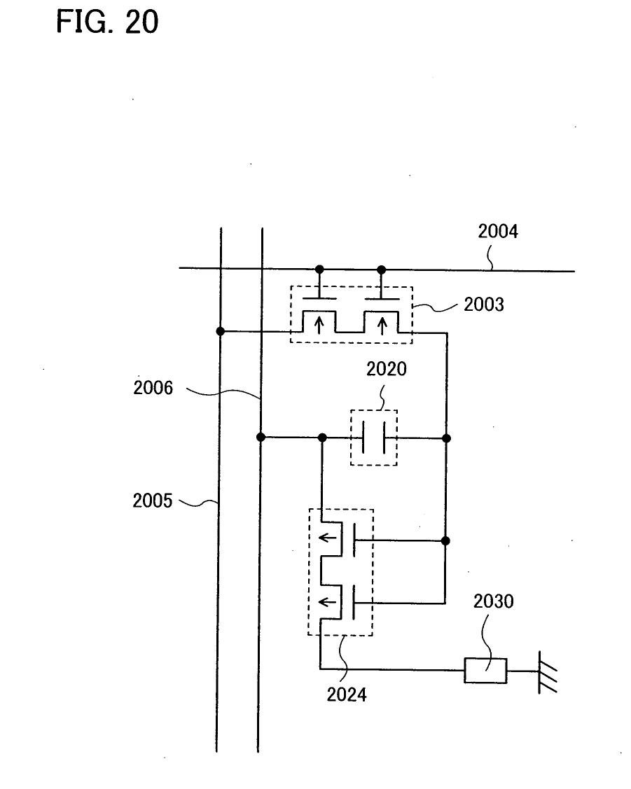

Next, an example of a circuit diagram of a pixel portion in the display device shown in FIGS. 9A and 9B will be shown in FIG. 20.

In FIG. 20, a pixel portion includes a light-emitting element 2030, a transistor 2024, a transistor 2003, and a capacitor element 2020. The light-emitting element 2030, the transistor 2024, and the capacitor element 2020 respectively corresponds to the light-emitting element 930, the driver transistor 924, and the capacitor element 920 in FIG. 9B. The transistor 2003 is a switching transistor having a switching function, and the transistor 2024 is a driver transistor.

A gate of the transistor 2003 is connected to a gate wiring 2004. One of source and drain of the transistor 2003 is connected to a source wiring 2005, and the other one is connected to a gate of the transistor 2024 and one of terminals of the capacitor element 2020. One of the terminals of the capacitor element 2020 is connected to the other of source and drain of the transistor 2003 and the gate of the transistor 2024. Another terminal is connected to a current supply line 2006 and one of source and drain of the transistor 2024. One of the source and drain of the transistor 2024 is connected to the current supply line 2006, and the other one is connected to the light-emitting element 2030. The source wiring 2005 and the current supply line 2006 are formed to be intersect with the gate wiring 2004.

As described, one of the source and drain of the transistor 2024 is connected to the current supply line 2006. When the transistor 2024 is turned on, a current is supplied to the light-emitting element 2030.

In the pixel portion of the display device in this embodiment mode, a plurality of light-emitting elements driven by a circuit shown in FIG. 20 are arranged in matrix. It is to be noted that a circuit for driving the light-emitting element is not limited to the circuit shown in FIG. 20. For example, a circuit provided with an erasing line for erasing forcibly an inputted signal and an erasing transistor which is used for erasing operation, or the like may also be employed.

In the display device of this embodiment mode, a driving method of screen display is not particularly limited, and for example, a dot sequential driving method, a line sequential driving method, an area sequential driving method, or the like may be used. When a line sequential driving method is used, a time division gray scale driving method and an area gray scale driving method may be appropriately selected. Further, an image signal inputted to a source wiring of the display device may be an analog signal or a digital signal. The driving circuit may be designed as appropriate in accordance with the image signal.

By applying the present invention, defects of the light-emitting element included in the display device can be prevented. Further, when a material included in the electrode layer is selected in considering a work function or the like in order to improve emit efficiency of the light-emitting element, defects of the light-emitting element can be prevented from generation by considering a Young's modulus by the present invention. Accordingly, reliability of the display device can be improved. Furthermore, the yield in the manufacturing process of the display device can be improved.

This embodiment mode can be combined with Embodiment Mode 1 and 2 as appropriate.

### Embodiment Mode 6

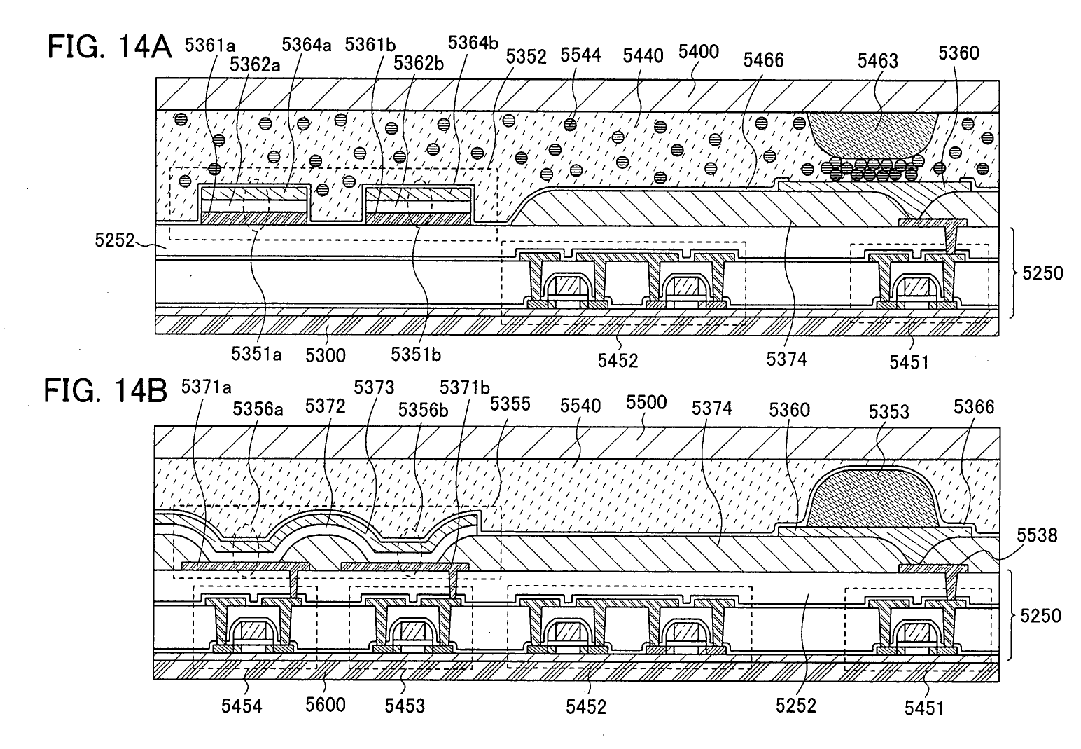

In this embodiment mode, an example of a semiconductor device and a manufacturing method thereof according to the present invention will be described with reference to FIG. 14A to FIG. 18.

A semiconductor device described in this embodiment mode is capable of reading and writing of data without contact. Data transmission method is broadly classified into three methods of an electromagnetic coupling method in which communication is performed by mutual induction with a pair of coils disposed opposite to each other, an electromagnetic induction method in which communication is performed by an inductive electromagnetic field, and an electric wave method in which communication is performed by using electric waves; and any of these methods may be employed. An antenna that is used for sending data can be provided in two ways. One way is to provide a terminal portion for a substrate provided with a transistor and a memory element and to connect an antenna provided over another substrate to the terminal portion, and the other way is to provide an antenna over a substrate provided with a transistor and a memory element.

First, a structural example of a semiconductor device will be described with reference to FIG. 14A, in which a terminal portion is provided for a substrate provided with a plurality of semiconductor elements and memory elements, and an antenna provided for another substrate is connected to the terminal portion. Here, as a part of a cross section of the semiconductor device, an antenna, and a circuit and a memory circuit connected to the antenna are partially shown.

In the semiconductor device shown in FIG. 14A, a transistor layer 5250 including a transistor 5451 and a transistor 5452 is provided over a substrate 5300, and a memory element portion 5352 is provided over the transistor layer 5250. A substrate 5400 is provided with a conductive layer 5463 serving as an antenna. The substrate 5300 and the substrate 5400 are provided to face each other so as to connect the transistor layer 5250 and the conductive layer 5463.

Although an example in which the memory element portion 5352 and the conductive layer 5463 are provided over the transistor layer 5250 is described here, the present invention is not particularly limited. For example, a memory element portion or a conductive layer serving as an antenna may be provided below an element formation layer or in the same layer as the element formation layer.

The memory element portion 5352 has a memory element 5351a and a memory element 5351b. The memory element 5351a includes a first electrode layer 5361a formed over an insulating layer 5252, a layer 5362a containing an organic compound formed over the first electrode layer 5361a, and a second electrode layer 5364a formed thereover. Similarly, the memory element 5351b includes a first electrode layer 5361b formed over the insulating layer 5252, a layer 5362b containing an organic compound formed over the first electrode layer 5361b, and a second electrode layer 5364b formed thereover. The memory element portion 5352 can be formed using a similar material and method to the memory elements shown in Embodiment Modes 1 to 4. In this embodiment mode, the second electrode layers 5364a and 5364b have a Young's modulus of 7.5×10¹⁰ N/m² or less.

An insulating layer 5466 serving as a protective layer is formed to cover the memory elements 5351a and 5351b. The insulating layer 5466 in a connection portion of the element formation layer and the conductive layer 5463 is removed.

The transistor 5452 partially forms a driver circuit for controlling operation of the memory element portion 5352. In the driver circuit, a decoder, a buffer, and the like, are provided. The transistor 5451 is connected to the conductive layer 5463 serving as an antenna and partially forms a circuit connected to the antenna. As for the transistors 5451 and 5452, various transistors can be applied. For example, the transistors shown in FIGS. 10A to 10D can be applied.

The conductive layer 5463 serving as an antenna is provided on the substrate 5400. As a material of the conductive layer 5463, an element such as gold (Au), platinum (Pt), nickel (Ni), tungsten (W), molybdenum (Mo), cobalt (Co), copper (Cu), aluminum (Al), manganese (Mn), or titanium (Ti), an alloy material containing the element, or the like can be used. The conductive layer 5463 can be formed by an evaporation method, a sputtering method, any printing method such as screen printing or gravure printing, a droplet discharge method, or the like.

The substrate 5300 provided with the transistor 5250 layer and the memory element portion 5352 is attached to the substrate 5400 provided with the conductive layer 5463 serving as an antenna with an adhesive resin 5440. The transistor layer 5250 and the conductive layer 5463 are electrically connected with conductive fine particles 5444 contained in the resin 5440. Specifically, the terminal electrode layer 5360 connected to the transistor 5451 provided over the substrate 5300 and the conductive layer 5463 provided on the substrate 5400 are each contacted with the conductive fine particles 5444, whereby the terminal electrode layer 5360 and the conductive layer 5463 are electrically connected. The substrate provided with the element formation layer and the substrate provided with the conductive layer serving as an antenna may also be attached by using a conductive adhesive such as silver paste, copper paste, or carbon paste, or solder bonding.

Next, a structural example of a semiconductor device will be described with reference to FIG. 14B, in which an antenna is provided over a substrate provided with a plurality of semiconductor elements and memory elements. It is to be noted that different portions from those of FIG. 14A are described in FIG. 14B.

In the semiconductor device shown in FIG. 14B, a transistor layer 5250 that includes transistors 5451 and 5452 is provided over a substrate 5600, and a memory element portion 5355 and a conductive layer 5353 serving as an antenna are provided over the transistor layer 5250. Further, a transistor 5453 and a transistor 5454 serving as a switching element of the memory element portion 5355 are provided in the same layer as the transistors 5451 and 5452. It is to be noted that the present invention is not particularly limited, and the memory element portion 5355 and the conductive layer 5353 serving as an antenna may be formed below the transistor layer 5250 or in the same layer as the transistor layer 5250.

The memory element portion 5355 has a memory element 5356a and a memory element 5356b. The memory element 5356a includes a first electrode layer 5371a formed over an insulating layer 5252, a layer 5372 containing an organic compound formed over the first electrode layer 5371a, and a second electrode layer 5373 formed over the layer 5372 containing an organic compound. Similarly, the memory element 5356b includes a first electrode layer 5371b formed over the insulating layer 5252, the layer 5372 containing an organic compound formed over the first electrode layer 5371b, and the second electrode layer 5373 formed over the layer 5372 containing an organic compound. The memory element portion 5355 can be formed using a similar material and method to those of the memory elements shown in Embodiment Modes 1 to 4. In this embodiment mode, the second electrode layer 5373 has a Young's modulus of 7.5×10¹⁰ N/m² or less. Terminal portions of the first electrode layer 5371a of the memory element 5356a and terminal portions of the first electrode layer 5371b of the memory element 5356b are covered with a partition layer 5374. The memory elements 5356a and 5356b adjacent to each other can be separated by the partition layer 5374.

In the memory elements 5356a and 5356b, the layer 5372 containing an organic compound and the second electrode layer 5373 are common. That is, the layer 5372 containing an organic compound and the second electrode layer 5373 are sequentially stacked over the first electrode layers 5371a and 5371b and the partition layer 5374 that covers the terminal portions of the first electrode layers 5371a and 5371b.

The memory element 5356a is connected to the transistor 5454, and the memory element 5356b is connected to the transistor 5453. As the transistors 5454 and 5453, a similar transistor to the transistor 5451 may be applied.

The conductive layer 5353 serving as an antenna is formed over a terminal electrode layer 5360. The terminal electrode layer 5360 is provided over the transistor 5451, and the terminal electrode layer 5360 and the transistor 5451 are connected through a wiring layer 5538. Specifically, the terminal electrode layer 5360 and an electrode layer serving as a source or drain electrode of the transistor 5451 are connected through the wiring layer 5538.

The conductive layer 5353 serving as an antenna can be formed using an element such as gold (Au), platinum (Pt), nickel (Ni), tungsten (W), molybdenum (Mo), cobalt (Co), copper (Cu), aluminum (Al), manganese (Mn), or titanium (Ti), an alloy material containing the element, or the like by an evaporation method, a sputtering method, any printing method such as screen printing or gravure printing, or a droplet discharge method. The terminal electrode layer 5360 can be formed using the same layer as the second electrode layer 5373. The wiring layer 5538 can be formed using the same layer as the first electrode layers 5371a and 5371b.

An insulating layer 5366 serving as a protective layer is formed to cover the memory elements 5356a and 5356b and the conductive layer 5353 serving as an antenna.

The substrate 5600 provided with the transistor layer 5250, the memory element portion 5355, and the conductive layer 5353 serving as an antenna is attached to a substrate 5500 with an insulating layer 5540 interposed therebetween. The substrate 5500 is preferably attached by providing an adhesive layer over a surface of the insulating layer 5540.

In FIGS. 14A and 14B, a sensor element may be provided in addition to the memory element. As the sensor element, an element which detects properties such as temperature, humidity, illuminance, gas, gravity, pressure, sound (vibration), or acceleration by a physical or chemical means can be given. The sensor element is typically formed from an element such as a resistor element, a capacitive coupling element, an inductive coupling element, a photovoltaic element, a photoelectric conversion element, a thermoelectric conversion element, a transistor, a thermistor, a diode, an electrostatic capacitance element, a piezo element, or the like.

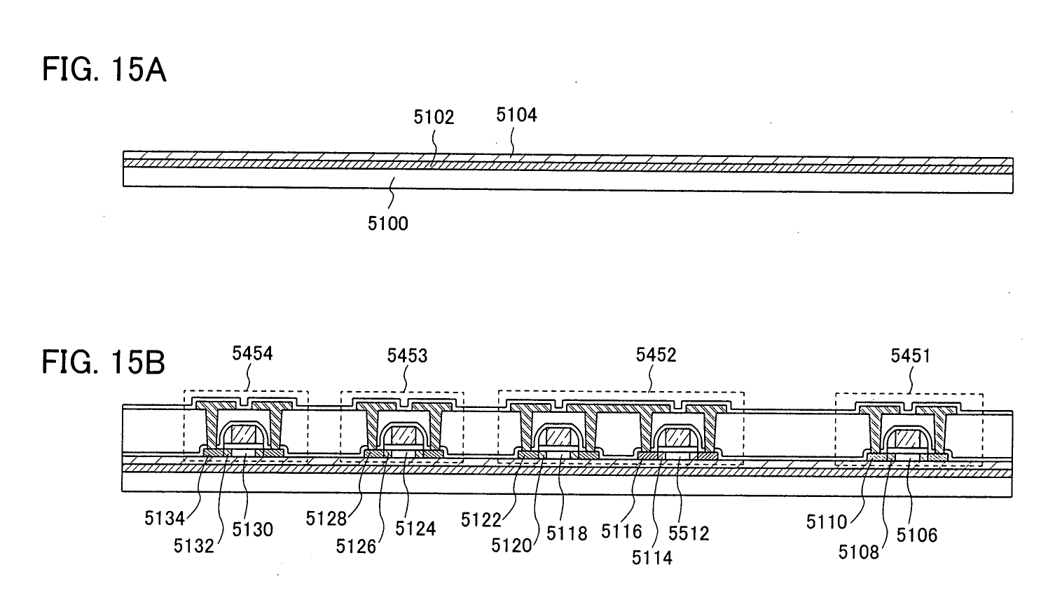

Next, an example of a method for manufacturing the semiconductor device shown in FIG. 14B will be described with reference to FIG. 15A to FIG. 18.

First, a peeling layer 5102 is formed over a surface of a substrate 5100 (see FIG. 15A). As the substrate 5100, a glass substrate, a quartz substrate, a metal substrate or a stainless-steel substrate having an insulating layer formed on its surface, a heat-resistant plastic substrate which can withstand the treatment temperature of the process in this embodiment mode, or the like can be used. Although the peeling layer 5102 is formed over an entire surface of the substrate 5100 here, the peeling layer 5102 may be partially provided over the substrate 5100. Further, although the peeling layer 5102 is formed in contact with the substrate 5100 here, an insulating layer may be formed so as to be in contact with the substrate 5100 as needed, and the peeling layer 5102 may be formed so as to be in contact with the insulating layer.

The peeling layer 5102 is formed to have a single-layer structure or a stacked structure by a sputtering method, a CVD method, or the like, using an element such as tungsten (W), molybdenum (Mo), titanium (Ti), tantalum (Ta), niobium (Nb), nickel (Ni), cobalt (Co), zirconium (Zr), zinc (Zn), ruthenium (Ru), rhodium (Rh), lead (Pb), osmium (Os), iridium (Ir), or silicon (Si), or an alloy material or a compound material containing the element. When a layer containing silicon is formed as the peeling layer 5102, a crystalline structure thereof may be any one of an amorphous structure, a microcrystalline structure, or a polycrystalline structure.

When the peeling layer 5102 has a single-layer structure, a layer a tungsten layer, a molybdenum layer or a layer containing a mixture of tungsten and molybdenum is preferably formed. Alternatively, a layer containing an oxide or oxynitride of tungsten, a layer containing an oxide or oxynitride of molybdenum, or a layer containing an oxide or oxynitride of a mixture of tungsten and molybdenum is formed. The mixture of tungsten and molybdenum corresponds to an alloy of tungsten and molybdenum, for example. In addition, the oxide of tungsten is also referred to as tungsten oxide.

When the peeling layer 5102 has a stacked structure, a metal layer is preferably formed as a first layer, and a layer containing metal oxide or metal nitride is preferably formed as a second layer. For example, a tungsten layer, a molybdenum layer or a layer containing a mixture of tungsten and molybdenum is preferably formed as a first layer. Then, as a second layer, an oxide, nitride, oxynitride or nitride oxide of tungsten, molybdenum or a mixture of tungsten and molybdenum is formed. When the peeling layer 5102 has a stacked structure, a first layer and a second layer are sequentially stacked from the substrate 5100 side.

When the peeling layer 5102 has a stacked structure of a metal layer and a layer containing metal oxide, a metal layer is formed, and the metal layer is subjected to oxidation treatment, so that a metal oxide layer can be formed. As oxidation treatment, thermal oxidization treatment, oxygen plasma treatment, or treatment with a solution having strong oxidizability such as ozone water may be performed. Alternatively, a metal layer is formed as the peeling layer, and an insulating layer formed from oxide is formed over the metal layer, whereby a layer containing the oxide of metal (metal oxide layer) can be formed at an interface between the metal layer and the insulating layer. For example, when the peeling layer 5102 has a stacked structure of a tungsten layer and a layer containing tungsten oxide, the layer containing tungsten is formed and then a layer containing silicon oxide is formed thereover, so that the layer containing the oxide of tungsten is formed at an interface between the tungsten layer and the layer containing silicon oxide. This method can be applied to the cases of forming layers containing nitride, oxynitride, and nitride oxide of tungsten, and after forming the layer containing tungsten, an insulating layer containing nitride and silicon such as silicon nitride or silicon oxide is formed thereover. After the formation of the metal layer, an insulating layer formed from oxide (for example, an insulating layer containing silicon such as silicon nitride or silicon oxide) and formed thereover serves as a base insulating layer and a protective layer in a peeling step of the subsequent step.

The oxide of tungsten used for the peeling layer 5102 is expressed by WOₓ, and x is 2 to 3. There are cases of x=2 (WO₂), x=2.5 (W₂O₅), x=2.75 (W₄O₁₁), x=3 (WO₃), and the like. When an oxide of tungsten s formed, the value of x described above is not particularly restricted and may be decided based on the etching rate of the oxide of tungsten or the like. It is to be noted that the value of x may be determined based on etching rate of a layer containing an oxide of tungsten, which is formed by a sputtering method in an oxygen atmosphere, (WOₓ, 0≦x≦3). Thus, in order to reduce manufacturing time, the layer containing an oxide of tungsten is preferably formed as the peeling layer 5102 by a sputtering method in an oxygen atmosphere. In this embodiment mode, a stacked structure of a tungsten layer and a layer containing an oxide of tungsten is formed as the peeling layer 5102. The layer containing an oxide of tungsten is formed by which a tungsten layer is subjected to plasma treatment in an atmosphere containing oxide and nitrogen.

Next, an insulating layer 5104 is formed to cover the peeling layer 5102. The insulating layer 5104 is formed to have a single-layer structure or a stacked structure using silicon such as silicon nitride or silicon oxide by a method for forming a thin film such as sputtering or CVD. The insulating layer 5104 serves as a blocking layer for preventing intrusion of an impurity from the substrate 5100. In addition, the insulating layer 5104 serves as a protective layer in a peeling step of the subsequent step. In this embodiment mode, a silicon nitride layer is formed as the insulating layer 5104.

Subsequently, transistors 5451, 5452, 5453, and 5454 are formed (see FIG. 15B). As the transistors 5451, 5452, 5453, and 5454, the transistors shown in FIGS. 10A to 10D may be formed. A specific structure, manufacturing method, and the like are based on those of Embodiment Mode 2, and they are omitted here. In this embodiment mode, the transistors are formed similarly to the top-gate TFT 1380 shown in FIG. 10A. Specifically, in FIG. 15B, a semiconductor layer is formed over the insulating layer 5104, and a gate electrode layer is formed over the semiconductor layer with a gate insulating layer interposed therebetween. Insulating layers serving as a sidewall are formed on side faces of the gate electrode layer, and an insulating layer that covers the semiconductor layer, the gate electrode layer, and the sidewall is formed. Then, an electrode layer serving as a source or drain electrode connected to the semiconductor layer through the insulating layer is formed.

An element imparting a conductivity type is added to each of the transistors 5451, 5452, 5453, and 5454, so that a channel formation region, an LDD region, and a source or drain region are formed in each semiconductor layer. In the source or drain region, an element is added, so that the source or drain region has higher concentration of impurities than that of the LDD region. It is to be noted that the LDD region is not necessarily provided. As an element imparting a conductivity type, an element imparting p-type conductivity or an element imparting n-type conductivity may be added. As the element imparting n-type conductivity, phosphorus (P), arsenic (As), or the like can be used. As the element imparting p-type conductivity, boron (B), aluminum (Al), gallium (Ga), or the like can be used.

Here, in the transistor 5451, a channel formation region 5106, LDD regions 5108, and source or drain regions 5110 are formed. The transistor 5452 is formed of two transistors to which elements having conductivity types different from each other are added. One of the transistors includes a channel formation layer 5512, LDD regions 5114, and source or drain regions 5116. The other transistor includes a channel formation layer 5118, LDD regions 5120, and source or drain regions 5122. In the transistor 5452, the LDD regions 5114 and the source or drain regions 5116 are added with the element having different conductivity type from that of the LDD regions 5120 and the source or drain regions 5122. In the transistor 5453, a channel formation region 5124, LDD regions 5126, and source or drain regions 5128 are formed. In the transistor 5454, a channel formation region 5130, LDD regions 5132, and source or drain regions 5134 are formed.

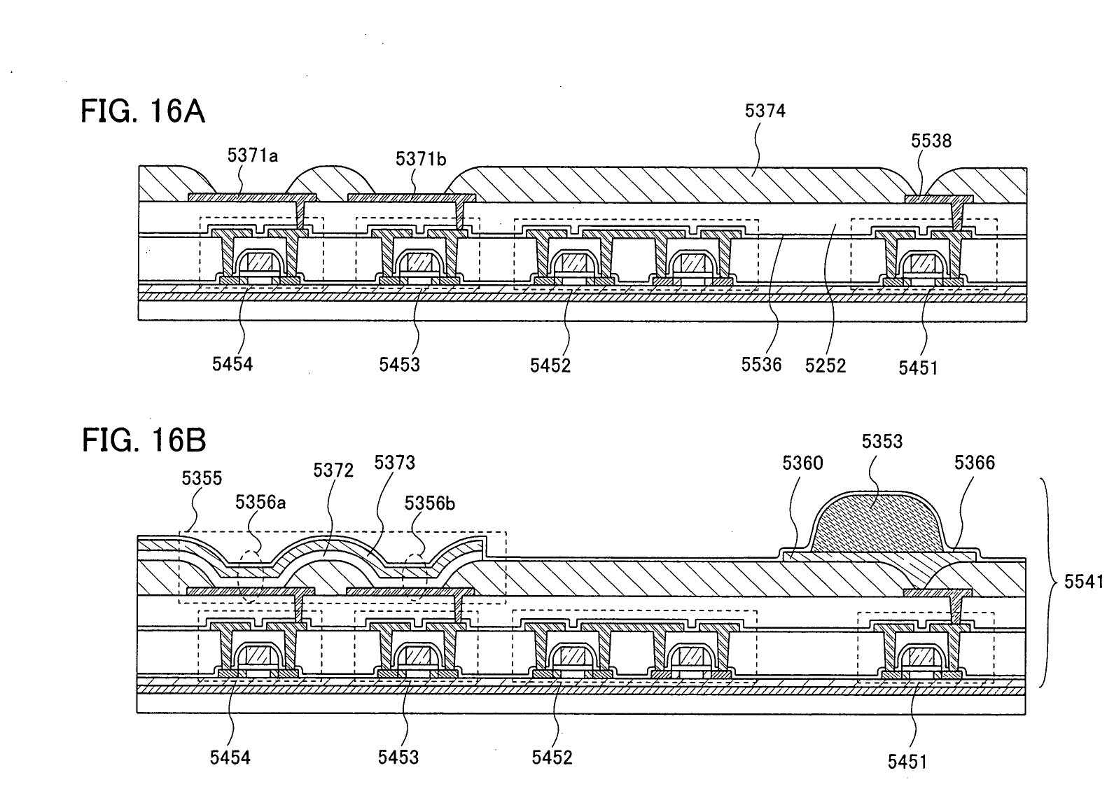

Next, an insulating layer 5536 and an insulating layer 5252 are sequentially formed over the transistors 5451, 5452, 5453, and 5454 (see FIG. 16A). The insulating layer 5536 and the insulating layer 5252 are formed using an inorganic insulating material such as silicon oxide, silicon nitride, silicon oxynitride, or silicon nitride oxide, or an organic insulating material such as acryl or polyamide. When a coating method such as spin coating or roll coater is used, an insulating layer containing silicon oxide, which is formed by applying a liquid insulating material and subjecting the liquid material to thermal treatment, can also be used. For example, a material containing a siloxane bond is applied and is subjected to thermal treatment at 200 to 400° C. so that an insulating layer containing silicon oxide can be obtained. When an insulating layer formed by a coating method or an insulating layer which is planarized by reflow is formed as the insulating layers 5536 and 5252, disconnection of a wire (here, a wiring layer that connects first electrode layers of memory elements and a conductive layer serving as an antenna to the transistors) provided over the insulating layers can be prevented. Although a two-layered structure is formed here as an interlayer insulating layer, the present invention is not particularly limited, and a single layer structure or a stacked structure having three or more layers can be formed. When the insulating layer 5536 having contact with the electrode layer of the transistors 5451, 5452, 5453, and 5454 is formed of an inorganic insulating material such as silicon oxide or silicon oxynitride, the insulating layer 5536 can serve as a protective layer.

Next, the insulating layers 5536 and 5252 are selectively etched to form contact holes for exposing the electrode layer serving as a source or drain electrode of the transistors 5451, 5453, and 5454. Then, a conductive layer is formed so that the contact holes are filled. The conductive layer is formed by a sputtering method, a printing method, a droplet discharge method, or the like, using a metal element such as gold (Au), silver (Ag), platinum (Pt), nickel (Ni), tungsten (W), chromium (Cr), molybdenum (Mo), iron (Fe), cobalt (Co), copper (Cu), palladium (Pd), carbon (C), aluminum (Al), manganese (Mn), titanium (Ti), or tantalum (Ta), or an alloy material or a compound material containing the element can be used. In addition, an alkali metal such as lithium (Li) or cesium (Cs), an alkaline earth metal such as magnesium (Mg), calcium (Ca), or strontium (Sr), a rare earth metal such as europium (Er) or ytterbium (Yb), an alloy containing any of these (such as MgAg or AlLi), or the like can be used. Further, a conductive oxide material such as indium tin oxide (ITO), zinc oxide (ZnO), indium zinc oxide (IZO), or zinc oxide to which gallium is added (GZO), indium tin oxide containing silicon oxide (ITSO), or indium oxide containing zinc oxide (ZnO) of 2 to 20 wt % can be used.

The conductive layer formed using the above material is selectively etched to form a first electrode layer 5371a and a first electrode layer 5371b each included in a memory element and a wiring layer 5538 (see FIG. 16A). The first electrode layer 5371a is connected to the transistor 5454. The first electrode layer 5371b is connected to the transistor 5453. The wiring layer 5538 serves as a wiring electrically connecting the transistor 5451 to a conductive layer serving as an antenna formed in the subsequent step.

Next, an insulating layer is formed to cover the first electrode layer 5371a, the first electrode layer 5371b, and the wiring layer 5538. The insulating layer is formed using an inorganic insulating material such as silicon oxide or silicon nitride, an organic insulating material such as acryl, polyamide, or resist, or a material containing a siloxane bond. The insulating layer is formed by a sputtering method, a CVD method, a coating method, or the like depending on the material to be used.

Subsequently, the insulating layer is selectively etched to expose the first electrode layer 5371a and the first electrode layer 5371b. The remaining insulating layer is a partition layer 5374. The partition layer is formed to cover end portions of the first electrode layer 5371a and the first electrode layer 5371b (see FIG. 16A). At a part of the insulating layer over the wiring layer 5538, a contact hole having a size with which a terminal electrode layer connected to the conductive layer serving as an antenna can be formed is formed so that a part of the wiring layer 5538 is exposed. In the case where a positive type photosensitive resin, of which an unexposed portion remains, is used for the insulating layer, the insulating layer can be formed by only an exposure step and a developing step, thereby reducing the number of steps.

Then, a layer 5372 containing an organic compound is formed over the first electrode layer 5371a and the first electrode layer 5371b (see FIG. 16B). The layer 5372 containing an organic compound is formed to have a single-layer structure or a stacked structure by an evaporation method, an electron beam evaporation method, a sputtering method or a CVD method, using an organic compound of which conductivity is changed or of which a shape is transformed by optical action or electric action. The memory element that includes the layer 5372 containing the organic compound can store two valued corresponding to an “initial state” and a “state after change” before or after change of the conductivity or transformation of the shape. For such a layer 5372 containing an organic compound, an organic resin such as polyimides, polyacrylic ester or polymethacrylic acid ester, an organic compound having a hole-transporting property, or an organic compound having an electron-transporting property can be used. It is to be noted that a specific material and manufacturing method that can be used for the layer 5372 containing an organic compound are based on description of the memory element 100 in Embodiment Mode 1.

Subsequently, a second electrode layer 5373 is formed over the layer 5372 containing an organic compound (see FIG. 16B). The second electrode layer 5373 is formed using a metal element, an alloy material or a compound material having a Young's modulus of 7.5×10¹⁰ N/m² or less, by an evaporation method, a sputtering method, a printing method, or a droplet discharge method, so that the second electrode layer 5373 has a Young's modulus of 7.5×10¹⁰ N/m² or less. When an alloy material or a compound material is used, a metal element having a Young's modulus of 7.5×10¹⁰ N/m² or less is preferably contained. For example, the second electrode layer 5373 can be formed using a metal element such as indium (In), barium (Ba), lead (Pb), calcium (Ca), bismuth (Bi), magnesium (Mg), tin (Sn), or aluminum (Al), or an alloy material or a compound material containing the metal element. Although a thickness of the second electrode layer 5373 is not particularly limited, it is preferably about 10 nm to 200 nm, further preferably about 10 nm to 100 nm. A specific material and the like that can be used for the second electrode layer 5373 are based on description of the memory element 100 of Embodiment Mode 1.

When forming the second electrode layer 5373, a terminal electrode layer 5360 can be also formed. The terminal electrode layer 5360 has a function for connecting a conductive layer serving as an antenna formed thereover and the transistor 5451. The terminal electrode layer 5360 is formed of the same layer as the second electrode layer 5373 so that the contact hole formed so as to expose the wiring layer 5538 is filled.

Although the layer 5372 containing an organic compound and the second electrode layer 5373 are stacked, as the common layer here, over the first electrode layers 5371a and 5371b and the partition layer 5374 that covers the end portions of the first electrode layers 5371a and 5371b, it is not particularly limited. For example, the layer containing an organic compound and the second electrode layer, which are separated from each other, may be selectively provided over each of the first electrode layer 5371a and the first electrode layer 5371b.

A conductive layer 5353 serving as an antenna is provided to be in contact with the terminal electrode layer 5360 (see FIG. 16B). The conductive layer 5353 is formed using a conductive material by an evaporation method, a sputtering method, any printing method such as screen printing or gravure printing, or a droplet discharge method. Specifically, the conductive layer 5353 is formed to have a single-layer structure or a stacked structure, using a metal element such as gold (Au), platinum (Pt), nickel (Ni), tungsten (W), molybdenum (Mo), cobalt (Co), copper (Cu), aluminum (Al), manganese (Mn), or titanium (Ti), or an alloy material or a compound material containing the element.

Subsequently, an insulating layer 5366 serving as a protective layer is formed over the second electrode layer 5373, the partition layer 5374, the terminal electrode layer 5360, and the conductive layer 5353 (see FIG. 16B). The insulating layer 5366 is formed using an inorganic insulating material such as silicon oxide, silicon nitride, silicon oxynitride, or silicon nitride oxide by a sputtering method, a CVD method, or the like. The insulating layer 5366 may be formed as needed, and is not necessarily provided. A stacked body including layers stacked over the insulating layer 5104 up to the second electrode layer 5373 is referred to as an element formation layer 5541.

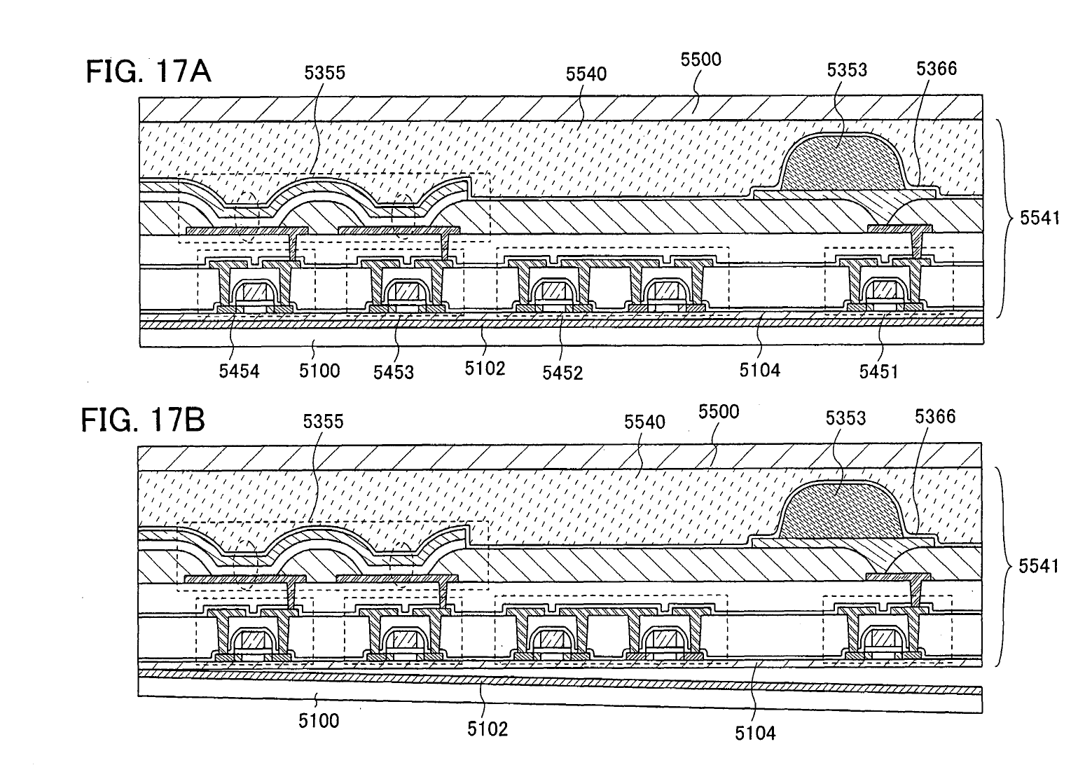

Next, an insulating layer 5540 is formed over the second electrode layer 5373 with the insulating layer 5366 interposed therebetween, and a substrate 5500 is attached to a surface of the insulating layer 5540 (see FIG. 17A). The insulating layer 5540 is formed of the following: an organic resin such as an acrylic resin, a polyimide resin, a melamine resin, a polyester resin, a polycarbonate resin, a phenol resin, an epoxy resin, polyacetal, polyether, polyurethane, polyamide (nylon), a furan resin, or a diallylphthalate resin; an inorganic siloxane polymer including a Si—O—Si bond among compounds including silicon, oxygen, and hydrogen formed by using a siloxane polymer-based material typified by silica glass as a starting material; or an organic siloxane polymer in which hydrogen bonded to silicon is substituted by an organic group such as methyl or phenyl, typified by an alkylsiloxane polymer, an alkylsilsesquioxane polymer, a silsesquioxane hydride polymer, or an alkylsilsesquioxane hydride polymer. The insulating layer 5540 can be formed by coating the second electrode with these materials by a coating method and drying and heating. When the insulating layer 5540 is formed by a coating method, an insulating layer with less uneven surface can be formed, which is preferable. Alternatively, after an insulating layer such as silicon oxide, silicon nitride, silicon oxynitride, or silicon nitride oxide is formed by a CVD method, a sputtering method, or the like, a surface thereof may be polished by a CMP method, so that the insulating layer 5540 can be formed. The insulating layer 5540 serves as a protective layer in the subsequent peeling step.

Although the substrate 5500 is attached to a surface of the insulating layer 5540 here, it is not particularly limited, and the substrate 5500 may be attached to the second electrode layer directly.

As the substrate 5500, a flexible, thin, and lightweight substrate is preferably used. Specifically, a substrate made from plastic such as PET (polyethylene terephthalate), PEN (polyethylene naphthalate), PES (polyethersulfone), polypropylene, polypropylene sulfide, polycarbonate, polyetherimide, polyphenylene sulfide, polyphenylene oxide, polysulfone, polyphthalamide, or the like can be used. Moreover, paper made from a fibrous material; a multilayer film of a base material film (polyester, polyamide, an inorganic evaporated film, paper, or the like) and an adhesive organic resin film (an acrylic-based organic resin, an epoxy-based organic resin, or the like); or the like can also be used. In addition, a film having an adhesive layer (made from polypropylene, polyester, vinyl, polyvinyl fluoride, vinyl chloride, or the like) which is attached to an object to be processed by thermocompression may be used. Such a film can be attached to an object to be processed by melting the adhesive layer provided in the outermost surface of the film or a layer (which is not the adhesive layer) provided in the outermost layer of the film by heat treatment and then by applying pressure thereto. Here, the object to be processed indicates a stacked body including the layers stacked below the insulating layer 5540 to the substrate 5100, and a surface to be processed is a surface of the insulating layer 5540 up to the substrate 5100, which is not contacted with the second electrode layer 5373.

When a plastic substrate that has no adhesive property or the like is used as the substrate 5500, an adhesive layer is provided between the insulating layer 5540 and the substrate 5500 to attach the insulating layer 5540 and the substrate 5500. When a substrate having an adhesive property (film) is used as the substrate 5500, an adhesive layer is not necessary to be provided additionally between the insulating layer 5540 and the substrate 5500.

In this embodiment mode, an epoxy resin composition is applied by a coating method, and the epoxy resin composition is dried and baked, so that the insulating layer 5540 is formed from an epoxy resin. A film having an adhesive layer is used as the substrate 5500, and the film that is the substrate 5500 is bonded with thermocompression to a surface of the insulating layer 5540, so that the insulating layer 5540 and the substrate 5500 are attached to each other.

Next, peeling is caused between the insulating layer 5104 and the peeling layer 5102, whereby the element formation layer 5541 is peeled from the substrate 5100 and transposed to the substrate 5500 (see FIG. 17B).

A method for peeling the element formation layer 5541 from the substrate 5100 can be appropriately selected from the following methods: (1) a method in which a stacked structure of a metal layer and a layer containing metal oxide (or metal nitride) is provided as a peeling layer between the substrate and the element formation layer, the layer containing metal oxide is weakened by crystallization, and the element formation layer is physically peeled from the substrate; (2) a method in which a stacked structure of a metal layer and a layer containing metal oxide (or metal nitride) is provided as a peeling layer between the substrate and the element formation layer, the layer containing metal oxide is weakened by crystallization, part of the peeling layer is etched away using a solution or a halogen fluoride gas such as NF₃, BrF₃, or ClF₃, and the element formation layer is physically peeled from the substrate; (3) a method in which a peeling layer is formed using amorphous silicon containing hydrogen between the substrate and the element formation layer, and the peeling layer is irradiated with a laser beam to discharge a hydrogen gas, so that the substrate is peeled; (4) a method in which a peeling layer is formed using amorphous silicon between the substrate and the element formation layer, and the peeling layer is etched away using a solution or a halogen fluoride gas to be peeled; (5) a method in which a substrate over which an element formation layer is formed (the substrate 5100 in this embodiment mode) is mechanically shaved, or the substrate is etched away using a solution or a halogen fluoride gas such as NF₃, BrF₃, or ClF₃ to be peeled; and the like. In the above peeling methods (1) and (2), the peeling layer and the insulating layer may be formed between the substrate and the element formation layer, a layer containing metal oxide (or metal nitride) is provided between the peeling layer and the insulating layer, and then the layer containing metal oxide may be weakened by crystallization. In this embodiment mode, a tungsten layer and a layer containing an oxide of tungsten are provided as the peeling layer 5102. The layer containing an oxide of tungsten is weakened in crystallization of the semiconductor layer of the transistor formed thereover. Accordingly, after the substrate 5500 is bonded to the element formation layer 5541, the element formation layer 5541 is physically peeled from the substrate 5100. The substrate 5100 from which the element formation layer is peeled is preferably reused for reduction of cost.

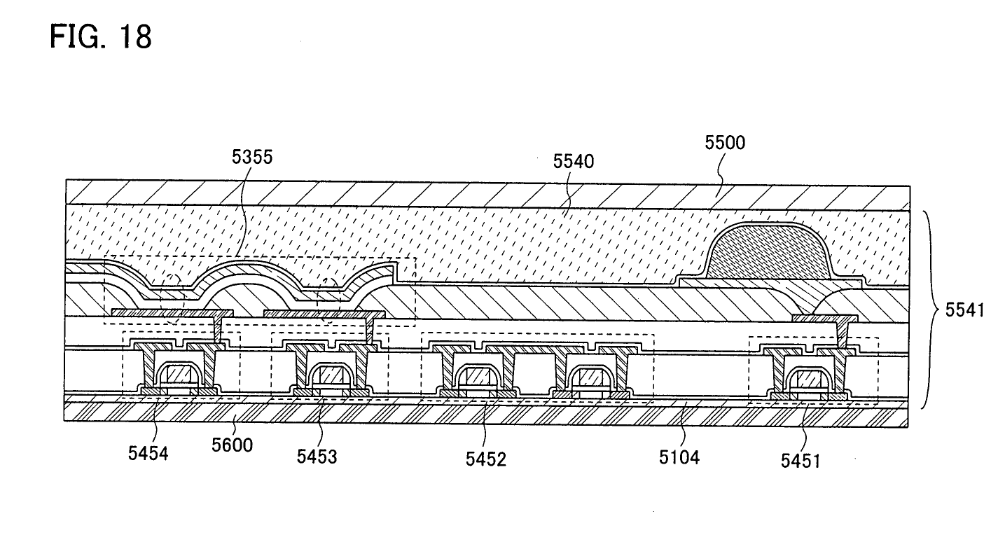

Subsequently, a substrate 5600 is attached to a surface where the insulating layer 5104 is exposed by peeling of the substrate 5100 (see FIG. 18). As the substrate 5600, a flexible substrate is preferable, and specifically, a similar substrate to the substrate 5500 can be used. In this embodiment mode, a film having an adhesive layer is used as the substrate 5600, and the film that is the substrate 5600 is bonded with thermocompression to the surface of the insulating layer 5104, so that the insulating layer 5104 and the substrate 5600 are attached to each other. By the above steps, the element formation layer 5541 is interposed between the flexible substrates.

After the element formation layer 5541 is transposed to the substrate 5500, the substrate 5500 may be peeled. For example, after the element formation layer 5541 is peeled from the substrate 5100 that is a supporting substrate and transposed to the substrate 5500, the substrate 5600 is attached to the element formation layer 5541, and the element formation layer 5541 can be peeled from the substrate 5500 and transposed to the substrate 5600.

By the above steps, a semiconductor device that has a memory element and an antenna can be formed. Further, a flexible semiconductor device can be formed. By applying the present invention, generation of defects in an element can be prevented in the transposing process. Accordingly, a highly reliable semiconductor device can be provided with high yield.

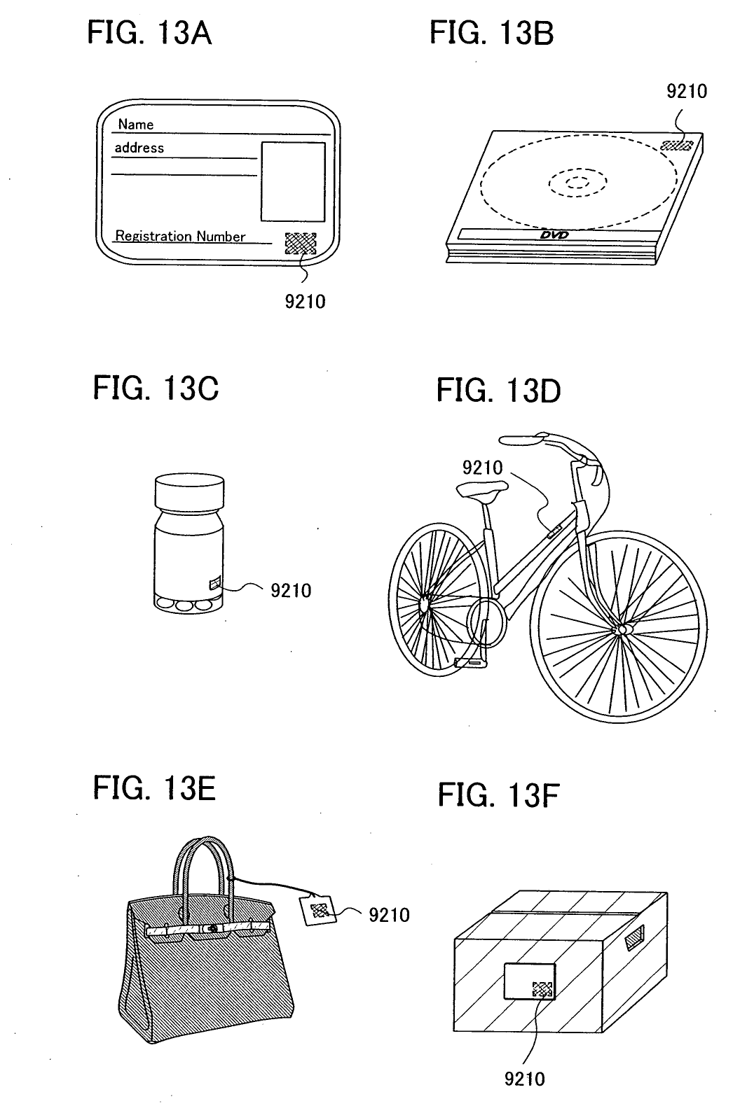

Next, an example in which a semiconductor device of the present invention, capable of reading and writing data without contact as shown in FIGS. 14A and 14B, is used for various usage will be described with reference to FIGS. 13A to 13F.

FIGS. 13A to 13F each show an example in which a semiconductor device of the present invention is applied as a wireless chip. For example, a wireless chip 9210 to which the semiconductor device of the present invention is applied can be applied to paper money, coins, securities, bearer bonds, identification certificates (driver's license, certificate of residence, and the like, see FIG. 13A), recording media (DVD software, video tapes, and the like, see FIG. 13B), containers for package (package paper, bottles, and the like, see FIG. 13C), vehicles (bicycles and the like, see FIG. 13D), personal belongings (bags, glasses, and the like), foods, plants, clothes, commodities, electronic appliances, baggage tags (see FIGS. 13E and 13F), and the like. Further, the wireless chip can be attached to or embedded into animals or human bodies. The electronic appliances include a liquid crystal display device, an EL display device, a television device (also referred to as simply a TV, a TV receiving machine or a television receiving machine), a mobile phone, and the like.

The semiconductor device of the present invention (for example, the wireless chip 9210 of FIGS. 13A to 13F) is fixed to a product by being mounted on a printed substrate, being attached to a surface of the product, or being embedded in the product. For example, if the product is a book, the semiconductor device is fixed to the book by embedding it in a paper, and if the product is a package made of an organic resin, the semiconductor device is fixed to the package by embedding it in the organic resin. Since the semiconductor device of the present invention can be small, thin and lightweight, the design quality of the product itself is not degraded even after the semiconductor device is fixed to the product. By providing the semiconductor device to paper money, coins, securities, bearer bonds, identification certificates, and the like, an identification function can be provided and the forgery can be prevented by using this identification function. Moreover, when the semiconductor device of the present invention is provided for containers for package, recording media, personal belongings, foods, clothes, commodities, electronic appliances, and the like, the efficiency of systems such as an inspection system can be improved.

This embodiment mode can be combined with Embodiment Modes 1 to 4 as appropriate.

### Embodiment Mode 7

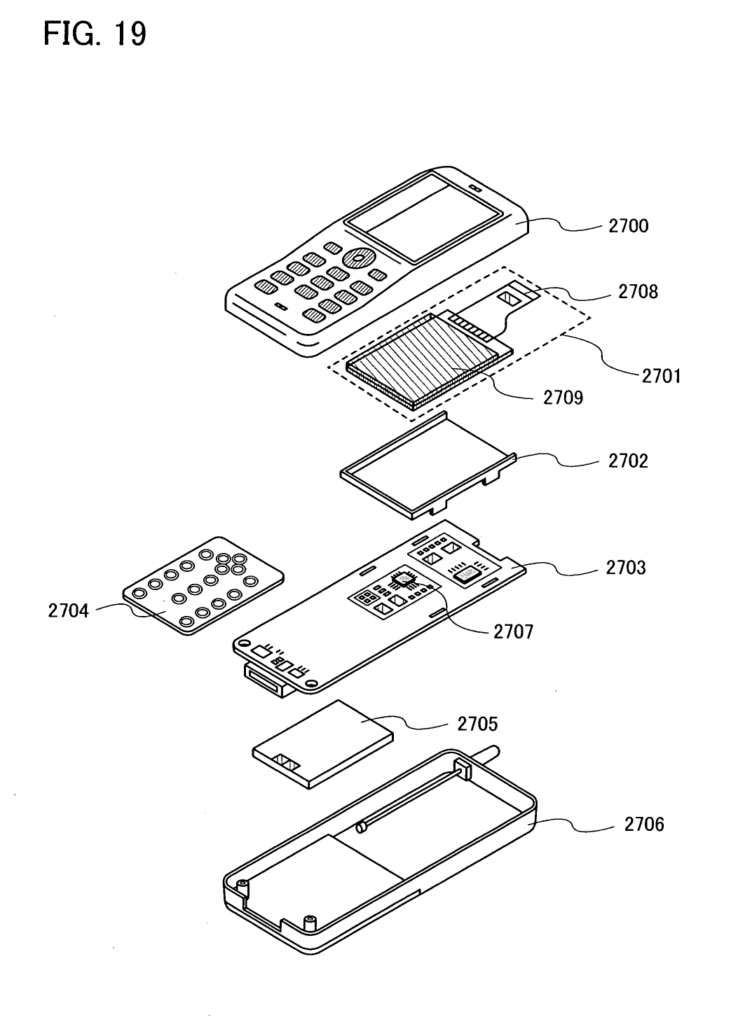

In this embodiment mode, an example of an electronic appliance mounted with a semiconductor device of the present invention will be described with reference to FIG. 19.

An electronic appliance described in this embodiment mode is a mobile phone, which includes a chassis 2700, a chassis 2706, a panel 2701, a housing 2702, a printed circuit board 2703, operation buttons 2704 and a battery 2705. The panel 2701 is detachably incorporated in the housing 2702, and the housing 2702 is fitted into the printed circuit board 2703. The shape and size of the housing 2702 is appropriately modified in accordance with an electronic appliance to which the panel 2701 is to be incorporated. The printed circuit board 2703 has a plurality of packaged semiconductor devices mounted. A semiconductor device of the present invention can be used as one of the packaged semiconductor devices. Specifically, a semiconductor device that has a memory element shown in the above embodiment modes is applied. The plurality of semiconductor devices mounted on the printed circuit board 2703 have any function of a controller, a central processing unit (CPU), a memory, a power supply circuit, an audio processing circuit, a sending/receiving circuit, and the like.

The panel 2701 is connected to the printed circuit board 2703 via a connection film 2708. The panel 2701, the housing 2702 and the printed circuit board 2703 are included inside the chassis 2700 and the chassis 2706 together with the operation buttons 2704 and the battery 2705. A pixel region 2709 in the panel 2701 is provided so as to be observed from an opening window of the chassis 2700.

As aforementioned, the semiconductor device of the present invention has features of being small, thin and lightweight. These features allow efficient usage of limited space in the chassis 2700 and the chassis 2706 of the electronic appliance.

Since the semiconductor device of the present invention includes a memory element having a simple structure in which a layer containing an organic compound is interposed between a pair of electrode layers, which is changed by application of voltage from the outside, the manufacturing cost of the semiconductor device can be suppressed, and an inexpensive electronic appliance can be provided. Further, since the semiconductor device of the present invention can be highly integrated easily, an electronic appliance including a large-capacity memory circuit can be provided.

The semiconductor device that has the memory element of the present invention has features that data writing is conducted by application of voltage from the outside, the memory element is nonvolatile, and additional writing of data is possible. By the features, forgery caused by rewriting of data can be prevented, and new data can be additionally written. Accordingly, an electronic appliance that has highly-function and high added value can be provided.

The chassis 2700 and the chassis 2706 are only examples of the exterior shape of the mobile phone, and electronic appliance of this embodiment mode may be varied in accordance with its function and intended use.

This embodiment mode can be combined with Embodiment Modes 1 to 6 as appropriate.

### Embodiment 1

In this embodiment, results of manufacturing a memory element using the present invention and conducting a transposing process will be described.

A titanium layer as a first electrode layer over a glass substrate, a polyimide layer with a thickness of 1.5 μm as a partition layer covering a part (end portion) of the first electrode layer, a calcium fluoride (CaF₂) layer with a thickness of 1 nm as an insulating layer over the first electrode layer and the partition layer, an NPB layer with a thickness of 10 nm as a layer containing an organic compound, and a second electrode layer were sequentially formed, so that a sample was manufactured. In this embodiment, by changing a material and a formation method of the second electrode layer, samples 1 to 14 were manufactured. In addition, Comparative Examples 1 to 3 using silver (Ag), zinc (Zn), and copper (Cu) as the second electrode layer were formed.

In this embodiment, after the partition layer using polyimide was formed over the first electrode layer so that the first electrode layer has an opening, oxygen (O₂) ashing was performed in order to remove a polyimide residue on the first electrode layer.

Next, the second electrode layer formed using the samples 1 to 14 is described. The sample 1 has an indium layer (thickness of 200 nm). The sample 2 has a calcium layer (thickness of 150 nm). The sample 3 has a tin layer (thickness of 200 nm). The sample 4 has an aluminum layer (thickness of 100 nm). The sample 5 has an indium-tin alloy layer (thickness of 200 nm). The sample 6 has a layer (thickness of 200 nm) formed by evaporating an indium-tin alloy and indium put in the same boat. The sample 7 has a layer (thickness of 200 nm) formed by co-evaporating indium and tin so that the tin is contained at 10 wt % with respect to indium. The sample 8 has a layer (thickness of 200 nm) formed by co-evaporating indium and tin so that tin is contained at 1 wt % with respect to indium. The sample 9 has a stacked layer of a layer (thickness of 200 nm) formed by co-evaporating indium and tin so that tin is contained at 10 wt % with respect to indium and an aluminum layer (thickness of 200 nm). The sample 10 has a layer (thickness of 200 nm) formed by co-evaporating an indium-tin alloy and chromium so that a ratio of the indium-tin alloy to chromium is 10:1. The sample 11 has a layer (thickness of 150 nm) formed by co-evaporating indium and magnesium so that magnesium is contained at 10 wt % with respect to indium. The sample 12 has a stacked layer of an indium layer (thickness of 100 nm) and an aluminum layer (thickness of 200 nm). The sample 13 has a stacked layer of a layer (thickness of 100 nm) formed by evaporating an indium-tin alloy and indium put in the same board and an aluminum layer (thickness of 100 nm). The sample 14 has a stacked layer of a layer (thickness of 200 nm) formed by evaporating an indium-tin alloy and indium put in the same board and an aluminum layer (thickness of 10 nm). Each of the samples 1 to 14 was formed as the second electrode layer. The samples 1 to 4 and 12 were formed by an evaporating method using each material.

A silver layer (thickness of 200 nm), a zinc layer (thickness of 200 nm), and a copper layer (thickness of 200 nm) were formed as the second electrode layer, in Comparative Example 1, Comparative Example 2, and Comparative Example 3 respectively. The Comparative Examples 1 to 3 were formed using each material by an evaporation method.

An epoxy resin was applied over the memory element of Sample 1 that was formed over a glass substrate by a mimeographic printing method, and heated at 110° C. for 60 minutes in a nitrogen atmosphere to form an epoxy resin layer with a thickness of 100 to 200 μm. After that, the memory element of the sample 1 was peeled from the glass substrate and transposed to the epoxy resin layer. A transposition state of the memory element of the sample 1 that was transposed to the epoxy resin layer is shown in Table 1. Similarly to the sample 1, an epoxy resin was applied over each of the memory elements of the samples 2 to 14 and Comparative Examples 1 to 3 each manufactured over a glass substrate by a mimeographic printing method, and heated at 110° C. for 60 minutes in a nitrogen atmosphere to form an epoxy resin layer with a thickness of 100 μm to 200 μm. After that, each memory element of the samples 2 to 14 and Comparative Examples 1 to 3 was peeled from the glass substrate and transposed to the epoxy resin layer. Respective transposition states of the memory elements of the samples 2 to 14 and Comparative Examples 1 to 3 that were transposed to the epoxy resin layer are shown in Table 1. In Table 1, “−” means an alloy, and for example, “In—Sn” means an indium-tin alloy. “+” means evaporation of the materials put in the same board, and for example, “(In—Sn)+In” means that an indium-tin alloy and indium put in the same boat were evaporated. “:” means co-evaporation, and for example, “In:Sn” means co-evaporation of indium and tin. “\” means a stacked structure and an object indicated on the right side is an upper layer of an object indicated on the left side, and for example, “In\Al” means a stacked structure of indium and aluminum, in which aluminum is an upper layer of indium.

TABLE 1

| | | TRANS- | |
|---|---|---|---|
| | | POSITION | REMARKS |
| SAMPLE | STRUCTURE | STATE | COLUMN |
| SAMPLE 1 | In | ∘ | |
| SAMPLE 2 | Ca | ∘ | |
| SAMPLE 3 | Sn | ∘ | |
| SAMPLE 4 | Al | ∘ | |
| SAMPLE 5 | In—Sn | ∘ | |
| SAMPLE 6 | (In—Sn) + In | ∘ | |
| SAMPLE 7 | In: Sn | ∘ | Sn; 10 wt % |
| SAMPLE 8 | In: Sn | ∘ | Sn; 1 wt % |
| SAMPLE 9 | (In: Sn)\Al | ∘ | Sn; 10 wt % |
| SAMPLE 10 | (In—Sn): Cr | ∘ | (In—Sn):Cr = |
| | | | 10:1 |
| SAMPLE 11 | In:Mg | ∘ | Mg; 10 wt % |
| SAMPLE 12 | In\Al | ∘ | |
| SAMPLE 13 | ((In—Sn) + | ∘ | |
| | In)\Al | | |
| SAMPLE 14 | ((In—Sn) + | ∘ | |
| | In)\Al | | |
| COMPARATIVE | Ag | x | |
| EXAMPLE 1 | | | |
| COMPARATIVE | Cu | x | |
| EXAMPLE 2 | | | |
| COMPARATIVE | Zn | x | |
| EXAMPLE 3 | | | |

The samples 1 to 14 manufactured by the present invention could be peeled with a good state without film peeling, a peeling residual, or the like when viewing. On the other hand, in a case of Comparative Examples 1 to 3, only the second electrode layers (the silver layer, the zinc layer, and the copper layer) were transposed to the epoxy resin layer, and the entire memory element could not be peeled from the glass substrate.

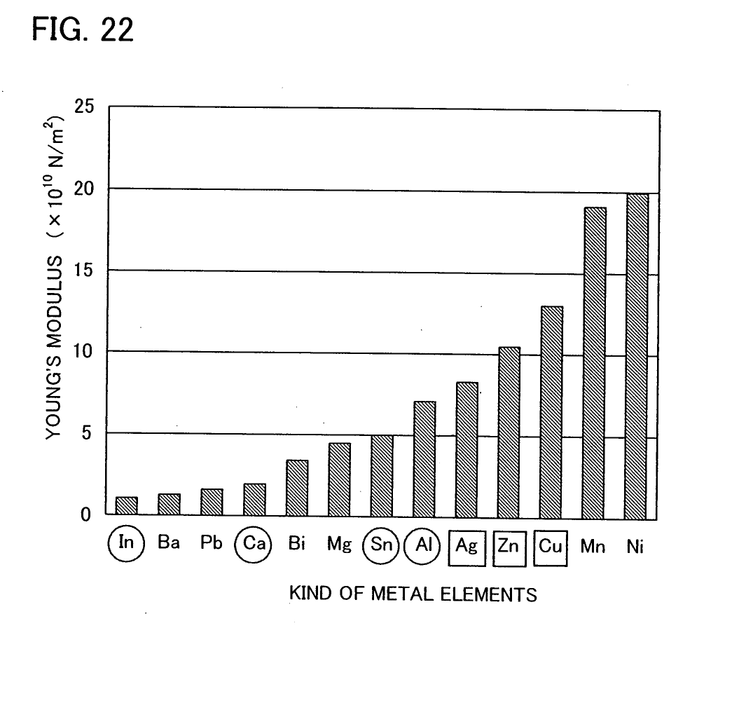

Here, mechanical properties of metal elements are shown in FIG. 22 and Table 2. In a bar graph shown in FIG. 22, a horizontal axis indicates a kind of metal elements, and a vertical axis indicates a Young's modulus (10¹⁰ N/m²). Young's moduli of metal elements shown below were extracted from Iwanami Physical and Chemical Dictionary 5^{th} edition.

TABLE 2

| KIND OF METAL | |
|---|---|
| ELEMENTS | YOUNG'S MODULUS (×10¹⁰ N/m²) |
| INDIUM (In) | 1.06 |
| BARIUM (Ba) | 1.28 |
| LEAD (Pb) | 1.61 |
| CALCIUM (Ca) | 1.96 |
| BISMUTH (Bi) | 3.40 |
| MAGNESIUM (Mg) | 4.47 |
| TIN (Sn) | 4.99 |
| ALUMINIUM (Al) | 7.06 |
| SILVER (Ag) | 8.27 |
| ZINC (Zn) | 10.45 |
| COPPER (Cu) | 12.98 |
| MANGANESE (Mn) | 19.10 |
| NICKEL (Ni) | 19.95 |

In FIG. 22, symbols of metal elements of In, Ba, Pb, Ca, Bi, Mg, Sn, Al, Ag, Zn, Cu, Mn, and Ni are arranged in this order from the left side on the horizontal axis, and it can be found that the metal elements of which a symbol is located on the right side have a higher Young's modulus. The specific numerical values of Young's moduli of the metal elements shown in FIG. 22 are shown in Table 2.

In addition, in FIG. 22, symbols of the metal elements that were peeled and transposed favorably shown in Table 1 are circled. On the other hand, symbols of the metal elements that had a poor peeling property and could not be transposed are surrounded in a square.

As it is obvious from FIG. 22 and Table 1, the metal elements of which the symbol is positioned on the left side of aluminum (including aluminum), in other words, the metal elements that have a lower Young's modulus than that of aluminum (including aluminum) could be favorably peeled and transposed. On the other hand, the metal elements of which the symbol is positioned on the right side of silver (including silver), in other words, the metal elements that have a higher Young's modulus than that of silver had a poor peeling property and could not transposed; therefore, such metal elements were outside the scope of the present invention. Accordingly, the metal elements having a Young's modulus less than a Young's modulus of silver were favorably peeled, and excellent results were obtained.

Through the transposing process of the element, the element is inevitably bent in the step for peeling the element from the substrate (supporting substrate such as a glass substrate) or the step for attaching the substrate (flexible substrate) to the element. The flexible substrate and the element can be bonded with relatively high adhesion by a method such as thermocompression. That is, the second electrode layer that is not in contact with the supporting substrate and is bonded to the flexible substrate with high adhesion.

As shown in the above mathematical formula (I), as a substance (electrode layer) has a lower Young's modulus, the substance (electrode layer) is not easily transformed, and as the substance has higher Young's modulus, the substance is not easily transformed. Therefore, when the second electrode layer has a higher Young's modulus than a predetermined value, the second electrode layer is not easily transformed and is bonded to the flexible substrate with high adhesion. Accordingly, it is considered that the element cannot be influenced by behavior such as bending, and the element is broken.

In this embodiment, it can be found that there is a critical state of element breakdown in the transposing process between a Young's modulus of aluminum and that of silver from the results of Table 1, FIG. 22, and the like. From Table 2, aluminum has a Young's modulus of 7.06×10¹⁰ N/m², and silver has a Young's modulus of 8.27×10¹⁰ N/m². In the present invention, when the second electrode layer has a Young's modulus of equal to or less than a value between a Young's modulus of aluminum and that of silver, the element can be favorably peeled, and it can be expected that transposition be performed. Therefore, when 7.5×10¹⁰ N/m² is the upper limit of a Young's modulus of the second electrode, preferably, the second electrode has a Young's modulus of 7.5×10¹⁰ N/m² or less, transposition can be favorably conducted.

### Embodiment 2

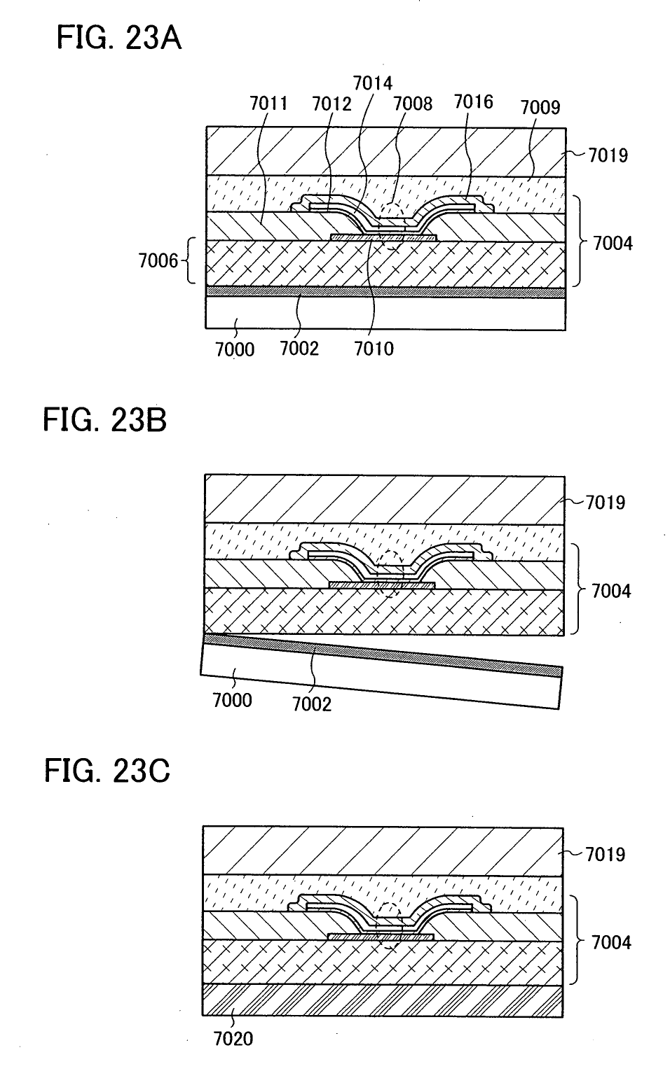

In this embodiment, the results of manufacturing a semiconductor device that has a memory element of the present invention by performing the transposing process and the results of evaluation of the characteristics of the semiconductor device that has a memory element are shown. In this embodiment, an aluminum layer is formed as a second electrode layer. Manufacturing of a semiconductor device of this embodiment will be described using schematic views of FIGS. 23A to 23C.

A peeling layer 7002 was formed over a first substrate 7000, and an element layer 7004 was formed over the peeling layer 7002. An insulating layer 7009 was formed over the element layer 7004, and a second substrate 7019 was attached to a surface of the insulating layer 7009 (see FIG. 23A).

As the first substrate 7000, a glass substrate was used. As the peeling layer 7002, a stacked structure of a metal layer and a metal oxide layer was formed. Specifically, a stacked structure of a tungsten layer and a layer containing an oxide of tungsten was formed. Here, after a tungsten layer was formed, an insulating layer was formed over the tungsten layer, whereby a layer containing an oxide of tungsten was formed at an interface between the insulating layer and the tungsten layer.

In the element layer 7004, a semiconductor element 7006 and a memory element 7008 electrically connected to the semiconductor element 7006 were formed. Further, in the element layer 7004, a conductive layer serving as an antenna was also formed. In FIGS. 23A to 23C, structures other than a memory element 7008 are simplified.

The memory element 7008 has a structure of the present invention. Specifically, a titanium layer as a first electrode layer 7010, a calcium fluoride (CaF₂) layer with a thickness of 1 nm as an insulating layer 7012 over the first electrode layer 7010, a layer formed of 9-[4-(N-carbazolyl)]phenyl-10-phenylanthracene (abbreviation: CzPA) as a layer 7014 containing an organic compound over the insulating layer 7012, and an aluminum layer with a thickness of 75 nm as a second electrode layer 7016 over the layer 7014 containing an organic compound were sequentially formed. The first electrode layer 7010 and the second electrode layer 7016 were formed by a sputtering method. The insulating layer 7012 and the layer 7014 containing an organic compound were formed by an evaporation method.

As the insulating layer 7009, an organic resin was used, and specifically, the insulating layer 7009 was formed using an epoxy resin. As the second substrate 7019, a flexible substrate was used, and specifically, a film having an adhesive layer is attached to a surface of the insulating layer 7009.

Next, the element layer 7004 was peeled from the first substrate 7000 and transposed to the second substrate 7019 (see FIG. 23B).

Peeling was generated at an interface between the peeling layer 7002 and the element layer 7004 or inside of the peeling layer 7002. The element layer 7004 was physically peeled from the first substrate 7000.

Then, a third substrate 7020 was attached to a surface of the element layer 7004 that was exposed by peeling of the first substrate 7000 (see FIG. 23C). As the third substrate 7020, a flexible substrate was used.

As described above, a semiconductor device that has a memory element, which was transposed to the flexible substrate, was obtained.

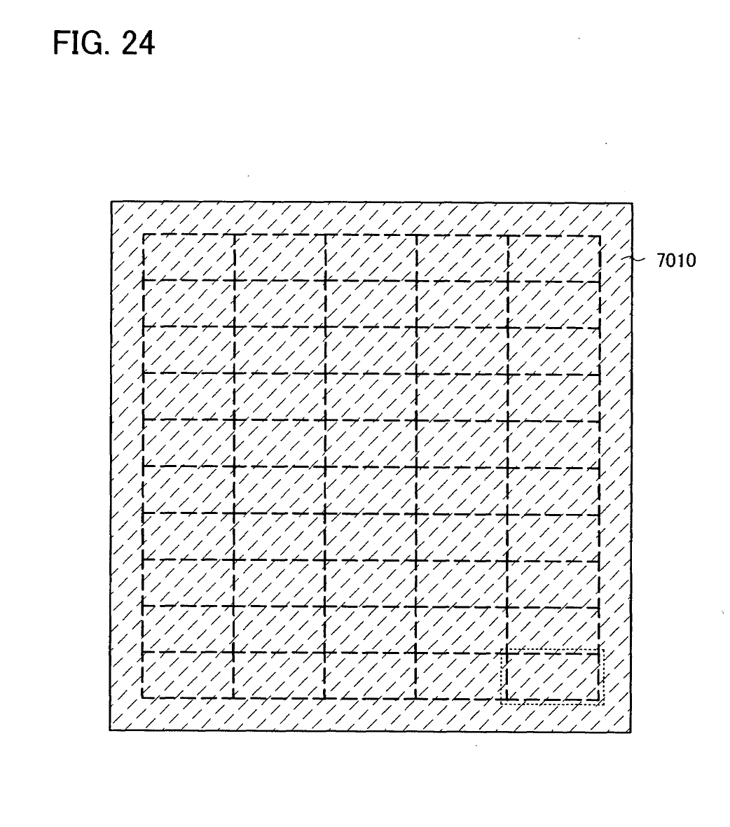

In this embodiment, Sample A and Sample B were manufactured. Sample A and Sample B have the same structure, in which 50 semiconductor devices are formed over one substrate. Each semiconductor device is provided with a semiconductor element, a memory element, and an antenna. Each of the 50 semiconductor devices formed in each of Sample A and Sample B is provided with 64 memory elements. FIG. 24 shows a schematic view of a top view, and individual semiconductor devices are indicated by a dot line.

When the appearance of Sample A was examined by an optical microscope, each memory element in the 50 semiconductor devices can be transposed without element breakdown, and a success rate of transposition was 100%. When the appearance of Sample B was examined by an optical microscope as similar to Sample A, each memory element in the 47 semiconductor devices can be transposed without element breakdown, and a success rate was 94%. Accordingly, it was found that transposition can be favorably performed by using an aluminum layer as the second electrode layer.

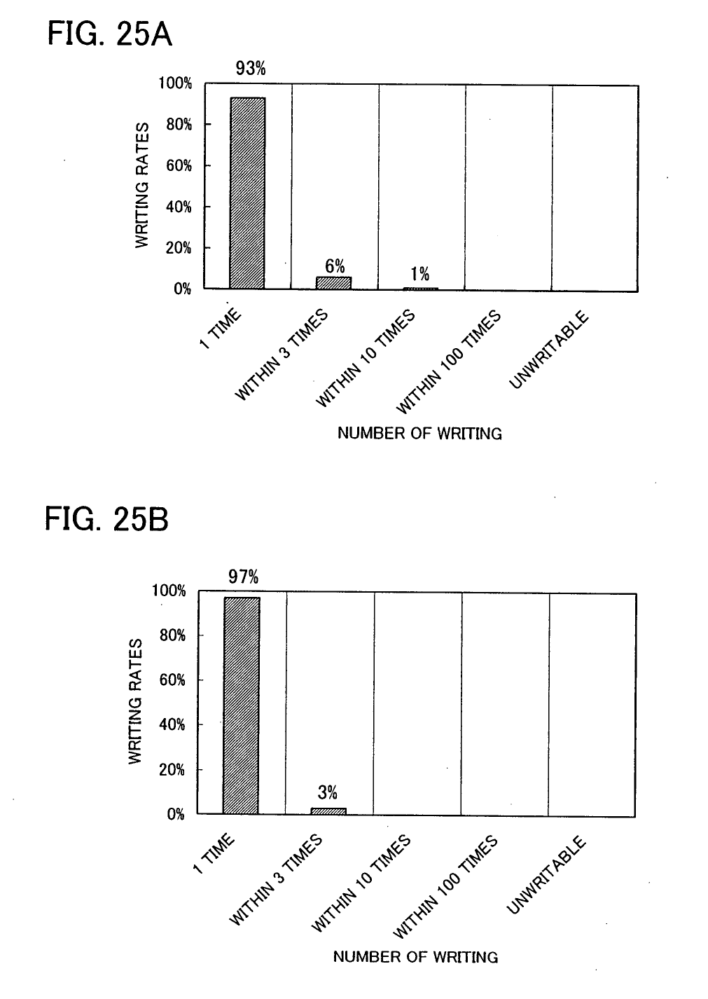

Next, FIGS. 25A and 25B show writing success rates in writing data into the memory elements formed in Sample A and Sample B without contact. Here, the results of performing writing into the memory elements by wireless using a reader/writer are shown.

FIG. 25A shows writing rates of Sample A, and FIG. 25B shows writing rates of Sample B. From FIG. 25A, data can be written into the memory elements at a rate of 93% by one writing instruction from a reader/writer. From FIG. 25B, data can be written into the memory elements at a rate of 97% by one writing instruction from a reader/writer. That is, when the writing rates of Sample A and Sample B are averaged, data can be written into the memory elements at a rate of 95% or more by one writing instruction from a reader/writer. Furthermore, from FIGS. 25A and 25B, it is found that data can be written into the memory elements at a rate of 100% by writing instructions within ten times from a reader/writer. Accordingly, it was found that Sample A and Sample B have favorable writing rates, and data can be favorably written into the memory elements of the present invention even after transposition.

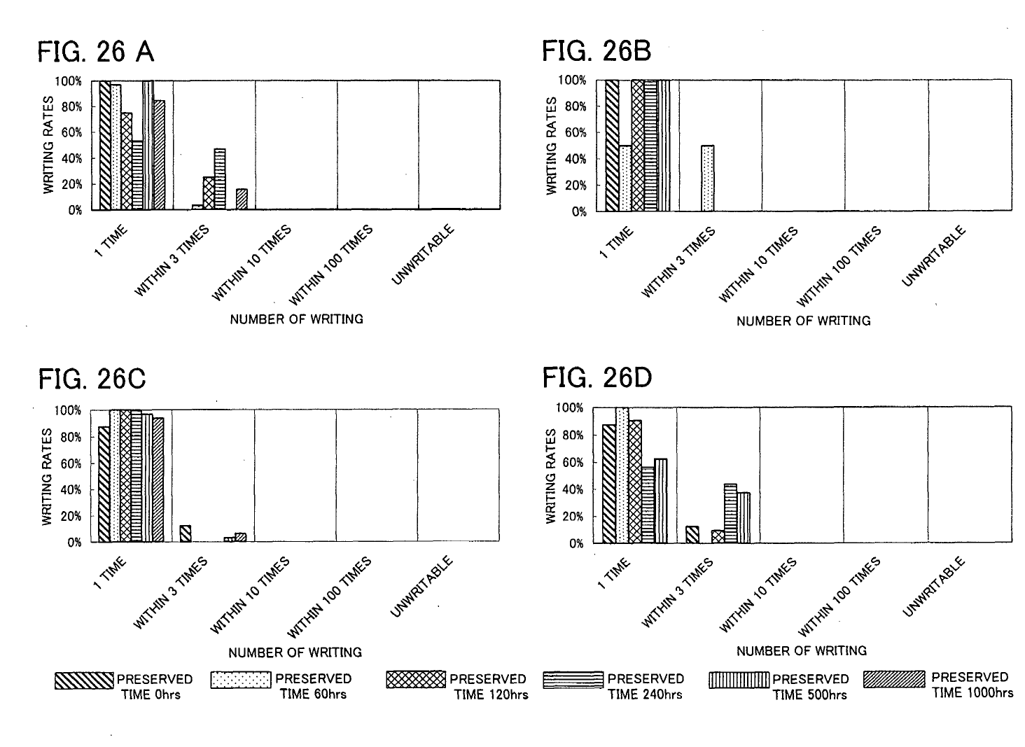

Next, FIGS. 26A to 26D show writing rates in writing data into the memory elements without contact after a semiconductor device obtained from Sample A or Sample B, which was determined that transposition has succeeded by appearance examination, was preserved under a certain condition. Here, the results of conducting writing into the memory elements by wireless using a reader/writer are shown.

Here, after the predetermined number of memory elements were preserved for a certain time (0 hour, 60 hours, 120 hours, 240 hours, 500 hours, or 1000 hours) under any of conditions of high temperature (+80° C.), low temperature (−40° C.), room temperature, or thermal shock (−40° C. to +85° C.), writing was conducted to the memory elements by wireless using a reader/wrier. Here, four semiconductor devices each have 8 memory elements, that is, 32 memory elements were preserved under a certain condition, and then, writing was conducted.

It is to be noted that thermal shock preservation in this embodiment indicates repetition of high-temperature preservation and low-temperature preservation. Here, the memory elements were preserved by repeating preservation for 30 minutes under +85° C. condition and preservation for 30 minutes under −45° C. condition.

FIG. 26A shows writing rates of the memory elements preserved at high temperature (+85° C.). FIG. 26B shows writing rates of the memory elements preserved at low temperature (−40° C.). FIG. 26C shows writing rates of the memory elements preserved at room temperature. FIG. 26D shows writing rates of the memory elements preserved under the condition where thermal shock is given.

From FIG. 26A and FIG. 26C, it is found that after the memory elements are preserved at high-temperature (+85° C.) or room temperature for 0 hour, 60 hours, 120 hours, 240 hours, 500 hours, or 1000 hours, data can be written by the writing instructions within three times.

From FIG. 26B and FIG. 26D, it is found that after the memory elements are preserved at low-temperature (−40° C.) or under condition where thermal shock is given, for 0 hour, 60 hours, 120 hours, 240 hours, or 500 hours, data can be written by the writing instructions within three times.

The results shown in FIGS. 26A to 26D are shown in the following Table 3. In Table 3, in a case where data can be written by the writing instructions within 100 times, a circle is marked.

TABLE 3

| PRESERVED | PRESERVED TIME (hour) | | | | |
|---|---|---|---|---|---|
| CONDITION | 0 | 120 | 240 | 500 | 1000 |
| HIGH | ◯ | ◯ | ◯ | ◯ | ◯ |
| TEMPERATURE | | | | | |
| (+85° C.) | | | | | |
| LOW | ◯ | ◯ | ◯ | ◯ | |
| TEMPERATURE | | | | | |
| (−40° C.) | | | | | |
| ROOM | ◯ | ◯ | ◯ | ◯ | ◯ |
| TEMPERATURE | | | | | |
| THERMAL | ◯ | ◯ | ◯ | ◯ | |
| SHOCK | | | | | |
| (−40° C.~+85° C.) | | | | | |

From the results of FIGS. 26A to 26D and Table 3, it was found that the memory elements of Sample A and Sample B had favorable writing rates, and writing of data could be favorably performed after the memory elements of the present invention were transposed and preserved under a certain condition.

Table 4 shows the results of evaluating the presence or absence of variation of data when a memory element of a semiconductor device was preserved under a certain condition after writing data into the memory element of the semiconductor device without contact. The memory element of the semiconductor device was obtained from Sample A or Sample B and determined that transposition had succeeded by appearance examination.

Here, writing was conducted by wireless to the memory element using a reader/writer. After writing of data, the predetermined number of memory elements were preserved for a certain time period (60 hours, 120 hours, 240 hours, 500 hours, or 1000 hours) under any of conditions of high temperature (+80° C.), low temperature (−40° C.), thermal shock (−45° C. to +85° C.), or room temperature.

TABLE 4

| PRESERVED | PRESERVED TIME (hour) | | | | |
|---|---|---|---|---|---|
| CONDITION | 60 | 240 | 500 | 1000 | 2000 |
| HIGH | 0/25 (0/1600) | 1/25 (1/1600) | 1/15 (1/960) | 0/10 (0/640) | 0/10 (0/640) |
| TEMPERATURE | | | | | |
| (+85° C.) | | | | | |
| LOW | 0/20 (0/1280) | 0/20 (0/1280) | 0/10 (0/640) | 0/10 (0/640) | 0/10 (0/640) |
| TEMPERATURE | | | | | |
| (−40° C.) | | | | | |
| THERMAL | 0/20 (0/1280) | 1/20 (1/1280) | 1/10 (1/640) | 1/10 (1/640) | 1/10 (1/640) |
| SHOCK | | | | | |
| (−40° C.~+85° C.) | | | | | |
| ROOM | 0/20 (0/1280) | 0/20 (0/1280) | 0/10 (0/640) | 0/10 (0/640) | 0/10 (0/640) |
| TEMPERATURE | | | | | |

In Table 4, denominators indicate the number of the evaluated semiconductor devices, and numerators indicate the number of the semiconductor devices in which data is varied after preservation under the certain condition. The evaluation is performed to 64 memory elements included in each semiconductor device, and the number of memory elements in which data is varied after preservation under the certain condition is shown in a parenthesis. In each parenthesis, a denominator indicates the number of the evaluated memory elements, and a numerator indicates the number of the memory elements in which data is varied after preservation under the certain condition. The number of the memory elements, which is a denominator in the parenthesis, is the number obtained by multiplying the number of the evaluated semiconductor device by 64.

According to the results of Table 4, it was found that probability of data variation was 0.1% or less in the evaluated memory elements, and after writing of data, probability of data variation was extremely low even when the memory elements of the present invention were preserved under a certain condition.

This application is based on Japanese Patent Application serial no. 2006-285378 filed in Japan Patent Office on Oct. 19, 2006, the entire contents of which are hereby incorporated by reference.

### EXPLANATION OF REFERENCE

10: memory cell array, 12: memory cell, 14: memory element, 20: substrate, 22: first electrode layer, 25: layer containing organic compound, 26 layer containing organic compound, 27: second electrode layer, 28: second electrode layer, 30: interface, 32: bit line driver circuit, 34: column decoder, 36: reading/writing circuit, 38: selector, 40: word line driver circuit, 42: row decoder, 44: level shifter, 50: diode, 52: third electrode layer, 54: semiconductor layer, 55: insulating layer, 56: partition layer, 62: interlayer insulating layer, 64: partition layer, 72: resistor element, 74: differential amplifier, 76: transistor, 78: clocked inverter, 100: memory element, 102: first electrode layer, 104: layer containing organic compound, 106: second electrode layer, 108: layer, 110: memory element, 220: light-emitting element, 222: second electrode layer, 224: light-emitting layer, 226: first electrode layer, 230: hole-injecting layer, 232: hole-transporting layer, 234: hole-transporting layer, 236: electron-injecting layer, 300: piezoelectric element, 302: second electrode layer, 304: piezoelectric layer, 306: first electrode layer, 320: organic transistor element, 322: electrode layer, 324: organic semiconductor layer, 326: gate electrode layer, 328: substrate, 330: gate insulating layer, 610: memory cell array, 612: memory cell, 614: memory element, 620: substrate, 622: first electrode layer, 626: layer containing organic compound, 628: second electrode layer, 630: interface, 632: bit line driver circuit, 634: column decoder, 636: reading/writing circuit, 638: selector, 640: word line driver circuit, 642: row decoder, 644: level shifter, 650: base insulating layer, 651: insulating layer, 652: insulating layer, 654: partition layer, 656: insulating layer, 660: single crystalline semiconductor substrate, 661: field oxide film, 662: filed effect transistor, 663: electrode layer, 672: insulating layer, 673: resistor element, 674: differential amplifier, 676: transistor, 678: clocked inverter, 680: transistor, 700: substrate, 702: peeling layer, 704: insulating layer, 706: transistor, 708: transistor, 710: transistor, 713: insulating layer, 716: insulating layer, 718: first electrode layer, 719: first electrode layer, 720: first electrode layer, 721: partition layer, 722: layer containing organic compound, 724: second electrode layer, 726: element, 728: element, 730: element, 734: insulating layer, 736: substrate, 738: element formation layer, 740: substrate, 900: display device, 901: substrate, 902: pixel portion, 903: insulating layer, 904: driver circuit portion, 906: terminal portion, 908: substrate, 910: sealant, 913: insulating layer, 914: insulating layer, 916: insulating layer, 918: partition layer, 920: capacitor element, 924: driver transistor, 926: transistor group, 930: light-emitting element, 932: first electrode layer, 934: layer containing organic compound, 936: second electrode layer, 938: region, 950: terminal electrode layer, 952: anisotropic conductive layer, 954: FPC, 1301: insulating layer, 1302: semiconductor layer, 1303: gate insulating layer, 1304: gate electrode layer, 1308: insulating layer, 1310: low concentration impurity region, 1311: high concentration impurity region, 1312: electrode layer, 1313: channel formation region, 1351: insulating layer, 1352: insulating layer, 1361: insulating layer, 1362: semiconductor layer, 1363: gate insulating layer, 1364: gate electrode layer, 1369: channel protective layer, 1372: electrode layer, 1380: TFT, 1390: TFT, 1391: insulating layer, 1392: insulating layer, 1401: insulating layer, 1402: gate electrode layer, 1403: gate insulating layer, 1404: organic semiconductor layer, 1412: electrode layer, 1461: insulating layer, 1462: gate electrode layer, 1463: gate insulating layer, 1464: organic semiconductor layer, 1472: electrode layer, 1480: TFT, 1490: TFT, 2003: transistor, 2004: gate wiring, 2005: source wiring, 2006: current supply line, 2020: capacitor element, 2024: transistor, 2030: light-emitting element, 2700: chassis, 2701: panel, 2702: housing, 2703: printed circuit board, 2704: operation button, 2705: battery, 2706: chassis, 2708: connection film, 2709: pixel region, 3000: substrate, 3020: element, 3022: first electrode layer, 3024: layer containing organic compound, 3026: second electrode layer, 3040: substrate, 5100: substrate, 5102: peeling layer, 5104: insulating layer, 5106: channel formation layer, 5108: LDD region, 5110: source or drain region, 5114: LDD region, 5116: source or drain region, 5118: channel formation region, 5120: LDD region, 5122: source or drain region, 5124: channel formation region, 5126: LDD region, 5128: source or drain region, 5130: channel formation region, 5132: LDD region, 5134: source or drain region, 5250: transistor layer, 5252: insulating layer, 5300: substrate, 5352: memory element portion, 5353: conductive layer, 5355: memory element portion, 5360: terminal electrode layer, 5366: insulating layer, 5372: layer containing organic compound, 5373: second electrode layer, 5374 partition layer, 5400: substrate, 5440: resin, 5451: transistor, 5452: transistor, 5453: transistor, 5454: transistor, 5463: conductive layer, 5466: insulating layer, 5500: substrate, 5512: channel formation region, 5536: insulating layer, 5538: wiring layer, 5540: insulating layer, 5541: element formation layer, 5544: conductive fine particle, 5600: substrate, 9210: wireless chip, 5351a: memory element, 5351b: memory element, 5356a: memory element, 5356b: memory element, 5361a: first electrode layer, 5361b: first electrode layer, 5362a: layer containing organic compound, 5362b: layer containing organic compound, 5364a: second electrode layer, 5364b: second electrode layer, 5371a: first electrode layer, 5371a: first electrode layer, 5371b: first electrode layer, 7000: substrate, 7002: peeling layer, 7004: element layer, 7006: semiconductor element, 7008: memory element, 7009: insulating layer, 7010: first electrode layer, 7012: insulating layer, 7014: layer containing organic compound, 7016: second electrode layer, 7019: substrate, 7020: substrate

1. A semiconductor device comprising:
a flexible substrate; and
a memory element over the flexible substrate,
wherein the memory element includes a layer containing an organic compound between a first electrode and a second electrode, and
wherein the second electrode layer has a Young's modulus of 7.5×10¹⁰ N/m² or less.

2. A semiconductor device according to claim 1,
wherein the second electrode layer has a thickness of greater than or equal to 10 nm and less than or equal to 200 nm.

3. A semiconductor device according to claim 1,
wherein the second electrode layer contains at least one of indium (In), barium (Ba), lead (Pb), calcium (Ca), bismuth (Bi), magnesium (Mg), tin (Sn), and aluminum (Al).

4. A semiconductor device comprising:
a flexible substrate; and
a light-emitting element over the flexible substrate,
wherein the light-emitting element includes a layer containing an organic compound between a first electrode and a second electrode, and
wherein the second electrode layer has a Young's modulus of 7.5×10¹⁰ N/m² or less.

5. A semiconductor device according to claim 4,
wherein the second electrode layer has a thickness of greater than or equal to 10 nm and less than or equal to 200 nm.

6. A semiconductor device according to claim 4,
wherein the second electrode layer contains at least one of indium (In), barium (Ba), lead (Pb), calcium (Ca), bismuth (Bi), magnesium (Mg), tin (Sn), and aluminum (Al).

7. A method for manufacturing a semiconductor device comprising the steps of:
forming a peeling layer over a first substrate;
forming an element layer over the peeling layer; and
after fixing the element layer to a second substrate, peeling the first substrate from the element layer,
wherein the element layer includes a first electrode layer, a layer containing an organic compound over the first electrode layer and a second electrode layer having a Young's modulus of 7.5×10¹⁰ N/m² or less over the layer containing an organic compound.

8. A method for manufacturing a semiconductor device according to claim 7,
wherein the second electrode layer has a thickness of greater than or equal to 10 nm and less than or equal to 200 nm.

9. A method for manufacturing a semiconductor device according to claim 7, further comprising:
after peeling the first substrate from the element layer, attaching a third substrate to the element layer,
wherein the third substrate is a flexible substrate.

10. A method for manufacturing a semiconductor device according to claim 7,
wherein a flexible substrate is used for the second substrate.

11. A method for manufacturing a semiconductor device according to claim 7,
wherein the second electrode layer is formed using a material containing at least one of indium (In), barium (Ba), lead (Pb), calcium (Ca), bismuth (Bi), magnesium (Mg), tin (Sn), and aluminum (Al).

12. A method for manufacturing a semiconductor device according to claim 7,
wherein at least one of a memory element, a light-emitting element, a piezoelectric element and an organic transistor element is formed in the element layer.
